(19) United States
(12) Patent Application Publication
(10) Pub. No.: US 2009/0014055 A1
(43) Pub. Date: Jan. 15, 2009

(54) Photovoltaic Modules Having a Filling Material

(75) Inventors: Markus E. Beck, San Jose, CA (US); Brian H. Cumpston, Pleasanton, CA (US); Benyamin Buller, Sylvania, OH (US)

Correspondence Address: JONES DAY, 222 EAST 41ST ST, NEW YORK, NY, 10017, US

(73) Assignee: Solyndra, Inc., Fremont, CA (US)

(21) Appl. No.: 12/235,195

(22) Filed: Sep. 22, 2008

Related U.S. Application Data
(63) Continuation-in-part of application No. 11/800,089, filed on May 3, 2007.
Application No. 11/800,089 is a continuation-in-part of application No. 11/378,847, filed on Mar. 18, 2006.
Application No. 11/378,847 is a continuation-in-part of application No. 12/039,659, filed on Feb. 28, 2008.
(60) Provisional application No. 60/906,901, filed on Mar. 13, 2007.
(60) Provisional application No. 60/975,175, filed on Sep. 26, 2007.

(51) Int. Cl. H01L 31/042

(52) U.S. Cl. 136/246

(57) ABSTRACT

A photovoltaic module comprising an elongated substrate in which at least a portion of the elongated substrate is rigid is provided. One or more solar cells are disposed on the elongated substrate and each comprise: (i) a back-electrode disposed on the elongated substrate, (ii) a semiconductor junction layer disposed on all or a portion of a surface of the back-electrode, and (iii) a transparent conductive layer, having a first refractive index, is disposed on all or a portion of a surface of the semiconductor junction. The photovoltaic module further comprises a filler material, having a second refractive index that is smaller or equal in value to the first refractive index, disposed on the transparent conductive layer of the one or more solar cells. The photovoltaic module further comprises a transparent casing disposed on the filler material thereby sealing the photovoltaic module.

### CROSS-REFERENCE TO RELATED APPLICATIONS

This application is a continuation-in-part of U.S. patent application Ser. No. 11/800,089, entitled “Elongated Photovoltaic Cells in Casings,” filed on May 3, 2007 which, in turn, is a continuation-in-part of U.S. patent application Ser. No. 11/378,847 entitled “Elongated Photovoltaic Cells in Tubular Casings,” filed on Mar. 18, 2006, each of which is hereby incorporated by reference herein in its entirety. This application is also a continuation-in-part of U.S. patent application Ser. No. 12/039,659, entitled “A Photovoltaic Apparatus Having a Filler Layer and Method for Making the Same,” filed on Feb. 28, 2008 which, in turn, claims priority to U.S. Patent Application No. 60/906,901 entitled “A Photovoltaic Apparatus Having a Filler Layer and Method for Making the Same,” filed on Mar. 13, 2007, each of which is hereby incorporated by reference herein in its entirety. This application also claims priority to U.S. Patent Application No. 60/975,175, entitled “Photovoltaic Modules Having a Filler Layer,” filed Sep. 26, 2007, which is hereby incorporated by reference herein in its entirety.

### 1. FIELD

This application is directed to photovoltaic module construction and photovoltaic modules made by such construction.

### 2. BACKGROUND

Solar cells are typically fabricated as separate physical entities with light gathering surface areas on the order of 4-6 cm² or larger. For this reason, it is standard practice for power generating applications to mount the photovoltaic modules containing one or more solar cells in a flat array on a supporting substrate or panel so that their light gathering surfaces provide an approximation of a single large light gathering surface. Also, since each solar cell itself generates only a small amount of power, the required voltage and/or current is realized by interconnecting the solar cells of the module in a series and/or parallel matrix.

A conventional prior art photovoltaic module 10 is shown in FIG. 1. A photovoltaic module 10 can typically have one or more photovoltaic cells (solar cells) 12a-b disposed within it. Because of the large range in the thickness of the different layers in a solar cell 12, they are depicted schematically. Moreover, FIG. 1 is highly schematic so that it represents the features of both “thick-film” solar cells 12 and “thin-film” solar cells 12. In general, solar cells 12 that use an indirect band gap material to absorb light are typically configured as “thick-film” solar cells 12 because a thick film of the absorber layer is required to absorb a sufficient amount of light. Solar cells 12 that use a direct band gap material to absorb light are typically configured as “thin-film” solar cells 12 because only a thin layer of the direct band-gap material is needed to absorb a sufficient amount of light.

The arrows at the top of FIG. 1 show the source of direct solar illumination on the photovoltaic module 10. Layer 102 of a solar cell 12 is the substrate. Glass or metal is a common substrate. In some instances, there is an encapsulation layer (not shown) coating the substrate 102. In some embodiments, each solar cell 12 in the photovoltaic module 10 has its own discrete substrate 102 as illustrated in FIG. 1. In other embodiments, there is a substrate 102 that is common to all of the solar cells 12 of the photovoltaic module 10.

Layer 104 is the back electrical contact for a solar cell 12 in photovoltaic module 10. Layer 106 is the semiconductor absorber layer of a solar cell 12 in photovoltaic module 10. In a given solar cell 12, back electrical contact 104 makes ohmic contact with absorber layer 106. In many but not all cases, absorber layer 106 is a p-type semiconductor. Absorber layer 106 is thick enough to absorb light. Layer 108 is the semiconductor junction partner that, together with semiconductor absorber layer 106, completes the formation of a p-n junction of a solar cell 12. A p-n junction is a common type of junction found in solar cells 12. In p-n junction based solar cells 12, when the semiconductor absorber layer 106 is a p-type doped material, the junction partner 108 is an n-type doped material. Conversely, when the semiconductor absorber layer 106 is an n-type doped material, the junction partner 108 is a p-type doped material. Generally, the junction partner 108 is much thinner than the absorber layer 106. The junction partner 108 is highly transparent to solar radiation. The junction partner 108 is also known as the window layer, since it lets the light pass down to the absorber layer 106.

In a typical thick-film solar cells 12, the absorber layer 106 and the window layer 108 can be made from the same semiconductor material but have different carrier types (dopants) and/or carrier concentrations in order to give the two layers their distinct p-type and n-type properties. In thin-film solar cells 12 in which copper-indium-gallium-diselenide (CIGS) is the absorber layer 106, the use of CdS to form the junction partner 108 has resulted in high efficiency photovoltaic devices. The layer 110 is the counter electrode, which completes the functioning solar cell. 12. The counter electrode 110 is used to draw current away from the junction since the junction partner 108 is generally too resistive to serve this function. As such, the counter electrode 110 should be highly conductive and transparent to light. The counter electrode 110 can in fact be a comb-like structure of metal printed onto the layer 108 rather than forming a discrete layer. The counter electrode 110 is typically a transparent conductive oxide (TCO) such as doped zinc oxide. However, even when a TCO layer is present, a bus bar network 114 is typically needed in conventional photovoltaic modules 10 to draw off current since the TCO has too much resistance to efficiently perform this function in larger photovoltaic modules. The network 114 shortens the distance charge carriers must move in the TCO layer in order to reach the metal contact, thereby reducing resistive losses. The metal bus bars, also termed grid lines, can be made of any reasonably conductive metal such as, for example, silver, steel or aluminum. The metal bars are preferably configured in a comb-like arrangement to permit light rays through the TCO layer 110. The bus bar network layer 114 and the TCO layer 110, combined, act as a single metallurgical unit, functionally interfacing with a first ohmic contact to form a current collection circuit.

Optional antireflective coating 112 allows a significant amount of extra light into the solar cell 12. Depending on the intended use of the photovoltaic module 10, it might be deposited directly on the top conductor as illustrated in FIG. 1. Alternatively or additionally, the antireflective coating 112 may be deposited on a separate cover glass that overlays the top electrode 110. Ideally, the antireflective coating 112 reduces the reflection of the solar cell 12 to very near zero over the spectral region in which photoelectric absorption occurs, and at the same time increases the reflection in the other spectral regions to reduce heating. U.S. Pat. No. 6,107,564 to Aguilera et al., hereby incorporated by reference herein in its entirety, describes representative antireflective coatings that are known in the art.

Solar cells 12 typically produce only a small voltage. For example, silicon based solar cells produce a voltage of about 0.6 volts (V). Thus, solar cells 12 are interconnected in series or parallel in order to achieve greater voltages. When connected in series, voltages of individual solar cells add together while current remains the same. Thus, solar cells arranged in series reduce the amount of current flow through such cells, compared to analogous solar cells arranged in parallel, thereby improving efficiency. As illustrated in FIG. 1, the arrangement of solar cells 12 in series is accomplished using interconnects 116. In general, an interconnect 116 places the first electrode of one solar cell 12 in electrical communication with the counter-electrode of an adjoining solar cell 12 of a photovoltaic module 10.

As noted above and as illustrated in FIG. 1, conventional photovoltaic modules 10 are typically in the form of a plate structure. Although such photovoltaic modules 10 are highly efficient when they contain smaller solar cells 12, photovoltaic modules 10 with larger planar solar cells 12 have reduced efficiency because it is harder to make the semiconductor films that form the junction in such solar cells 12 uniform. Furthermore, the occurrence of pinholes and similar flaws increase in larger planar solar cells 12. These features can cause shunts across the junction.

Referring to FIG. 2, light beam L₁ incident on a nonplanar photovoltaic module 10 undergoes optical effects before reaching the active layers of the one or more solar cells 12 in the photovoltaic module 10. Some of the light is reflected as light beam L₂, while some is refracted as light beam L₃ that continues traveling into the layers of a solar cell 12 of the photovoltaic module 10. If light beam L₃ is incident to another boundary between two layers of the solar cell 12 of a photovoltaic module that have different incidences of refraction, the process of reflection and refraction occur again. Light that is reflected does not reach the active layers of the solar cell (e.g., the layers of the solar cell junction) and thus is not used by the solar cell to generate an electric potential. Light that is refracted must be refracted into the junction layers of the solar cells 12 of the photovoltaic module or else it cannot be absorbed. However, the more light that is refracted towards the junction layers of the solar cells 12, the more reflection occurs. Likewise, reducing reflection from the junction layers of the solar cells 12 means light is not strongly refracted towards the junction layers of the solar cells. What are needed in the art are methods and systems optimizing the amount of light incident on junction layers of the solar cells 12 of a photovoltaic module 10.

Discussion or citation of a reference herein will not be construed as an admission that such reference is prior art to the present application.

### 3. SUMMARY

Systems and methods for maximizing the amount of light incident onto a solar cell or photovoltaic module, taking advantage of the effects of reflection and refraction, are provided. The transparent casing, filler material, and transparent conductive layer within a photovoltaic module each have indexes of refraction, and the values for the indexes are chosen so that light incident on the transparent casing is refracted towards the active layers of the solar cells of the photovoltaic module. The values of the refraction indexes are also chosen to reduce the amount of reflection that occurs at the surface boundary of the aforementioned layers.

One aspect provides a photovoltaic module having an elongated substrate. One or more solar cells are disposed on the substrate, and each of the solar cells has a back-electrode disposed on the elongated substrate, a semiconductor junction layer disposed on the back-electrode, and a transparent conductive layer having a first refractive index disposed on the semiconductor junction. A filler material is configured so that it is disposed on the transparent conductive layer of each of the one or more solar cells. The filler material has a second refractive index that is smaller or equal in value to the first refractive index. A transparent casing is disposed on the filler material. In some embodiments, the transparent casing has a third refractive index that is smaller or equal in value to the second refractive index. In some embodiments, the transparent casing has a third refractive index that is greater in value to the second refractive index.

In some embodiments, the second refractive index has a value approximately equal to the third refractive index plus X, where X is half the absolute difference between the values of the first and third refractive indexes. In some embodiments, the third refractive index is slightly more than the second refractive index. In some embodiments, the second refractive index is approximately equal to the first refractive index. In some embodiments, the second refractive index is approximately equal to the third refractive index. In some embodiments the first and second refractive indexes are chosen to minimize the reflection of light on the surface of the transparent conductive layer.

In some embodiments, the third refractive index is in the range of 1.2 to 1.9. In, other embodiments, the third refractive index is in the range of 1.1 to 2. In some embodiments, the second refractive index is in the range of 1.2 to 1.9. In, other embodiments, the second refractive index is approximately equal to 1.6. In some embodiment, the first refractive index is greater or equal to 1.5. In, other embodiments, the first refractive index is greater or equal to 1.6.

In some embodiments, the first, second, and third refractive indexes are chosen such that light incident on the transparent casing is refracted towards a solar cell within the photovoltaic module. In some embodiments, the one or more solar cells on a substrate within the transparent casing of the photovoltaic module each have a first surface area and the transparent casing has a second surface area. In such embodiments, the first, second, and third refractive indexes are chosen such that the one or more solar cells on the substrate within the transparent casing exhibit an effective optical surface area approximately equal to the second surface area. In some embodiments, the second and third refractive indexes are chosen to minimize the reflection of light on the surface of the filler material of the photovoltaic module.

In some embodiments, the photovoltaic module further comprises a water resistant layer disposed on the transparent casing. In some embodiments, an antireflective coating is disposed on the transparent casing. In some embodiments, all or a portion of the substrate is a rigid tube or a rigid solid rod.

In some embodiments, a solar cell in the photovoltaic module is cylindrical shaped and the photovoltaic module obeys the inequality

$${r}_{i} \geq \frac{{r}_{o}}{{η}_{outer ring}}$$

where rᵢ is a radius of the solar cell, rₒ is the radius of the transparent casing of the photovoltaic module, and η_{outer ring} is the second refractive index, the third refractive index, or some combination of the second and third refractive indexes. In some embodiments, the elongated substrate or transparent casing is nonplanar. In some embodiments, the elongated substrate or transparent casing is characterized by a circular cross-section, an ovoid cross-section, a triangular cross-section, a pentangular cross-section, a hexagonal cross-section, a cross-section having at least one arcuate portion, or a cross-section having at least one curved portion.

In some embodiments, a first portion of the elongated substrate or transparent casing is characterized by a first cross-sectional shape and a second portion of the photovoltaic module is characterized by a second cross-sectional shape. In some embodiments, the first cross-sectional shape and the second cross-sectional shape are the same. In other embodiments, the first cross-sectional shape and the second cross-sectional shape are different. In some embodiments, at least ninety percent of the length of the elongated substrate is characterized by the first cross-sectional shape. In some embodiments, the first cross-sectional shape is planar and the second cross-sectional shape has at least one arcuate side. In some embodiments, a cross-section of the elongated substrate or transparent casing forms an n-sided polygon, where n is an integer greater than or equal to 3.

In some embodiments, the elongated substrate has a Young's modulus of 20 GPa or greater. In other embodiments, the elongated substrate has a Young's modulus of 40 GPa or greater. In yet other embodiments, the elongated substrate has a Young's modulus of 70 GPa or greater. In some embodiments, the elongated substrate is made of a linear material.

In some embodiments, the photovoltaic module is elongated, having a longitudinal dimension and a width dimension. In some embodiments, the longitudinal dimension is at least four times greater than the width dimension. In other embodiments, the longitudinal dimension is at least five times greater than the width dimension. In yet other embodiments, the longitudinal dimension is at least six times greater than the width dimension. In some embodiments, the longitudinal dimension is 10 cm or greater. In other embodiments, the longitudinal dimension is 50 cm or greater. In some embodiments, the width dimension is 1 cm or greater. In other embodiments, the width dimension is 5 cm or greater. In yet other embodiments, the width dimension is 10 cm or greater. In some embodiments, the elongated substrate is closed at both ends, only at one end, or open at both ends.

In some embodiments, a first solar cell and a second solar cell in a photovoltaic module are electrically arranged in series. In other embodiments, a first solar cell and a second solar cell in a plurality of solar cell in a photovoltaic module are electrically arranged in parallel. Another aspect of the invention provides an assembly comprising a plurality of photovoltaic modules, each of which is arranged in coplanar rows to form the assembly. In some embodiments, the assembly further comprises an albedo surface positioned to reflect sunlight into the plurality of photovoltaic modules of the assembly. In some embodiments, the albedo surface has an albedo that exceeds 80%. In other embodiments, the albedo surface is Lambertian or diffuse.

### 4. BRIEF DESCRIPTION OF THE DRAWINGS

FIG. 1 illustrates interconnected solar cells in a photovoltaic module in accordance with the prior art.

FIG. 2 illustrates a partial cross-sectional view of an elongated photovoltaic module in a casing, in accordance with an embodiment of the present application.

FIG. 3A illustrates a photovoltaic module with a tubular casing, in accordance with an embodiment of the present application.

FIG. 3B illustrates a cross-sectional view of an exemplary photovoltaic module, in accordance with an embodiment of the present application.

FIG. 3C illustrates the multi-layer components of a photovoltaic module in accordance with an embodiment of the present application.

FIG. 3D illustrates a transparent casing, in accordance with an embodiment of the present application.

FIG. 3E illustrates a photovoltaic module comprising multiple solar cells disposed on an elongated substrate in accordance with an embodiment of the present application.

FIG. 4A is a cross-sectional view of photovoltaic modules in tubular casings that are electrically arranged in series and geometrically arranged in a parallel or near parallel manner, in accordance with an embodiment of the present application.

FIG. 4B is a cross-sectional view taken about line 4B-4B of FIG. 4A depicting the serial electrical arrangement of photovoltaic modules in an assembly, in accordance with an embodiment of the present application.

FIG. 4C is a blow-up perspective view of region 4C of FIG. 4B, illustrating various layers in an exemplary photovoltaic module, in accordance with one embodiment of the present application.

FIG. 4D is a cross-sectional view of a photovoltaic module taken about line 4D-4D of FIG. 4B, in accordance with an embodiment of the present application.

FIGS. 5A-5D illustrate semiconductor junctions that are used in various solar cells in various embodiments of the present application.

FIG. 6A illustrates an extrusion blow molding method in accordance with the prior art.

FIG. 6B illustrates an injection blow molding method in accordance with the prior art.

FIG. 6C illustrates a stretch blow molding method in accordance with the prior art.

FIG. 7 is a perspective view an array of transparent casings, in accordance with an embodiment disclosed herein.

FIG. 8 is a cross-sectional view of photovoltaic modules electrically arranged in series in an assembly where counter-electrodes abut individual photovoltaic modules and the outer TCO is cut, in accordance with another embodiment disclosed herein.

FIG. 9 is a cross-sectional view of photovoltaic modules each having an elongated substrate electrically arranged in series in an assembly in which the substrate is hollowed, in accordance with an embodiment disclosed herein.

FIG. 10 is a cross-sectional view of photovoltaic modules each having an elongated substrate electrically arranged in series in an assembly in which a groove pierces the counter-electrodes, transparent conducting layer, and junction layers of the photovoltaic modules, in accordance with an embodiment disclosed herein.

FIG. 11 illustrates a static concentrator for use in some embodiments of the present application.

FIG. 12 illustrates a static concentrator used in some embodiments disclosed herein.

FIG. 13 illustrates a cross-sectional view of a photovoltaic module in accordance with an embodiment disclosed herein.

FIG. 14 illustrates a cross-sectional view of an array of alternating tubular casings and internal reflectors, in accordance with an embodiment disclosed herein.

FIG. 15A illustrates a suction loading assembly method in accordance with an embodiment disclosed herein.

FIG. 15B illustrates a pressure loading assembly method in accordance with an embodiment disclosed herein.

FIG. 15C illustrates a pour-and-slide loading assembly method in accordance with an embodiment disclosed herein.

FIG. 16 illustrates Q-type silicone, silsequioxane, D-type silicon, and M-type silicon, in accordance with the prior art.

FIGS. 17A-17K illustrates a hermetically sealed elongated photovoltaic module, in accordance with some embodiments of the present application.

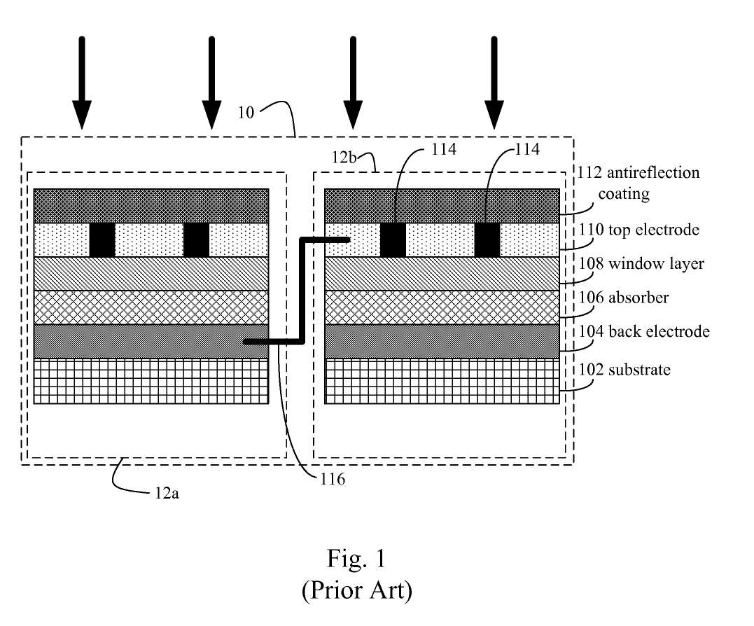

Like reference numerals refer to corresponding parts throughout the several views of the drawings. Dimensions are not drawn to scale.

### 5. DETAILED DESCRIPTION

A photovoltaic module having an elongated substrate is provided. A portion of the elongated substrate is rigid. One or more solar cells are disposed on the elongated substrate. The one or more solar cells each comprise (i) a back-electrode disposed on the elongated substrate, (ii) a semiconductor junction layer disposed on the back-electrode, (iii) and a transparent conductive layer disposed on the semiconductor junction, where the transparent conductive layer has a first refractive index. A filler material is disposed on the transparent conductive layer. The filler material has a second refractive index that is smaller or equal in value to said first refractive index. A transparent casing is disposed on the filler material thereby sealing the photovoltaic module. In some embodiments, the transparent casing has a third refractive index that is smaller or equal in value to the second refractive index. In some embodiments, the transparent casing has a third refractive index that is larger in value to the second refractive index.

### 5.1 Basic Structure

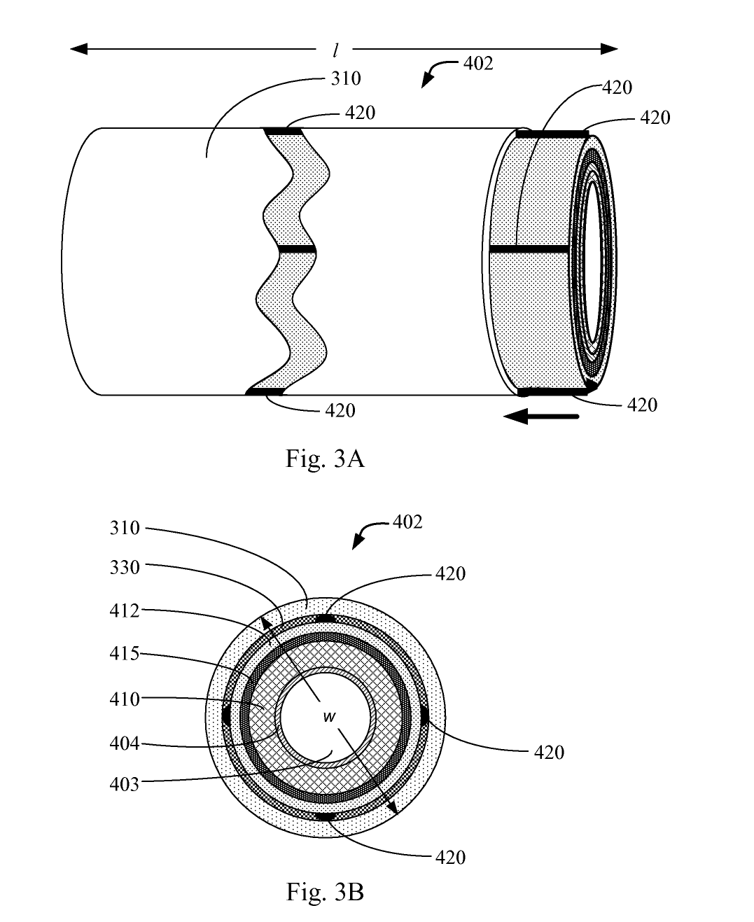

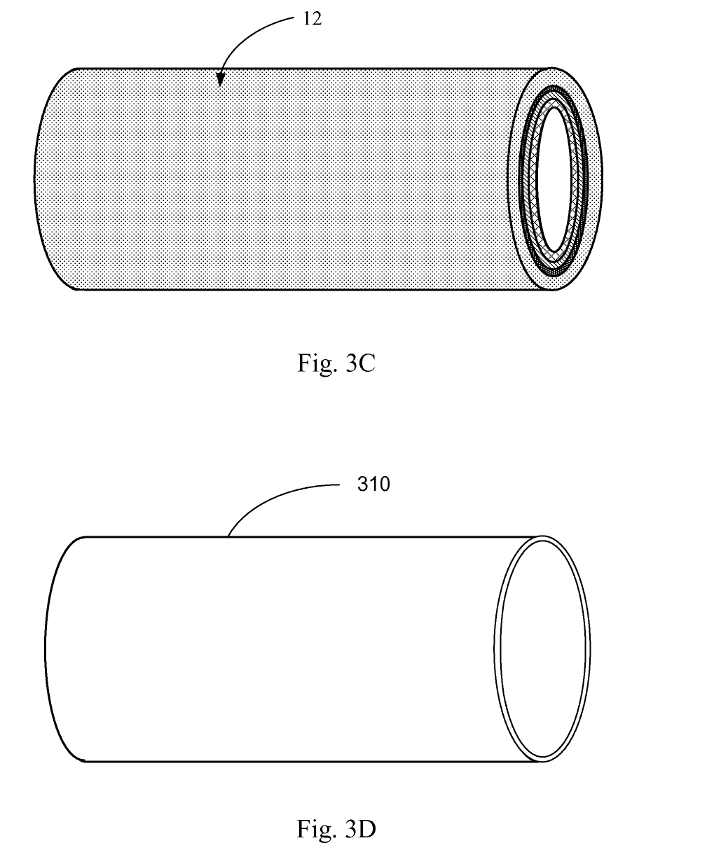

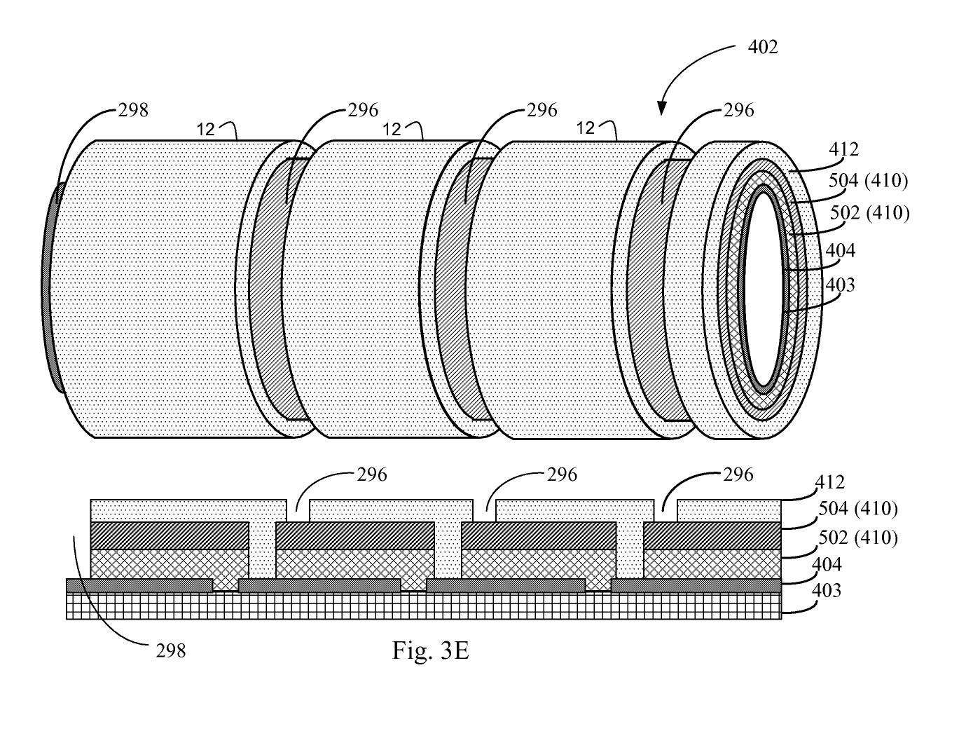

The present application provides individually covered photovoltaic modules 402 that are illustrated in perspective view in FIG. 3A and cross-sectional view in FIG. 3B. In one embodiment of a photovoltaic module 402, one (FIG. 3C) or more (FIG. 3E) solar cells 12 are covered by a transparent casing 310 (FIG. 3D). In some embodiments, one end of the photovoltaic module 402 is exposed by the transparent casing 310 in order to form an electrical connection with solar cells 12 of an adjacent photovoltaic module 402 or other circuitry. In some embodiments, both ends of the photovoltaic module 402 are exposed by the transparent casing 310 in order to form an electrical connection with solar cells 12 of adjacent photovoltaic modules 402 or other circuitry.

In some embodiments, the transparent casing 310 has a cylindrical shape. As used herein, the term “cylindrical” means objects having a cylindrical or approximately cylindrical shape. In fact, cylindrical objects can have irregular shapes so long as the object, taken as a whole, is roughly cylindrical. Such cylindrical shapes can be solid (e.g., a rod) or hollowed (e.g., a tube). As used herein, the term “tubular” means objects having a tubular or approximately tubular shape. In fact, tubular objects can have irregular shapes so long as the object, taken as a whole, is roughly tubular.

Although photovoltaic modules 402 in the context of either the encapsulated embodiments or circumferentially covered embodiments are described in detail, the application is not limited to such embodiments. Any transparent casing that provides support and protection to solar cells 12 and permits electrical connections between the solar cells 12 is within the scope of the systems and methods of the present application.

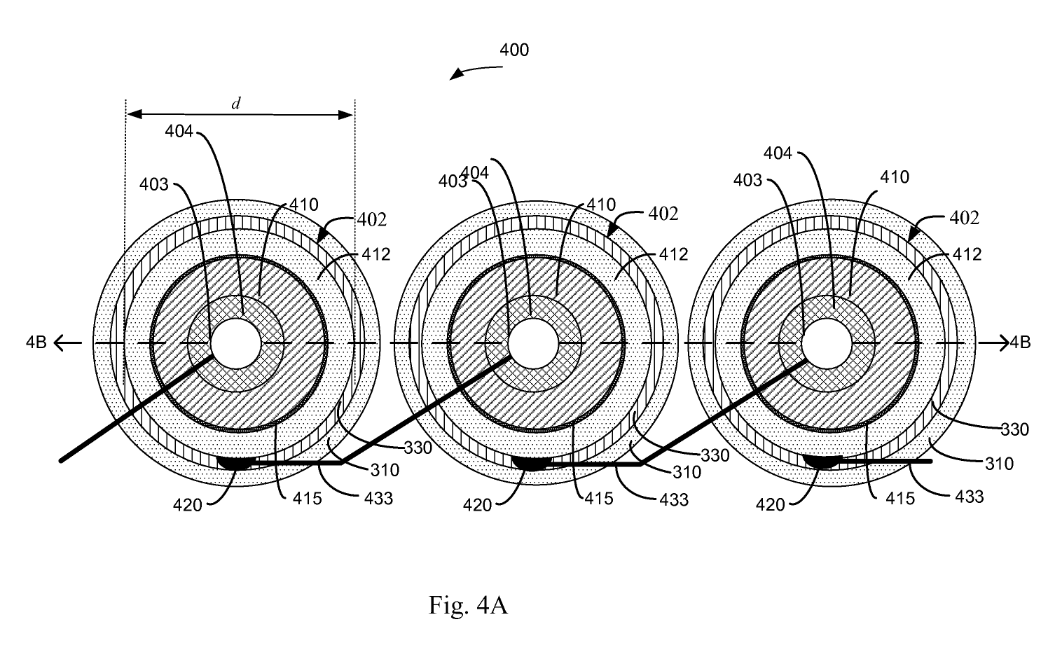

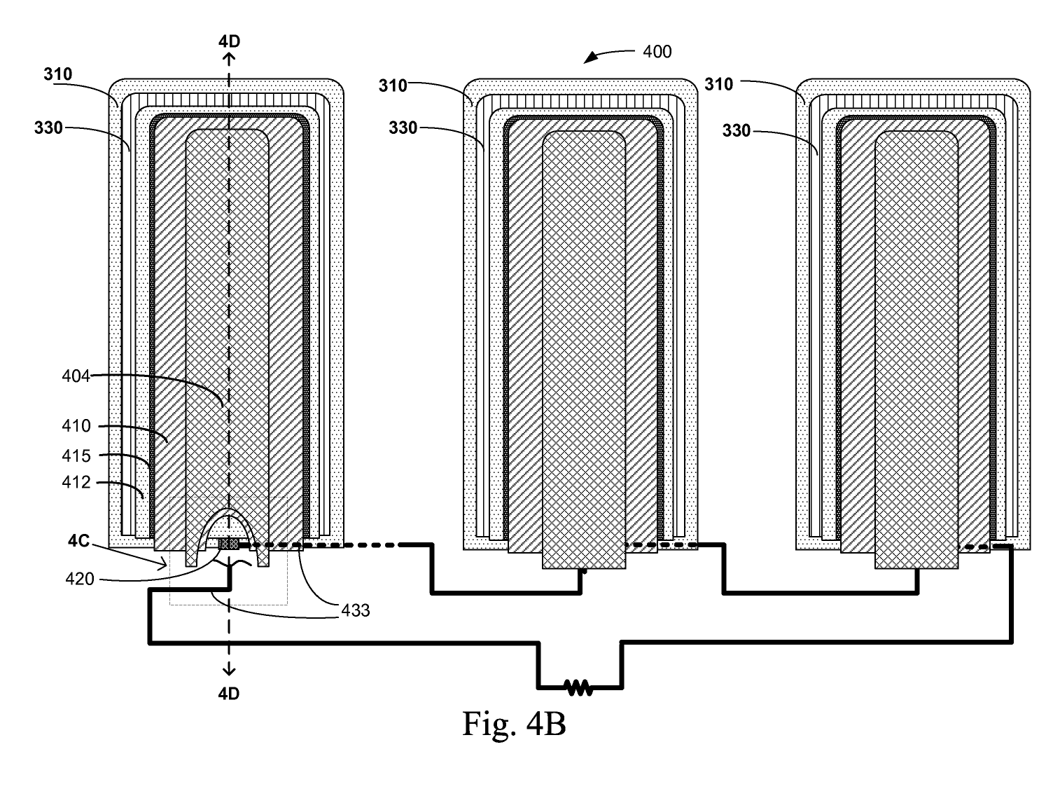

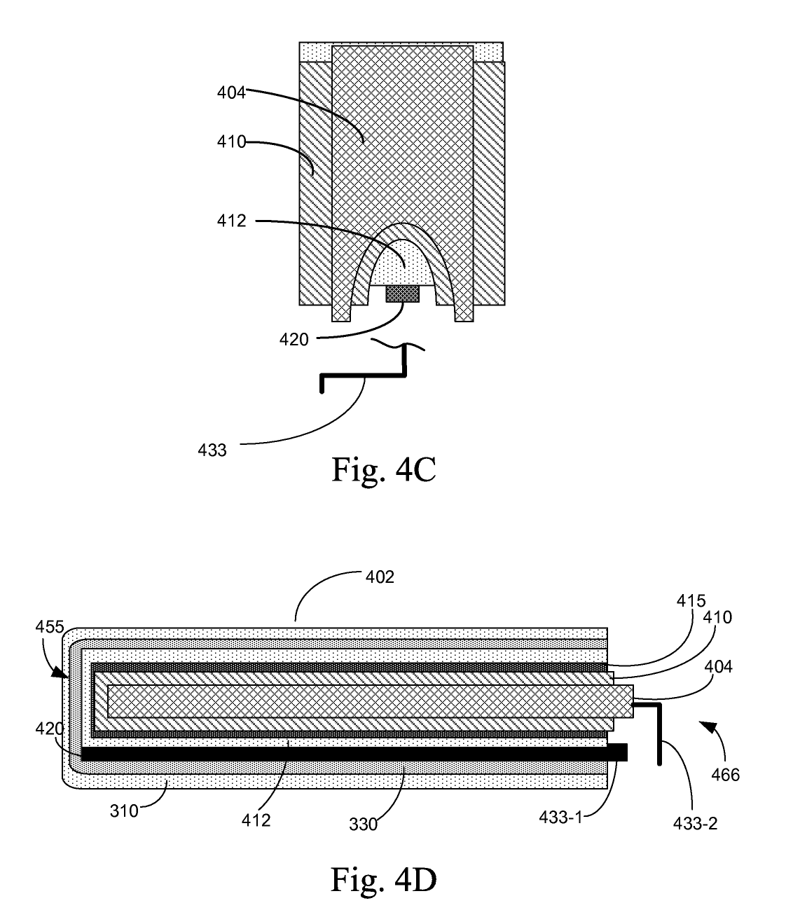

FIG. 3B illustrates the cross-sectional view of an exemplary embodiment of a photovoltaic module 402. Other exemplary embodiments of photovoltaic modules (e.g., 402 in FIG. 4A) are also suitable for coating by a transparent casing 310. FIGS. 3A and 3B illustrate a case in which there is a single solar cell 12 in a photovoltaic module 402. More typically, there are several solar cells 12 on a common substrate within a photovoltaic module 402. FIG. 3E illustrates one such photovoltaic module 402 that contains several solar cells 12 disposed on a common elongated substrate 403. In FIG. 3E, individual solar cells 12 are separated on elongated substrate 403 by separations 296. More disclosure of exemplary photovoltaic modules 402 that have multiple solar cells 12 is found in U.S. Pat. No. 7,235,736, which is hereby incorporated by reference herein in its entirety. In the present application, the solar cells 12 may be disposed on a nonplanar elongated substrate 403 as illustrated in FIG. 3E or on a planar substrate.

Elongated substrate 403. An elongated elongated substrate 403 serves as a substrate for one or more solar cells 12. In some embodiments, the elongated substrate 403 is made of a plastic, metal, metal alloy, or glass. In some embodiments, as illustrated in FIG. 3E, the elongated substrate 403 is cylindrical shaped. In some embodiments, the elongated substrate 403 has a hollow core, as illustrated in FIG. 3B. In some embodiments, the elongated substrate 403 has a solid core. In some embodiments, the shape of the elongated substrate 403 is only approximately that of a cylindrical object, meaning that a cross-section taken at a right angle to the long axis of the elongated substrate 403 defines an ellipse rather than a circle. As the term is used herein, such approximately shaped objects are still considered cylindrically shaped in the present application. In some embodiments, the elongated substrate 403 supports one or more solar cells 12 arranged in a bifacial, multi-facial, or omnifacial manner. Thus, in some embodiments, the elongated substrate 403 is flat planar while in other embodiments the elongated substrate 403 is nonplanar. More description of the elongated substrate 403 is found in Section 5.9, below.

Back-electrode 404. A back-electrode 404 is disposed over all or a portion of the elongated substrate 403. By “a portion of” it is meant at least 20%, or at least 30%, or at least 40%, or at least 50%, or at least 60%, or at least 70%, or at least 80%, or at least 90%, or at least 95% of the surface area of the elongated substrate 403. The back-electrode 404 serves as the first electrode for each solar cell 12 in the photovoltaic module 402. In general, the back-electrode 404 is made out of any material such that it can support the photovoltaic current generated by the solar cell 12 with negligible resistive losses. Additional disclosure on the back-electrode 404 is found in Section 5.11, below.

Semiconductor junction 410. A semiconductor junction 410 is disposed on all or a portion of the back-electrode 404. By “a portion of” it is meant at least 20%, or at least 30%, or at least 40%, or at least 50%, or at least 60%, or at least 70%, or at least 80%, or at least 90%, or at least 95% of the surface area of the back-electrode 404. The semiconductor junction 410 is any photovoltaic homojunction, heterojunction, heteroface junction, buried homojunction, p-i-n junction or tandem junction having an absorber layer that is a direct band-gap absorber (e.g., crystalline silicon) or an indirect band-gap absorber (e.g., amorphous silicon). Such junctions are described in Chapter 1 of Bube, Photovoltaic Materials, 1998, Imperial College Press, London, as well as Lugue and Hegedus, 2003, Handbook of Photovoltaic Science and Engineering, John Wiley & Sons, Ltd., West Sussex, England, each of which is hereby incorporated by reference herein in its entirety. Details of exemplary types of semiconductors junctions 410 in accordance with the present application are disclosed in Section 5.2, below. In addition to the exemplary junctions disclosed in Section 5.2, below, the junctions 410 can be multijunctions in which light traverses into the core of the junction 410 through multiple junctions that, preferably, have successfully smaller band gaps. In some embodiments, the semiconductor junction 410 includes a copper-indium-gallium-diselenide (CIGS) absorber layer. In some embodiments, the semiconductor junction 410 is a so-called thin film semiconductor junction. In some embodiments, the semiconductor junction 410 is a so-called thick film (e.g., silicon) semiconductor junction.

Optional intrinsic layer 415. Optionally, there is a thin intrinsic layer (i-layer) 415 disposed on all or a portion of the semiconductor junction 410. By “a portion of,” it is meant at least 20%, or at least 30%, or at least 40%, or at least 50%, or at least 60%, or at least 70%, or at least 80%, or at least 90%, or at least 95% of the exposed surface area of the semiconductor junction 410. The i-layer 415 can be formed using any undoped transparent oxide including, but not limited to, zinc oxide, metal oxide, or any transparent material that is highly insulating. In some embodiments, the i-layer 415 is highly pure zinc oxide.

Transparent conductive layer 412. The transparent conductive layer 412 is disposed on all or a portion of semiconductor junction 410 thereby completing the circuit of each solar cell 12. By “a portion of” it is meant at least 20%, or at least 30%, or at least 40%, or at least 50%, or at least 60%, or at least 70%, or at least 80%, or at least 90%, or at least 95% of the exposed surface area of the semiconductor junction 410. As noted above, in some embodiments, a thin i-layer 415 is disposed on the semiconductor junction 410. In such embodiments, the transparent conductive layer 412 is disposed on all or a portion of the i-layer 415. Additional disclosure on the transparent conductive layer 412 is found in Section 5.12, below

Optional electrode strips 420. In some embodiments in accordance with the present application, optional counter-electrode strips or leads 420 are disposed on the transparent conductive layer 412 in order to facilitate electrical current flow. Additional disclosure on the optional electrode strips 420 is found in Section 5.10, below.

Transparent casing 310. A transparent casing 310 is disposed on all or a portion of the transparent conductive layer 412 and/or the filler material detailed below 330. In some embodiments, the transparent casing 310 is made of plastic or glass. In some embodiments, the solar cells 12 of a photovoltaic module 402 are sealed in the transparent casing 310. As shown in FIG. 4A, a transparent casing 310 fits over the outermost layer of the photovoltaic module 402. In some embodiments, the photovoltaic module 402 is inside the transparent casing 310 such that adjacent photovoltaic modules 402 do not form electric contact with each other except at the ends of the photovoltaic modules 402. Methods, such as heat shrinking, injection molding, or vacuum loading, can be used to construct the transparent casing 310 such that they exclude oxygen and water from the system as well as provide complementary fitting to the underlying photovoltaic module 402. Additional disclosure on the transparent casing 310 is found in Section 5.13, below.

Filler material 330. In some embodiments of the present application, as depicted in FIG. 3B, a filler material 330 is disposed between transparent conducting layer 412 and the transparent casing 310. The filler material 330 can be used to protect the photovoltaic module 402 from physical or other damage, and can also be used to aid the photovoltaic module 402 in collecting more light by its optical and chemical properties.

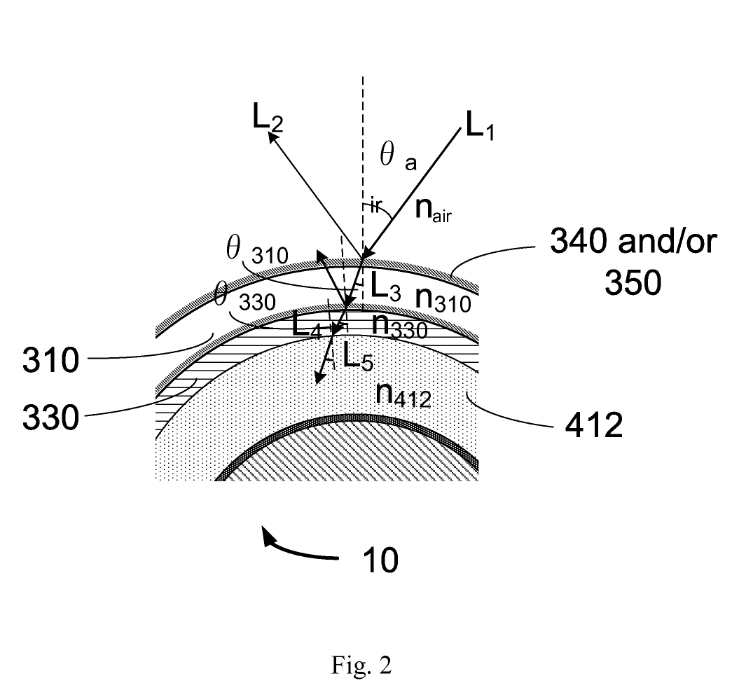

Refractive Properties of Components 310, 330 and 412. As depicted in FIG. 2, part of incident beam L₁ is refracted as refracted beam L₃. How much and to which direction incident beam L₁ is bent from its path is determined by the refractive indices of the media in which beams L₁ and L₃ travel. Snell's Law specifies:

η₁ sin(θ₁)=η₂ sin(θ₂),

where η₁ and η₂ are the refractive indices of the two bordering media 1 and 2 while θ₁ and θ₂ represent the angle of incidence and the angle of refraction, respectively.

In FIG. 2, the first refraction process occurs when incident beam L₁ travels from air through the transparent casing 310 as L₃. Ambient air has a refractive index around 1 (vacuum space has a refractive index of 1, which is the smallest among all known materials), which is much smaller than the refractive index of glass material (ranging from 1.2 to 1.9) or plastic material (around 1.45). Because ηₐᵢᵣ is always smaller than η₃₁₀ whether the transparent casing 310 is formed by glass or plastic material, the refractive angle θ₃₁₀ is always smaller than the incident angle θₐᵢᵣ, e.g., the incident beam is always bent towards the interior of photovoltaic module 402 as it travels through the transparent casing 310.

In the presence of the filler material 330, beam L₃ becomes the new incident beam that impinges upon the surface of the filler material 330, and L₄ is the new refracted beam that travels through the filler material 330. Ideally, according to Snell's Law and the preceding analysis, the refractive index of the filler material 330 (e.g., η₃₃₀ in FIG. 2) should be larger than the refractive index of the transparent casing 310 so that refracted beam L₄ will also be bent towards the interior layers of the solar cells 12 of the photovoltaic module 402. L₄ itself becomes the incident beam that strikes the surface of the layers of the solar cells 12 of the photovoltaic module 402 (specifically, the transparent conductive layer 412), and is refracted yet again into beam L₅ in transparent conductive layer 412. Ideally, the refractive index of transparent conductive layer 412, η₄₁₂, should be larger than η₃₃₀ so that refracted beam L₅ is also bent towards interior layers of the solar cells 12 of the photovoltaic module 402.

In this ideal situation, a portion of the incident beam on the transparent casing 310 will be bent towards interior layers of the solar cells 12 of the photovoltaic module 402 after several refraction processes while the remainder of the incident beam will be reflected. If the refractive indices are matched exactly, there will be no reflective losses and all of the incident beam will be bent towards interior layers of the solar cells 12. In to achieve the ideal situation in which at least a portion of the incident beam is refracted towards interior layers of the solar cells 12, the refractive indexes of the various layers preferably have magnitudes that obey the following inequality:

ηₐᵢᵣ≦η₃₁₀≦η₃₃₀≦η₄₁₂

The refractive index of air is approximately 1. In some embodiments, materials that form the transparent casing 310 comprise transparent materials (either glass or plastic or other suitable materials) with refractive indices between approximately 1.2 and 1.9. In some embodiments, the material that forms the transparent casing 310 has a refractive index between 1.1 and 2. For example, fused silica glass has a refractive index of 1.46. Common plastic materials have refractive indices between 1.46 and 1.55. In some embodiments, the refractive index of the transparent conductive layer 412 is approximately 1.9. In some embodiments, the refractive index of the transparent conductive layer 412 is greater or equal to 1.5, or greater or equal to 1.6. Therefore, in order to achieve inwards refraction, the refractive index of the filler material 330 is typically larger than the refractive index of the transparent casing 310 and smaller than the refractive index of the transparent conductive layer 412 (e.g. 1.2<η₃₃₀<1.9 where η₃₁₀=1.2 and η₄₁₂=1.9).

Reflection and refraction are inter-related phenomenon. Fresnel's equations describe the intensity of reflected waves and refracted waves when an electromagnetic wave strikes an interface between two materials. According to Fresnel's equations in the special case of an incident wave that is normal (perpendicular) to the surface, the reflection coefficient R and transmission (refracted wave) coefficient T are:

$$R = {( \frac{{η}_{1} - {η}_{2}}{{η}_{1} + {η}_{2}} )}^{2} ; T = \frac{4 {η}_{1} {η}_{2}}{{( {η}_{1} + {η}_{2} )}^{2}}$$

where η₁ and η₂ are the refractive indices of the two bordering media 1 and 2. As can be seen, when η₂ is much larger than η₁, the reflection coefficient R becomes larger. This means that more light is reflected (and thus less light refracted by transmission) when the difference between the refractive indexes is larger than when the difference is smaller. This extends beyond the special case of normal incidence and affects all incident beams regardless of the angle of incidence. So, although a larger difference in value between refractive indexes of components 310, 330, and 412 will result in a higher degree of refraction towards interior layers of the solar cells 12 of the photovoltaic module 402, it also results in more reflection of light away from interior layers of the solar cells 12 of the photovoltaic module 402. These two competing effects are preferably balanced in order to achieve maximum exposure of interior layers of the solar cells 12 (e.g., junction 410 of solar cells 12) of the photovoltaic module 402 to light.

One method of balancing these effects is to choose the compositions that the filler material 330 is composed of based on the refractive index of the material. In some embodiments, a value of η₃₃₀ is chosen such that the aggregate reflection of light at the interface between the components 310 and 330 and components 330 and 412 is minimized. In some embodiments, η₃₃₀ is chosen to be approximately halfway between η₃₁₀ and η₄₁₂. For example, if η₃₁₀=1.2 and η₄₁₂=1.9, then η₃₃₀ would be chosen to be approximately 1.55. In other embodiments, η₃₃₀ is chosen to be approximately equal to either one of η₃₁₀ or η₄₁₂. For example, when η₃₃₀ is approximately equal to η₃₁₀, there is very little reflection or refraction that occurs at the interface between the transparent casing 310 and the filler material 330. This means that the interface does not noticeably alter the trajectory or intensity of light passing through the interface. Thus it is only at the interface between the filler material 330 and the transparent conductive layer 412 where light is reflected and refracted.

In some embodiments, a given index of refraction is approximately equal to a reference index of refraction when the given index of refraction is within 0.5, within 0.4, within 0.3, within 0.2, 0.1, with 0.05, or with 001 units of the reference index of refraction. For example, consider the case where the given index of refraction is x, the reference index of refraction is y, and the term “approximately equal” in accordance with one embodiment is 0.1. In this case, y−0.1≦x≦y+0.1. On the other hand, if the term “approximately equal” in accordance with one embodiment is 0.2, y−0.2≦x≦y+0.2, and so forth.

Reflective properties of components 310 and 330. Referring to FIG. 2, an incident beam L₁ hits the surface of the transparent casing 310. Part of the incident beam L₁ is reflected as L₂ while the remainder of incident beam L₁ (e.g., as refracted beam L₃ in FIG. 2) travels through the transparent casing 310. In some embodiments in accordance with the present application, the refracted beam L₃ directly impinges upon the transparent conductive layer 412 of a solar cell 12 of photovoltaic module 402 (e.g., when the filler material 330 is absent). Alternatively, when the filler material 330 is present, as depicted in FIG. 2, L₃ hits the outer surface of the filler material 330, and the processes of reflection and refraction are repeated as they were when L₁ hit the surface of the transparent casing 310, with some of L₃ reflected back into the filler material 330 and some of L₃ refracted by the filler material 330 as beam L₄.

In order to maximize input of solar radiation, reflection at the outer surface of the transparent casing 310 is minimized in some embodiments. Antireflective coating, either as a separate layer 350 or in combination with the water resistant coating 340, may be applied on the outside of the transparent casing 310. In some embodiments, this antireflective coating is made of MgF₂. In some embodiments, this antireflective coating is made of silicon nitride or titanium nitride. In other embodiments, this antireflective coating is made of one or more layers of silicon monoxide (SiO). For example, shiny silicon can act as a mirror and reflects more than thirty percent of the light that shines on it. A single layer of SiO reduces surface reflection to about ten percent, and a second layer of SiO can lower the reflection to less than four percent. Other organic antireflective materials, in particular, one which prevents back reflection from the surface of or lower layers in the semiconductor device and eliminates the standing waves and reflective notching due to various optical properties of lower layers on the wafer and the photosensitive film, are disclosed in U.S. Pat. No. 6,803,172, which is hereby incorporated by reference herein in its entirety. Additional antireflective coating materials and methods are disclosed in U.S. Pat. Nos. 6,689,535; 6,673,713; 6,635,583; 6,784,094; and 6,713,234, each of which is hereby incorporated by reference herein in its entirety.

Alternatively, the outer surface of the transparent casing 310 may be textured to reduce reflected radiation. Chemical etching creates a pattern of cones and pyramids, which capture light rays that might otherwise be deflected away from the cell. Reflected light is redirected down into the cell, where it has another chance to be absorbed. Material and methods for creating an anti-reflective layer by etching or by a combination of etching and coating techniques are disclosed in U.S. Pat. Nos. 6,039,888; 6,004,722; and 6,221,776; each of which is hereby incorporated by reference herein in its entirety.

Chemical composition of the filler material 330. The filler material 330 can be made of sealant such as ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, and/or a urethane is coated over the transparent conductive layer 412 to seal out air and, optionally, to provide complementary fitting to a transparent casing 310. In some embodiments, the filler material 330 is a Q-type silicone, a silsequioxane, a D-type silicone, or an M-type silicone. Filler material 330 can be, for example, a gel or a liquid.

In one embodiment, the substance used to form the filler material 330 comprises a resin or resin-like substance, the resin potentially being added as one component, or added as multiple components that interact with one another to effect a change in viscosity. In another embodiment, the resin can be diluted with a less viscous material, such as a silicone-based oil or liquid acrylates. In these cases, the viscosity of the initial substance can be far less than that of the resin material itself.

In one example, a medium viscosity polydimethylsiloxane mixed with an elastomer-type dielectric gel can be used to make the filler material 330. In one case, as an example, a mixture of 85% (by weight) Dow Corning 200 fluid, 50 centistoke viscosity (PDMS, polydimethylsiloxane); 7.5% Dow Corning 3-4207 Dielectric Tough Gel, Part A—Resin; and 7.5% Dow Corning 3-4207 Dielectric Tough Gel, Part B—Catalyst is used to form the filler material 330. Other oils, gels, or silicones can be used to produce much of what is described in the specification, and accordingly this specification should be read to include those other oils, gels and silicones to generate the described layer. Such oils include silicone based oils, and the gels include many commercially available dielectric gels. Curing of silicones can also extend beyond a gel like state. Commercially available dielectric gels and silicones and the various formulations are contemplated as being usable in this application.

In one example, the composition used to form the filler material 330 is 85%, by weight, polydimethylsiloxane polymer liquid, where the polydimethylsiloxane has the chemical formula (CH₃)₃SiO[SiO(CH₃)₂]ₙSi(CH₃)₃, where n is a range of integers chosen such that the polymer liquid has an average bulk viscosity that falls in the range between 50 centistokes and 100,000 centistokes (all viscosity values given in this application for compositions assume that the compositions are at room temperature). Thus, there may be polydimethylsiloxane molecules in the polydimethylsiloxane polymer liquid with varying values for n provided that the bulk viscosity of the liquid falls in the range between 50 centistokes and 100,000 centistokes. Bulk viscosity of the polydimethylsiloxane polymer liquid may be determined by any of a number of methods known to those of skill in the art, such as using a capillary viscometer. Further, the composition includes 7.5%, by weight, of a silicone elastomer comprising at least sixty percent, by weight, dimethylvinyl-terminated dimethyl siloxane (CAS number 68083-19-2) and between 3 and 7 percent by weight silicate (New Jersey TSRN 14962700-537 6P). Further, the composition includes 7.5%, by weight, of a silicone elastomer comprising at least sixty percent, by weight, dimethylvinyl-terminated dimethyl siloxane (CAS number 68083-19-2), between ten and thirty percent by weight hydrogen-terminated dimethyl siloxane (CAS 70900-21-9) and between 3 and 7 percent by weight trimethylated silica (CAS number 68909-20-6).

In some embodiments, the filler material 330 is formed by soft and flexible optically suitable material such as silicone gel. For example, in some embodiments, the filler material 330 is formed by a silicone gel such as a silicone-based adhesives or sealants. In some embodiments, the filler material 330 is formed by GE RTV 615 Silicone. Silicone-based adhesives or sealants are based on tough silicone elastomeric technology. The characteristics of silicone-based materials, such as adhesives and sealants, are controlled by three factors: resin mixing ratio, potting life and curing conditions.

Advantageously, silicone adhesives have a high degree of flexibility and very high temperature resistance (up to 600° F.). Silicone-based adhesives and sealants have a high degree of flexibility. Silicone-based adhesives and sealants are available in a number of technologies (or cure systems). These technologies include pressure sensitive, radiation cured, moisture cured, thermo-set and room temperature vulcanizing (RTV). In some embodiments, the silicone-based sealants use two-component addition or condensation curing systems or single component (RTV) forms. RTV forms cure easily through reaction with moisture in the air and give off acid fumes or other by-product vapors during curing.

Pressure sensitive silicone adhesives adhere to most surfaces with very slight pressure and retain their tackiness. This type of material forms viscoelastic bonds that are aggressively and permanently tacky, and adheres without the need of more than finger or hand pressure. In some embodiments, radiation is used to cure silicone-based adhesives. In some embodiments, ultraviolet light, visible light or electron bean irradiation is used to initiate curing of sealants, which allows a permanent bond without heating or excessive heat generation. While UV-based curing requires one substrate to be UV transparent, the electron beam can penetrate through material that is opaque to UV light. Certain silicone adhesives and cyanoacrylates based on a moisture or water curing mechanism may need additional reagents properly attached to the photovoltaic module 402 without affecting the proper functioning of the photovoltaic module 402. Thermo-set silicone adhesives and silicone sealants are cross-linked polymeric resins cured using heat or heat and pressure. Cured thermo-set resins do not melt and flow when heated, but they may soften. Vulcanization is a thermosetting reaction involving the use of heat and/or pressure in conjunction with a vulcanizing agent, resulting in greatly increased strength, stability and elasticity in rubber-like materials. RTV silicone rubbers are room temperature vulcanizing materials. The vulcanizing agent is a cross-linking compound or catalyst. In some embodiments in accordance with the present application, sulfur is added as the traditional vulcanizing agent.

In one example, the composition used to form the filler material 330 is silicone oil mixed with a dielectric gel. The silicone oil is a polydimethylsiloxane polymer liquid, whereas the dielectric gel is a mixture of a first silicone elastomer and a second silicone elastomer. As such, the composition used to form the filler material 330 is X %, by weight, polydimethylsiloxane polymer liquid, Y %, by weight, a first silicone elastomer, and Z %, by weight, a second silicone elastomer, where X, Y, and Z sum to 100. Here, the polydimethylsiloxane polymer liquid has the chemical formula (CH₃)₃SiO[SiO(CH₃)₂]ₙSi(CH₃)₃, where n is a range of integers chosen such that the polymer liquid has an average bulk viscosity that falls in the range between 50 centistokes and 100,000 centistokes. Thus, there may be polydimethylsiloxane molecules in the polydimethylsiloxane polymer liquid with varying values for n provided that the bulk viscosity of the liquid falls in the range between 50 centistokes and 100,000 centistokes. The first silicone elastomer comprises at least sixty percent, by weight, dimethylvinyl-terminated dimethyl siloxane (CAS number 68083-19-2) and between 3 and 7 percent by weight silicate (New Jersey TSRN 14962700-537 6P). Further, the second silicone elastomer comprises at least sixty percent, by weight, dimethylvinyl-terminated dimethyl siloxane (CAS number 68083-19-2), between ten and thirty percent by weight hydrogen-terminated dimethyl siloxane (CAS 70900-21-9) and between 3 and 7 percent by weight trimethylated silica (CAS number 68909-20-6). In this embodiment, X may range between 30 and 90, Y may range between 2 and 20, and Z may range between 2 and 20, provided that X, Y and Z sum to 100 percent.

In another example, the composition used to form the filler material 330 is silicone oil mixed with a dielectric gel. The silicone oil is a polydimethylsiloxane polymer liquid, whereas the dielectric gel is a mixture of a first silicone elastomer and a second silicone elastomer. As such, the composition used to form the filler material 330 is X %, by weight, polydimethylsiloxane polymer liquid, Y %, by weight, a first silicone elastomer, and Z %, by weight, a second silicone elastomer, where X, Y, and Z sum to 100. Here, the polydimethylsiloxane polymer liquid has the chemical formula (CH₃)₃SiO[SiO(CH₃)₂]ₙSi(CH₃)₃, where n is a range of integers chosen such that the polymer liquid has a volumetric thermal expansion coefficient of at least 500×10⁻⁶/° C. Thus, there may be polydimethylsiloxane molecules in the polydimethylsiloxane polymer liquid with varying values for n provided that the polymer liquid has a volumetric thermal expansion coefficient of at least 960×10⁻⁶/° C. The first silicone elastomer comprises at least sixty percent, by weight, dimethylvinyl-terminated dimethyl siloxane (CAS number 68083-19-2) and between 3 and 7 percent by weight silicate (New Jersey TSRN 14962700-537 6P). Further, the second silicone elastomer comprises at least sixty percent, by weight, dimethylvinyl-terminated dimethyl siloxane (CAS number 68083-19-2), between ten and thirty percent by weight hydrogen-terminated dimethyl siloxane (CAS 70900-21-9) and between 3 and 7 percent by weight trimethylated silica (CAS number 68909-20-6). In this embodiment, X may range between 30 and 90, Y may range between 2 and 20, and Z may range between 2 and 20, provided that X, Y and Z sum to 100 percent.

In some embodiments, the composition used to form the filler material 330 is a crystal clear silicone oil mixed with a dielectric gel. In some embodiments, the filler material 330 has a volumetric thermal coefficient of expansion of greater than 250×10⁻⁶/° C., greater than 300×10⁻⁶/° C., greater than 400×10⁻⁶/° C., greater than 500×10⁻⁶/° C., greater than 1000×10⁻⁶/° C., greater than 2000×10⁻⁶/° C., greater than 5000×10⁻⁶/° C., or between 250×10⁻⁶/° C. and 1 0000×10⁻⁶/° C.

In some embodiments, a silicone-based dielectric gel can be used in-situ. The dielectric gel can also be mixed with a silicone based oil to reduce both beginning and ending viscosities. The ratio of silicone-based oil by weight in the mixture can be varied. The percentage of silicone-based oil by weight in the mixture of silicone-based oil and silicone-based dielectric gel can have values at or about (e.g. ±2.5%) 25%, 30%, 35%, 40%, 45%, 50%, 55%, 60%, 65%, 70%, 75%, and 85%. Ranges of 20%-30%, 25%-35%, 30%-40%, 35%-45%, 40%-50%, 45%-55%, 50%-60%, 55%-65%, 60%-70%, 65%-75%, 70%-80%, 75%-85%, and 80%-90% (by weight) are also contemplated. Further, these same ratios by weight can be contemplated for the mixture when using other types of oils or acrylates instead of or in addition to silicon-based oil to lessen the beginning viscosity of the gel mixture alone.

The initial viscosity of the mixture of 85% Dow Corning 200 fluid, 50 centistoke viscosity (PDMS, polydimethylsiloxane); 7.5% Dow Corning 3-4207 Dielectric Tough Gel, Part A—Resin; and 7.5% Dow Corning 3 4207 Dielectric Tough Gel, Part B—Pt Catalyst is approximately 100 centipoise (cP). Beginning viscosities of less than 1, less than 5, less than 10, less than 25, less than 50, less than 100, less than 250, less than 500, less than 750, less than 1000, less than 1200, less than 1500, less than 1800, and less than 2000 cP are imagined, and any beginning viscosity in the range 1-2000 cP is acceptable. Other ranges can include 1-10 cP, 10-50 cP, 50-100 cP, 100-250 cP, 250-500 cP, 500-750 cP, 750-1000 cP, 800-1200 cP, 1000-1500 cP, 1250-1750 cP, 1500-2000 cP, and 1800-2000 cP. In some cases an initial viscosity between 1000 cP and 1500 cP can also be used.

A final viscosity for the filler material 330 of well above the initial viscosity is envisioned in some embodiments. In most cases, a ratio of the final viscosity to the beginning viscosity is at least 50:1. With lower beginning viscosities, the ratio of the final viscosity to the beginning viscosity may be 20,000:1, or in some cases, up to 50,000:1. In most cases, a ratio of the final viscosity to the beginning viscosity of between 5,000:1 to 20,000:1, for beginning viscosities in the 10 cP range, may be used. For beginning viscosities in the 1000 cP range, ratios of the final viscosity to the beginning viscosity between 50:1 to 200:1 are imagined. In short order, ratios in the ranges of 200:1 to 1,000:1, 1,000:1 to 2,000:1, 2,000:1 to 5,000:1, 5,000:1 to 20,000:1, 20,000:1 to 50,000:1, 50,000:1 to 100,000:1, 100,000:1 to 150,000:1, and 150,000:1 to 200,000:1 are contemplated.

The final viscosity of the filler material 330 is typically on the order of 50,000 cP to 200,000 cP. In some cases, a final viscosity of at least 1×10⁶ cP is envisioned. Final viscosities of at least 50,000 cP, at least 60,000 cP, at least 75,000 cP, at least 100,000 cP, at least 150,000 cP, at least 200,000 cP, at least 250,000 cP, at least 300,000 cP, at least 500,000 cP, at least 750,000 cP, at least 800,000 cP, at least 900,000 cP, and at least 1×10⁶ cP are all envisioned. Ranges of final viscosity for the filler material 330 can include 50,000 cP to 75,000 cP, 60,000 cP to 100,000 cP, 75,000 cP to 150,000 cP, 100,000 cP to 200,000 cP, 100,000 cP to 250,000 cP, 150,000 cP to 300,000 cP, 200,000 cP to 500,000 cP, 250,000 cP to 600,000 cP, 300,000 cP to 750,000 cP, 500,000 cP to 800,000 cP, 600,000 cP to 900,000 cP, and 750,000 cP to 1×10⁶ cP.

Curing temperatures can be numerous, with a common curing temperature of room temperature. The curing step need not involve adding thermal energy to the system. Temperatures that can be used for curing can be envisioned (with temperatures in degrees F.) at up to 60 degrees, up to 65 degrees, up to 70 degrees, up to 75 degrees, up to 80 degrees, up to 85 degrees, up to 90 degrees, up to 95 degrees, up to 100 degrees, up to 105 degrees, up to 110 degrees, up to 115 degrees, up to 120 degrees, up to 125 degrees, and up to 130 degrees, and temperatures generally between 55 and 130 degrees. Other curing temperature ranges can include 60-85 degrees, 70-95 degrees, 80-110 degrees, 90-120 degrees, and 100-130 degrees.

The working time of the substance of a mixture can be varied as well. The working time of a mixture in this context means the time for the substance (e.g., the substance used to form the filler material 330) to cure to a viscosity more than double the initial viscosity when mixed. Working time for the layer can be varied. In particular, working times of less than 5 minutes, on the order of 10 minutes, up to 30 minutes, up to 1 hour, up to 2 hours, up to 4 hours, up to 6 hours, up to 8 hours, up to 12 hours, up to 18 hours, and up to 24 hours are all contemplated. A working time of 1 day or less is found to be best in practice. Any working time between 5 minutes and 1 day is acceptable.

In the context of this disclosure, resin can mean both synthetic and natural substances that have a viscosity prior to curing and a greater viscosity after curing. The resin can be unitary in nature, or may be derived from the mixture of two other substances to form the resin.

In yet another embodiment the filler material may comprise solely a liquid. In one case the filler material may be a dielectric oil. Such dielectric oils may be silicone-based. In one example, the oil can be 85% Dow Corning 200 fluid, 50 centistoke viscosity (PDMS, polydimethylsiloxane), One will realize that many differing oils can be used in place of polydimethylsiloxane, and this application should be read to include such other similar dielectric oils having the proper optical properties. Ranges of bulk viscosity of the oil by itself can range from include 0.1-1 centistokes, 1-5 centistokes, 5-10 centistokes, 10-25 centistokes, 25-50 centistokes, 40-60 centistokes, 50-75 centistokes, 75-100 centistokes, and 80-120 centistokes. Ranges between each of the individual points mentioned in this paragraph are also contemplated.

In some embodiments, the transparent casing 310, the filler material 330, the optional antireflective layer 350, the water-resistant layer 340, or any combination thereof form a package to maximize and maintain the photovoltaic module 402 efficiency, provide physical support, and prolong the life time of photovoltaic modules 402.

In some embodiments, the filler material 330 is a laminate layer such as any of those disclosed in U.S. Provisional patent application No. 60/906,901, filed Mar. 13, 2007, entitled “A Photovoltaic Apparatus Having a Laminate Layer and Method for Making the Same” which is hereby incorporated by reference herein in its entirety for such purpose. In some embodiments the filler material 330 has a viscosity of less than 1×10⁶ cP. In some embodiments, the filler material 330 has a thermal coefficient of expansion of greater than 500×10⁻⁶/° C. or greater than 1000×10⁻⁶/° C. In some embodiments, the filler material 330 comprises epolydimethylsiloxane polymer. In some embodiments, the filler material 330 comprises by weight: less than 50% of a dielectric gel or components to form a dielectric gel; and at least 30% of a transparent silicone oil, the transparent silicone oil having a beginning viscosity of no more than half of the beginning viscosity of the dielectric gel or components to form the dielectric gel. In some embodiments, the filler material 330 has a thermal coefficient of expansion of greater than 500×10⁻⁶/° C. and comprises by weight: less than 50% of a dielectric gel or components to form a dielectric gel; and at least 30% of a transparent silicone oil. In some embodiments, the filler material 330 is formed from silicone oil mixed with a dielectric gel. In some embodiments, the silicone oil is a polydimethylsiloxane polymer liquid and the dielectric gel is a mixture of a first silicone elastomer and a second silicone elastomer. In some embodiments, the filler material 330 is formed from X %, by weight, polydimethylsiloxane polymer liquid, Y %, by weight, a first silicone elastomer, and Z %, by weight, a second silicone elastomer, where X, Y, and Z sum to 100. In some embodiments, the polydimethylsiloxane polymer liquid has the chemical formula (CH₃)₃SiO[SiO(CH₃)₂]ₙSi(CH₃)₃, where n is a range of integers chosen such that the polymer liquid has an average bulk viscosity that falls in the range between 50 centistokes and 100,000 centistokes. In some embodiments, first silicone elastomer comprises at least sixty percent, by weight, dimethylvinyl-terminated dimethyl siloxane and between 3 and 7 percent by weight silicate. In some embodiments, the second silicone elastomer comprises: (i) at least sixty percent, by weight, dimethylvinyl-terminated dimethyl siloxane; (ii) between ten and thirty percent by weight hydrogen-terminated dimethyl siloxane; and (iii) between 3 and 7 percent by weight trimethylated silica. In some embodiments, X is between 30 and 90; Y is between 2 and 20; and Z is between 2 and 20.

In some embodiments, the filler material 330 comprises a silicone gel composition, comprising: (A) 100 parts by weight of a first polydiorganosiloxane containing an average of at least two silicon-bonded alkenyl groups per molecule and having a viscosity of from 0.2 to 10 Pa·s at 25° C.; (B) at least about 0.5 part by weight to about 10 parts by weight of a second polydiorganosiloxane containing an average of at least two silicone-bonded alkenyl groups per molecule, wherein the second polydiorganosiloxane has a viscosity at 25° C. of at least four times the viscosity of the first polydiorganosiloxane at 25° C.; (C) an organohydrogensiloxane having the average formula R₇Si(SiOR⁸₂H)₃ wherein R⁷ is an alkyl group having 1 to 18 carbon atoms or aryl, R⁸ is an alkyl group having 1 to 4 carbon atoms, in an amount sufficient to provide from 0.1 to 1.5 silicone-bonded hydrogen atoms per alkenyl group in components (A) and (B) combined; and (D) a hydrosilylation catalyst in an amount sufficient to cure the composition as disclosed in U.S. Pat. No. 6,169,155, which is hereby incorporated by reference herein.

Optional water resistant layer. In some embodiments, one or more water resistant layers are disposed on solar cells 12 and/or the photovoltaic module 402 to prevent water damage. In some embodiments, the one or more water resistant layers are disposed onto the transparent conductive layer 412 prior to depositing the filler material 330 and encasing the photovoltaic module 402 in the transparent casing 310. In some embodiments, such water resistant layers are disposed (e.g., circumferentially coated) onto the filler material 330 prior to encasing the photovoltaic module 402 in the transparent casing 310. In some embodiments, such water resistant layers are disposed (e.g. circumferentially coated) onto the transparent casing 310 itself. In embodiments where a water resistant layer is provided to seal water from the solar cells 12 and/or photovoltaic module 402 itself, the optical properties of the water resistant layer preferably do not interfere with the absorption of incident solar radiation by the solar cells 12 of the photovoltaic module. In some embodiments, this water resistant layer is made of clear silicone, SiN, SiOₓN_{y}, SiOₓ, or Al₂O₃, where x and y are integers. In some embodiments, the water resistant layer is made of a Q-type silicone, a silsequioxane, a D-type silicone, or an M-type silicone.

Optional antireflective coating. In some embodiments, an optional antireflective coating is also disposed (e.g.) circumferentially disposed on the transparent casing 310 to maximize solar cell efficiency. In some embodiments, there is a both a water resistant layer and an antireflective coating disposed on the transparent casing 310. In some embodiments, a single layer serves the dual purpose of a water resistant layer and an anti-reflective coating. In some embodiments, an antireflective coating is made of MgF₂, silicon nitride, titanium nitride, silicon monoxide (SiO), or silicon oxide nitride. In some embodiments, there is more than one layer of antireflective coating. In some embodiments, there is more than one layer of antireflective coating and each layer is made of the same material. In some embodiments, there is more than one layer of antireflective coating and each layer is made of a different material.

In some embodiments, some of the layers of the multi-layered solar cells 12 are constructed using cylindrical magnetron sputtering techniques. In some embodiments, some of the layers of multi-layered solar cells 12 are constructed using conventional sputtering methods or reactive sputtering methods on long tubes or strips. Sputtering coating methods for long tubes and strips are disclosed in for example, Hoshi et al., 1983, “Thin Film Coating Techniques on Wires and Inner Walls of Small Tubes via Cylindrical Magnetron Sputtering,” Electrical Engineering in Japan 103:73-80; Lincoln and Blickensderfer, 1980, “Adapting Conventional Sputtering Equipment for Coating Long Tubes and Strips,” J. Vac. Sci. Technol. 17:1252-1253; Harding, 1977, “Improvements in a dc Reactive Sputtering System for Coating Tubes,” J. Vac. Sci. Technol. 14:1313-1315; Pearce, 1970, “A Thick Film Vacuum Deposition System for Microwave Tube Component Coating,” Conference Records of 1970 Conference on Electron Device Techniques 208-211; and Harding et al., 1979, “Production of Properties of Selective Surfaces Coated onto Glass Tubes by a Magnetron Sputtering System,” Proceedings of the International Solar Energy Society 1912-1916, each of which is hereby incorporated by reference herein in its entirety.

Optional fluorescent material. In some embodiments, a fluorescent material (e.g., luminescent material, phosphorescent material) is coated on a surface of a layer of a solar cell 12 and/or photovoltaic module. In some embodiments, the fluorescent material is coated on the luminal surface and/or the exterior surface of the transparent casing 310. In some embodiments, the fluorescent material is coated on the outside surface of the transparent conductive layer 412. In some embodiments, the photovoltaic module includes a filler material 330 and the fluorescent material is coated on the filler material. In some embodiments, the photovoltaic module includes a water resistant layer and the fluorescent material is coated on the water resistant layer. In some embodiments, more than one surface of a solar cell 12 and/or photovoltaic module 402 is coated with optional fluorescent material. In some embodiments, the fluorescent material absorbs blue and/or ultraviolet light, which some semiconductor junctions 410 of the present application do not use to convert light to electricity, and the fluorescent material emits visible and/or infrared light which is useful for electrical generation in some photovoltaic modules 402 of the present application. In some embodiments, fluorescent material is dissolved in the filler material 330.

Fluorescent, luminescent, or phosphorescent materials can absorb light in the blue or UV range and emit visible light. Phosphorescent materials, or phosphors, usually comprise a suitable host material and an activator material. The host materials are typically oxides, sulfides, selenides, halides or silicates of zinc, cadmium, manganese, aluminum, silicon, or various rare earth metals. The activators are added to prolong the emission time.

In some embodiments, phosphorescent materials are incorporated in the systems and methods of the present application to enhance light absorption by a photovoltaic module 402. In some embodiments, the phosphorescent material is directly added to the material used to make the transparent casing 310. In some embodiments, the phosphorescent materials are mixed with a binder for use as transparent paints to coat various outer or inner layers of the solar cells 12 and/or photovoltaic modules, as described above.

Exemplary phosphors include, but are not limited to, copper-activated zinc sulfide (ZnS:Cu) and silver-activated zinc sulfide (ZnS:Ag). Other exemplary phosphorescent materials include, but are not limited to, zinc sulfide and cadmium sulfide (ZnS:CdS), strontium aluminate activated by europium (SrAlO₃:Eu), strontium titanium activated by praseodymium and aluminum (SrTiO3:Pr,Al), calcium sulfide with strontium sulfide with bismuth ((Ca,Sr)S:Bi), copper and magnesium activated zinc sulfide (ZnS:Cu,Mg), or any combination thereof.

Methods for creating phosphor materials are known in the art. For example, methods of making ZnS:Cu or other related phosphorescent materials are described in U.S. Pat. Nos. 2,807,587 to Butler et al.; 3,031,415 to Morrison et al.; 3,031,416 to Morrison et al.; 3,152,995 to Strock; 3,154,712 to Payne; 3,222,214 to Lagos et al.; 3,657,142 to Poss; 4,859,361 to Reilly et al., and 5,269,966 to Karam et al., each of which is hereby incorporated by reference herein in its entirety. Methods for making ZnS:Ag or related phosphorescent materials are described in U.S. Pat. Nos. 6,200,497 to Park et al., 6,025,675 to Ihara et al.; 4,804,882 to Takahara et al., and 4,512,912 to Matsuda et al., each of which is hereby incorporated by reference herein in its entirety. Generally, the persistence of the phosphor increases as the wavelength decreases. In some embodiments, quantum dots of CdSe or similar phosphorescent material can be used to get the same effects. See Dabbousi et al., 1995, “Electroluminescence from CdSe quantum-dot/polymer composites,” Applied Physics Letters 66 (11): 1316-1318; Dabbousi et al., 1997 “(CdSe)ZnS Core-Shell Quantum Dots Synthesis and Characterization of a Size Series of Highly Luminescent Nanocrystallites,” J. Phys. Chem. B, 101: 9463-9475; Ebenstein et al., 2002, “Fluorescence quantum yield of CdSe:ZnS nanocrystals investigated by correlated atomic-force and single-particle fluorescence microscopy,” Applied Physics Letters 80: 4033-4035; and Peng et al., 2000, “Shape control of CdSe nanocrystals,” Nature 404: 59-61; each of which is hereby incorporated by reference herein in its entirety.

In some embodiments, optical brighteners are used in the optional fluorescent layers of the present application. Optical brighteners (also known as optical brightening agents, fluorescent brightening agents or fluorescent whitening agents) are dyes that absorb light in the ultraviolet and violet region of the electromagnetic spectrum, and re-emit light in the blue region. Such compounds include stilbenes (e.g., trans-1,2-diphenylethylene or (E)-1,2-diphenylethene). Another exemplary optical brightener that can be used in the optional fluorescent layers of the present application is umbelliferone (7-hydroxycoumarin), which also absorbs energy in the UV portion of the spectrum. This energy is then re-emitted in the blue portion of the visible spectrum. More information on optical brighteners is in Dean, 1963, Naturally Occurring Oxygen Ring Compounds, Butterworths, London; Joule and Mills, 2000, Heterocyclic Chemistry, 4^{th} edition, Blackwell Science, Oxford, United Kingdom; and Barton, 1999, Comprehensive Natural Products Chemistry 2: 677, Nakanishi and Meth-Cohn eds., Elsevier, Oxford, United Kingdom, 1999, each of which is hereby incorporated by reference herein in its entirety.

Circumferentially disposed. In some embodiments of the present application, layers of material are successively circumferentially disposed on a non-planar elongated substrate 403 in order to form solar cells 12 of the photovoltaic module 402 as well as the encapsulating layers of the photovoltaic module such as filler material 330 and the casing 310. As used herein, the term “circumferentially disposed” is not intended to imply that each such layer of material is necessarily deposited on an underlying layer or that the shape of the solar cell 12 and/or photovoltaic module 402 is cylindrical. In fact, the present application teaches methods by which such layers are molded or otherwise formed on an underlying layer. Further, as discussed above in conjunction with the discussion of the elongated substrate 403, the substrate and underlying layers may have any of several different planar or nonplanar shapes. Nevertheless, the term “circumferentially disposed” means that an overlying layer is disposed on an underlying layer such that there is no space (e.g., no annular space) between the overlying layer and the underlying layer. Furthermore, as used herein, the term “circumferentially disposed” means that an overlying layer is disposed on at least fifty percent of the perimeter of the underlying layer. Furthermore, as used herein, the term “circumferentially disposed” means that an overlying layer is disposed along at least half of the length of the underlying layer. Furthermore, as used herein, the term “disposed” means that one layer is disposed on an underlying layer without any space between the two layers. So, if a first layer is disposed on a second layer, there is no space between the two layers.

Circumferentially sealed. In the present application, the term “circumferentially sealed” is not intended to imply that an overlying layer or structure is necessarily deposited on an underlying layer or structure. In fact, the present application teaches methods by which such layers or structures (e.g., transparent casing 310) are molded or otherwise formed on an underlying layer or structure. Nevertheless, the term “circumferentially sealed” means that an overlying layer or structure is disposed on an underlying layer or structure such that there is no space (e.g., no annular space) between the overlying layer or structure and the underlying layer or structure. Furthermore, as used herein, the term “circumferentially sealed” means that an overlying layer is disposed on the full perimeter of the underlying layer. In typical embodiments, a layer or structure circumferentially seals an underlying layer or structure when it is circumferentially disposed around the full perimeter of the underlying layer or structure and along the full length of the underlying layer or structure. However, the present application contemplates embodiments in which a circumferentially sealing layer or structure does not extend along the full length of an underlying layer or structure.

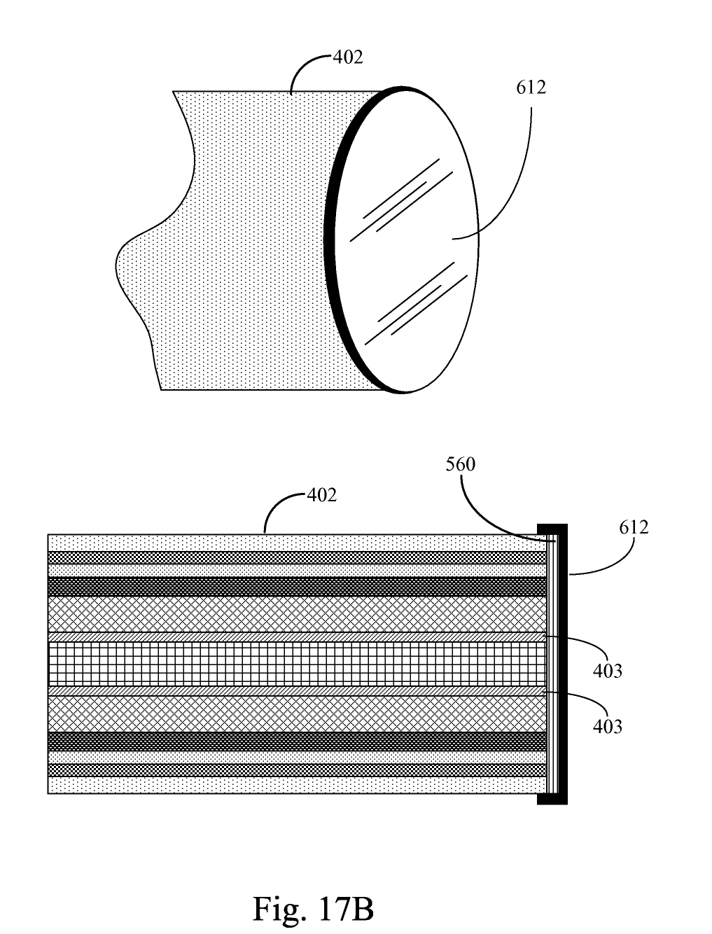

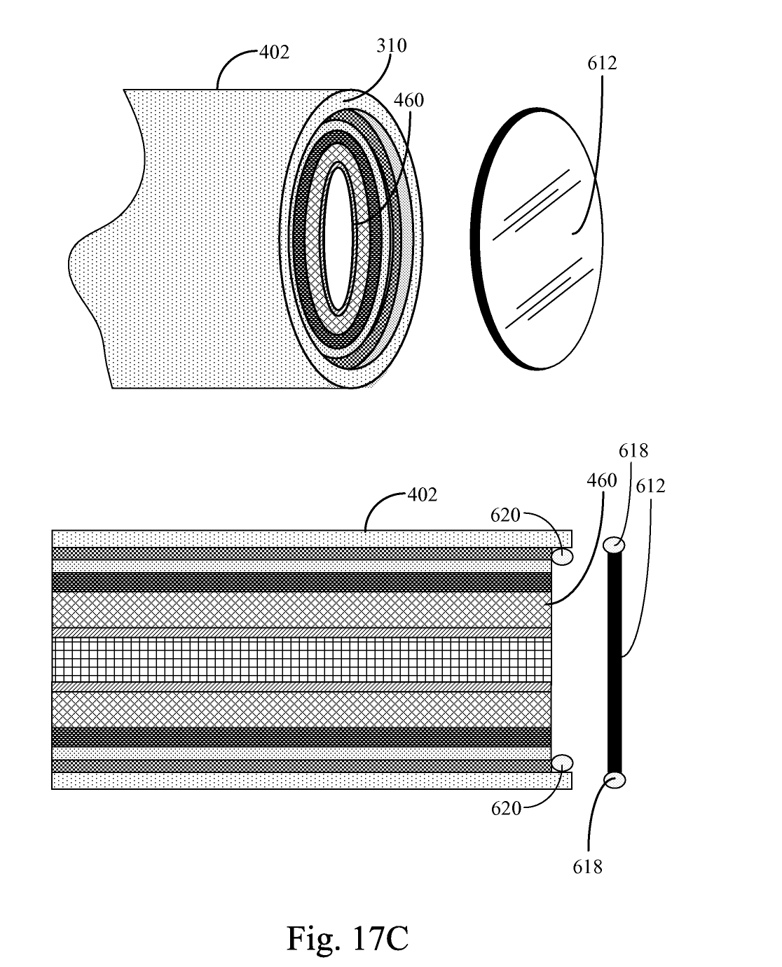

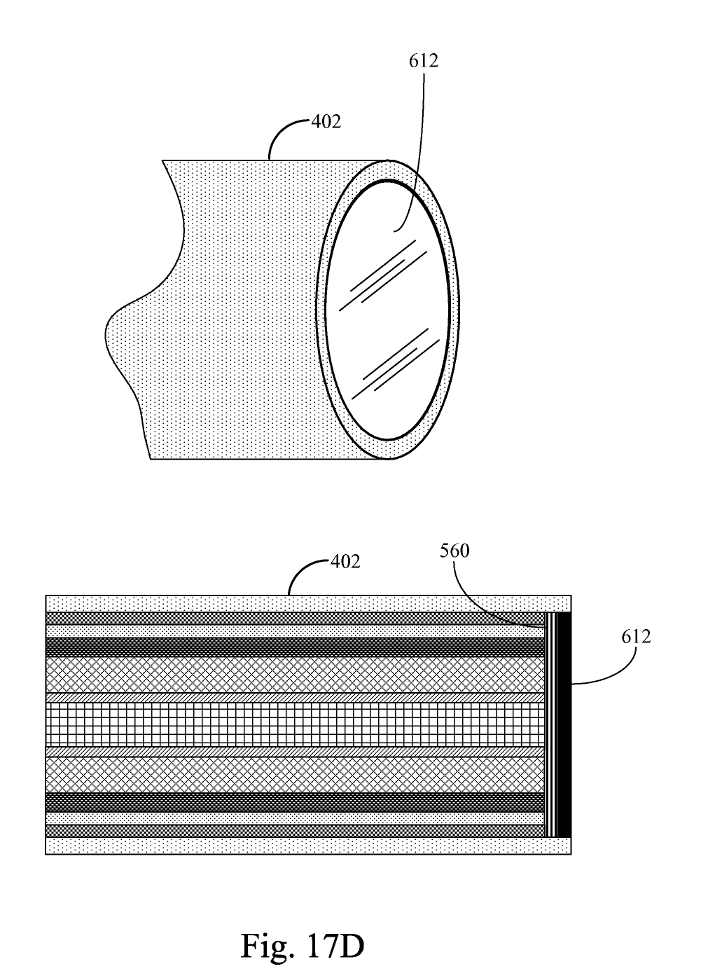

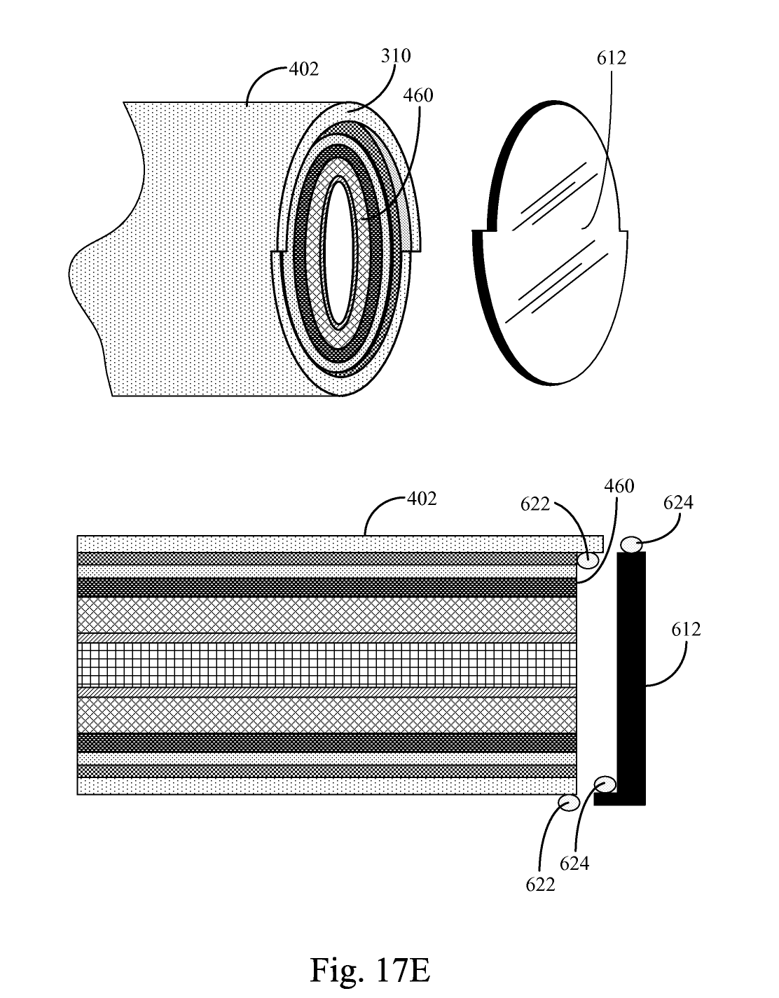

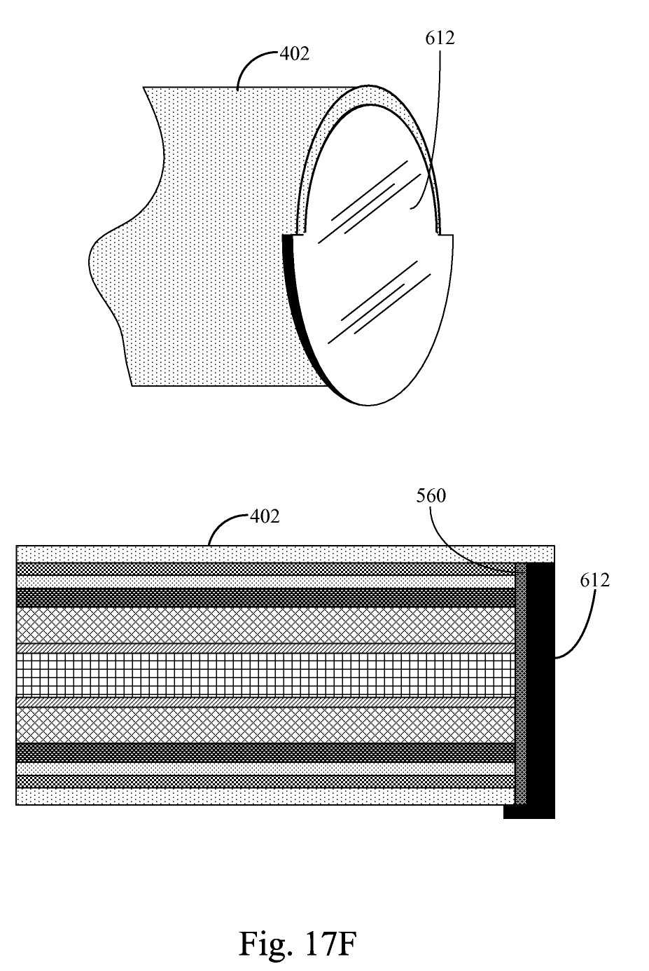

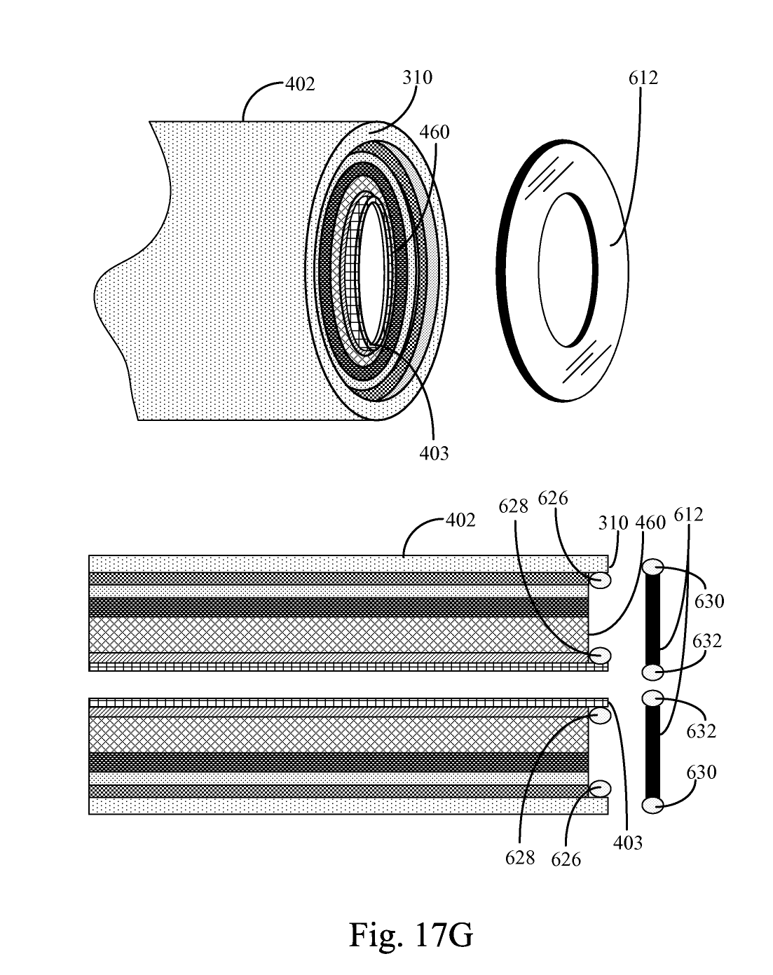

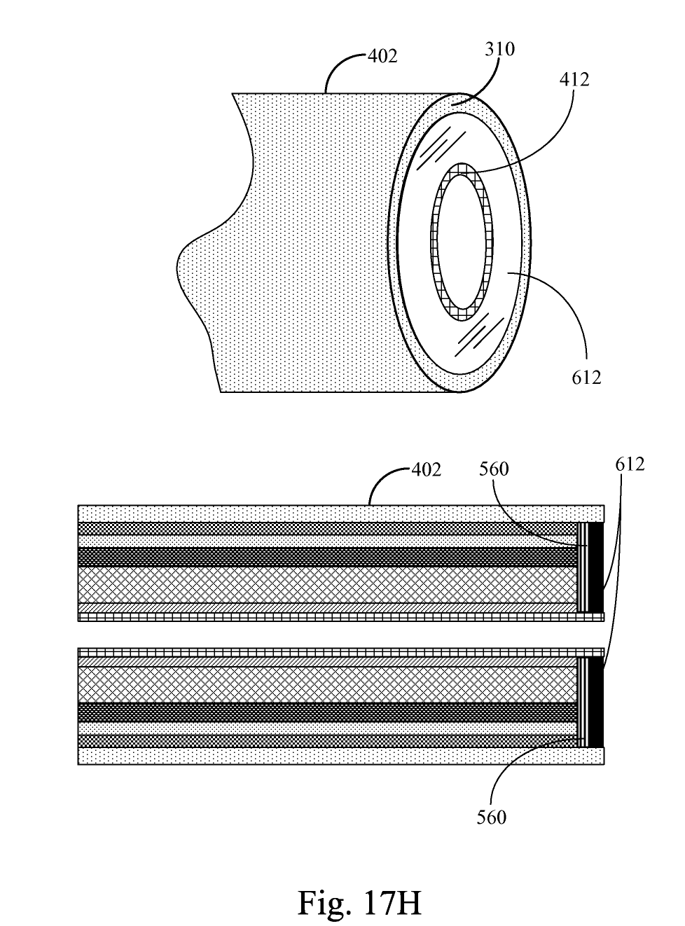

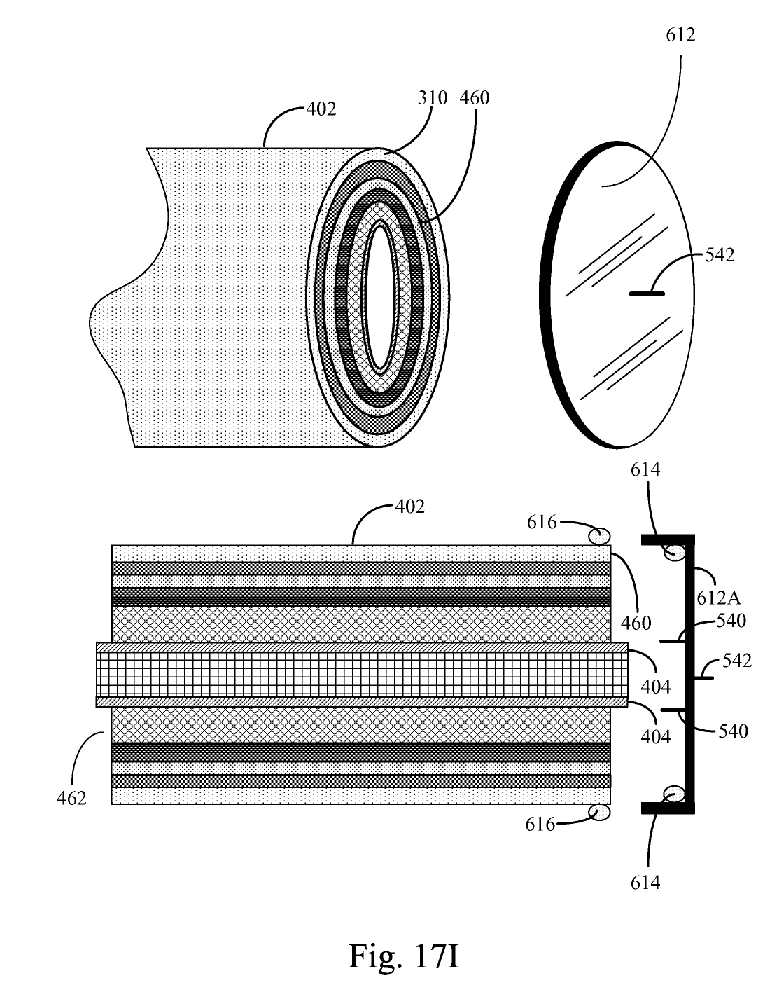

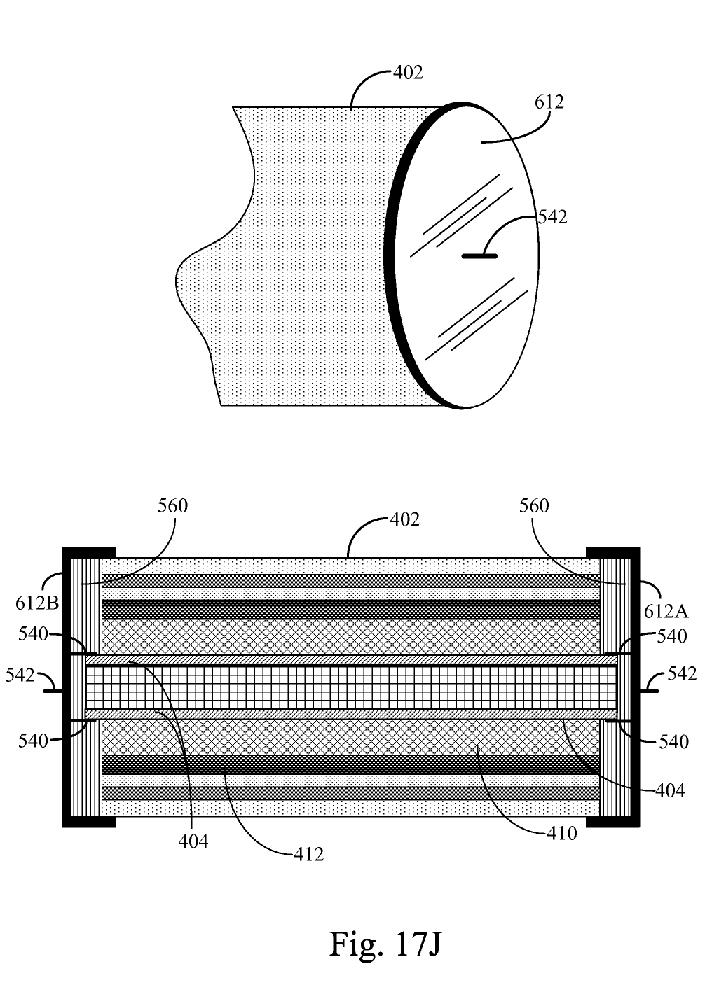

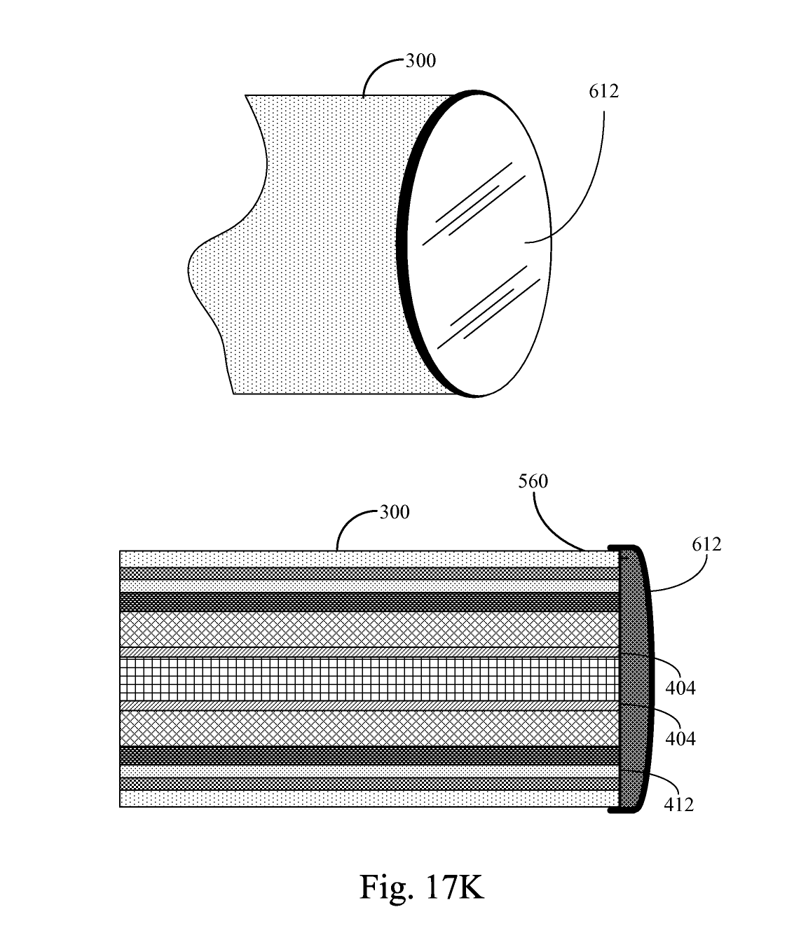

Sealant cap 612. In some embodiments, one or both ends of the photovoltaic module 402 are sealed with a sealant cap. Examples of sealant caps are illustrated, for example, in FIGS. 17A through 17K. Each illustration in FIGS. 17A-17K provides a perspective view of a photovoltaic module 402. Below each perspective view is a corresponding cross-sectional view of the photovoltaic module. In some embodiments, the photovoltaic modules illustrated in FIGS. 17A through 17K do not have an electrically conducting substrate 403. In some embodiments, any of the photovoltaic modules 402 disclosed herein are sealed with sealant caps such as those illustrated in FIG. 17 and described herein.

In some embodiments, there is a first sealant cap at a first end of the photovoltaic module 402 and a second sealant cap at a second end of the photovoltaic module, thereby sealing the photovoltaic module 402 from water. For example, referring to FIGS. 17A and 17B, sealant cap 612 seals end 460 of the photovoltaic module 402. In the embodiment illustrated in FIGS. 17A and 17B, the sealant cap 612 is sealed onto the outer surface of transparent nonplanar casing 310. However, other configurations of the sealant cap 612 are possible. For example, referring to FIGS. 17C and 17D, the sealant cap 612 is sealed onto the inner surface of the transparent nonplanar casing 310. Mixed embodiments of the sealant cap 612 are possible as well. For example, referring to FIGS. 17E and 17F, a first portion of the cap 612 seals onto the inner surface of the transparent nonplanar casing 310 while a second portion of the cap 612 seals onto the outer surface of the transparent nonplanar casing 310. In FIGS. 17G and 17H, this first portion is approximately half the circumference of the cap 612. However, in other embodiments, this first portion is some value other than half the circumference of the cap 612. In some embodiments, the first portion is a quarter of the circumference of the cap 612 and the second portion is three quarters of the circumference of the cap 612. In some embodiments, the first portion is one percent or more, ten percent or more, twenty percent or more, thirty percent or more of the circumference of the cap 612 and the second portion makes up the balance of cap 612. In some embodiments, the cap 612 comprises a plurality of first portions, where each first portion seals onto the inner surface of the transparent nonplanar casing 310, and a plurality of second portions, where each said second portion of the cap 612 seals onto the outer surface of the transparent nonplanar casing 310. In the embodiments illustrated in FIGS. 17I and 17J, the sealant cap 612 is sealed onto the inner surface of the transparent nonplanar casing 310 and the outer surface of the substrate 403. In FIGS. 17G and 17H, the substrate 403 is hollowed. In other embodiments, however, the substrate 403 is solid, with no hollow core. In some embodiments, any of the configurations shown in FIG. 17 has a substrate 403 with a hollow core.

Still other configurations of the sealant cap 612 are possible. For example, in some embodiments, the sealant cap 612 is bonded onto the outer surface of the transparent nonplanar casing 310 and the outer surface of the substrate 403. In some embodiments, the sealant cap 612 is bonded onto the outer surface of the transparent nonplanar casing 310 and the inner surface of the substrate 403. In some embodiments, the sealant cap 612 is bonded onto the inner surface of the transparent nonplanar casing 310 and the inner surface of the substrate 403.

Usefully, in some embodiments, the metal(s) that are typically used to make some embodiments of the sealant cap 612 are chosen to match the thermal expansion coefficient of the glass. For example, in some embodiments, the transparent nonplanar casing 310 is made of soda lime glass (CTE of about 9 ppm/C) and the sealant cap 612 is made of a low expansion stainless steel alloy like 410 (CTE of about 10 ppm/C). In some embodiments, the transparent nonplanar casing 310 is made of borosilicate glass (CTE of about 3.5 ppm/C) and sealant cap 612 is made of KOVAR(CTE of about 5 ppm/C). KOVAR is an iron-nickel-cobalt alloy. In some embodiments, the sealant cap 612 is composed of any conductive material, such as aluminum, molybdenum, tungsten, vanadium, rhodium, niobium, chromium, tantalum, titanium, steel, nickel, platinum, silver, gold, an alloy thereof (e.g. KOVAR), or any combination thereof. In some embodiments, the sealant cap 612 is composed of any waterproof conductive material, such as indium tin oxide, titanium nitride, tin oxide, fluorine doped tin oxide, doped zinc oxide, aluminum doped zinc oxide, gallium doped zinc oxide, boron dope zinc oxide, or indium-zinc oxide. In some embodiments, the sealant cap 612 is made of aluminosilicate glass, borosilicate glass (e.g., Pyrex, Duran, Simax, etc.), dichroic glass, germanium/semiconductor glass, glass ceramic, silicate/fused silica glass, soda lime glass, quartz glass, chalcogenide/sulphide glass, fluoride glass, pyrex glass, a glass-based phenolic, cereated glass, or flint glass.

In embodiments where the sealant cap 612 is made of metal, care is taken to make sure that the sealant cap does not form an electrical connection with both the transparent conductive layer 412 and the back-electrode 404. This can be accomplished in any number of ways. In the embodiment illustrated in FIG. 17A, a filler material 560 is positioned between the end 460 and the sealant cap 612. The filler material 560 electrically isolates the sealant cap 612 from the transparent conductive layer 412 and back-electrode 404. In some embodiments the filler material 560 includes ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, and/or a urethane. In some embodiments, the filler layer 560 is a Q-type silicone, a silsequioxane, a D-type silicone, or an M-type silicone. In some embodiments, the filler material 560 comprises EVA, silicone rubber, or solid rubber. In some embodiments, the filler material 560 is part of filler material 330. In some embodiments the filler material 560 is laced with a desiccant such as calcium oxide or barium oxide. In some embodiments, in addition to using the filler material 560, the sealant cap 612 is shaped so that it will not contact the transparent conductive layer 412 and the back-electrode 404. One such shape for the sealant cap 612 is illustrated in FIG. 17K. As can be seen in FIG. 17K, the sealant cap 612 is bowed out relative to the photovoltaic module 402 so that it does not make electrical contact with the transparent conductive layer 412 and the back-electrode 404. FIG. 17K merely serves to illustrate the point that the sealant cap 612 can adopt any type of shape so long at it makes a seal with the solar cell unit.

Advantageously, the sealant cap 612 can serve as an electrical lead for either the transparent conductive layer 412 or the back-electrode 404. Thus, in some embodiments, a first end of the photovoltaic module 402 is sealed with a first sealant cap 612 that makes an electrical connection with the transparent conductive layer 412 and the second end of the photovoltaic module 402 is sealed with a second sealant cap 612 that makes an electrical connection with the back-electrode 404. More typically, a first end of the photovoltaic module 402 is sealed with a first sealant cap 612 that makes an electrical connection with the back-electrode 404 that is electrical communication with the transparent conductive layer 412 while a second end of the photovoltaic module 402 is sealed with a second sealant cap 612 that makes an electrical connection with the back-electrode 404 that is electrically isolated from the transparent conductive layer 412. For example, referring to FIG. 17J, in some embodiments, a first sealant cap 612A makes an electrical connection with the back-electrode 404 that is in electrical communication with the transparent conductive layer 412 and a second sealant cap 612B makes an electrical connection with the back-electrode 404 that is electrically isolated from the transparent conductive layer 412. In these embodiments, the first sealant cap 612 serves as the electrode for transparent conductive layer 412 while the second sealant cap 612 serves as the electrode for the back-electrode 404. Referring to FIGS. 17A and 17B, for example, in embodiments where the sealant cap 612 is made of metal, electrical contact between the sealant cap 612 and both the transparent conductive layer 412 and the back-electrode 404 is not made. Thus, in embodiments where the sealant cap 612 is made of metal, the sealant cap 612 is electrically isolated from at least one of the transparent conductive layer 412 and the back-electrode 404.

Referring to FIG. 17I, in one example, the sealant cap 612A includes the electrical contacts 540 that are positioned within the sealant cap 612A so that they form electrical contact with the back-electrode 404 (as illustrated in FIG. 17J). Then the lead 542 serves as the electrical lead for the transparent conductive layer 412 (as illustrated in FIG. 17J) since the transparent conductive layer 412 is in electrical communication with the back-electrode 404 at the point of contact of electrode 540. Referring to FIG. 17J, sealant cap 612A is sealed onto the photovoltaic module 402 using the sealant 614 and/or 616. As a result, the electrical contacts 540 make electrical contact with the back-electrode 404. In preferred embodiments, the space 560 is filled with a non-conducting filler such as ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, or a urethane, before sealing the sealant cap 612 onto the nonplanar solar cell unit to prevent encapsulation of air within the solar cell. In some embodiments, the electrical contacts 540 are fitted onto the back-electrode 404 rather than onto the sealant cap 612. In some embodiments, the electrical contacts 540 are simply an extension of the back-electrode 404.

In some embodiments the sealant cap 612 is made of glass. In some of such embodiments, there is a lead for the transparent conductive layer 412 or the back-electrode 404 through the sealant cap 612 (not shown). In such embodiments, the sealant cap 612 can abut directly against the side ends 460. Thus, in such embodiments, the filler layer 560 is optional.

In some embodiments, the sealant cap 612 is sealed onto solar cell unit using butyl rubber (e.g., polyisobutylene). In such embodiments, the filler layer 560 is butyl rubber and glass frits or ceramics are not required to seal the sealant cap 612 onto the photovoltaic module 402 because the butyl rubber performs this function. In some embodiments, this butyl rubber is loaded with active desiccant such as CaO or BaO. In such embodiments that are sealed with butyl rubber, the solar cell unit has a water vapor transmission rate of less than 10⁻⁴ g/m²·day. In some embodiments that use butyl rubber for the filler layer 560, the sealant cap 612 is not required. In such embodiments, the ends of the photovoltaic module 402 are sealed with butyl rubber. In embodiments where butyl rubber is used without the sealant cap 612 leads such as leads 540 and 542 of FIG. 31 can be used to electrically connect the photovoltaic module 402 with other photovoltaic modules 402 or other circuitry.

In some embodiments the sealant cap 612 is sealed onto the photovoltaic module 402 using glass-to-glass, metal-to-metal, ceramic-to-metal, or glass-to-metal seals. There are two exemplary types of glass-to-metal hermetic seals used in various exemplary embodiments: matched seals and mismatched (compression) seals. Matched glass-to-metal hermetic seals are made of metal alloys and the substrate 403/transparent nonplanar casing 310 that share similar thermal expansion characteristics. Mismatched or compression glass to metal hermetic seals feature a steel or stainless steel sealant cap 612 that has a higher thermal expansion rate than the glass solar cell. Upon cooling, the sealant cap 612 contracts around the glass, creating a hermetic seal that is reinforced both chemically and mechanically. In some embodiments, a hermetic seal is any seal that has a water vapor transmission rate of 10⁻⁴ g/m²·day or better. In some embodiments, a hermetic seal is any seal that has a water vapor transmission rate of 10⁻⁵ g/m²·day or better. In some embodiments, a hermetic seal is any seal that has a water vapor transmission rate of 10⁻⁶ g/m²·day or better. In some embodiments, a hermetic seal is any seal that has a water vapor transmission rate of 10⁻⁷ g/m²·day or better. In some embodiments, a hermetic seal is any seal that has a water vapor transmission rate of 10⁻⁸ g/m²·day or better.

In some embodiments, the seal formed between the sealant cap 612 and the photovoltaic module 402 has a water vapor transmission rate (WVTR) of 10⁻⁴ g/m²·day or less. In some embodiments, the seal formed between the sealant cap 612 and the photovoltaic module 402 has a water vapor transmission rate (WVTR) of 10⁻⁵ g/m²·day or less. In some embodiments, the seal formed between the cap 612 and the photovoltaic module 402 has a WVTR of 10⁻⁶ g/m²·day or less. In some embodiments, the seal formed between the cap 612 and the photovoltaic module 402 has a WVTR of 10⁻⁷ g/m²·day or less. In some embodiments, the seal formed between the cap 612 and the photovoltaic module 402 has a WVTR of 10⁻⁸ g/m²·day or less. The seal between the sealant cap 612 and the photovoltaic module 402 can be accomplished using a glass or, more generally, a ceramic material. In some embodiments, this glass or ceramic material has a melting temperature between 200° C. and 450° C. In some embodiments, this glass or ceramic material has a melting temperature between 300° C. and 450° C. In some embodiments, this glass or ceramic material has a melting temperature between 350° C. and 400° C. There are a wide range of glasses and ceramic materials that can be used to form the hermetic seal. Examples include, but are not limited to, oxide ceramics including alumina, zirconia, silica, aluminum silicate, magnesia and other metal oxide based materials, ceramics based upon aluminum dioxide, aluminum nitrate, aluminum oxide, aluminum zirconia, as well as glasses based upon silicon dioxide.

Referring to FIG. 17A, in some embodiments, the sealant cap 612 is sealed onto the photovoltaic module 402 by placing a continuous strip of sealant 614 around the inner edge of the sealant cap 612. Still referring to FIG. 17A, in some embodiments, a continuous strip of sealant 616 is placed on the outer edge of the transparent nonplanar casing 310. Typically, the sealant 614 (around inner edge of sealant cap 612) or the sealant 616 (around outer edge of transparent nonplanar casing 310), but not both, are used (although both can be used).

In some embodiments, the sealant 614 and/or sealant 616 is glass frit. There are different types of frit which can be used for different types of glass and at different temperatures. The present invention is independent of the frit or glass type. In some embodiments, the glass frit has a melting temperature between 200° C. and 450° C. Such materials, also called solder glass, are available from many sources, including Ferro Corporation (Cleveland, Ohio), Schott Glass (Elmsford, N.Y.), and Asahi Glass (Tokyo, Japan). Advantageously, the use of low temperature melting solder glass limits the exposure of the active components of the solar cell to extreme temperature during formation of the seal. In some embodiments, the glass frit is a pressed or sintered preform made to the correct shape of the application (either to fit over outer edge of the transparent nonplanar casing 310 in the case of the sealant 616 or to fit within the inner edge of sealant cap 612 in the case of the sealant 614. In some embodiments, the solder glass is suspended in an organic binder material or is applied as a dry powder. In embodiments where the sealant 614 and/or 616 is glass frit, the temperature is increased to a value that will enable the continuous glass frit to soften. Heat can be applied by methods such as direct contact with a hot surface, by inductively heating up a metal part, by contact with flame or hot air, or through absorption of light from a laser. Once the glass frit is softened, the sealant cap 612 is pressed onto the photovoltaic module 402. The softened glass frit forms a bond with the parts being joined, thus forming a hermetic seal.

In some embodiments, the sealant 614 and/or sealant 616 is a sol-gel material. As is known, a sol-gel material alternates between two states, one being a colloidal suspension of solid particles in a liquid, the other state being a dual phase material in which there is a solid outer shell filled with a solvent. When the solvent is removed, e.g., though exposure to ambient atmospheric pressure, a xerogel material results with a consistency similar to that of a low density glass. As is also known, a sol-gel material may be formulated by combining a quantity of potassium silicate (kasil) (e.g., 120 grams) with a comparatively smaller quantity of formamide (e.g., 7-8 grams). Alternatively, a lesser quantity of kasil (e.g., 12 grams) may be combined with still a lesser quantity of propylene carbonate (e.g., 2-3 grams). Another method of forming a sol-gel material involves the mixture of TEOS-H₂O and methanol, and allowing the mixture to hydrolyse. In embodiments where the sealant 614 and/or 616 is sol-gel, the sealant cap 612 is pressed onto the photovoltaic module 402 and the sol-gel is allowed to cure. In some embodiments, the sol-gel is cured at ambient temperature and ambient atmospheric pressure. Alternatively, the curing process may be accelerated by other methods such as, e.g., applying heat or using an infrared heat source. In the case where the sol-gel is a polycarbonate-kasil mixture, the sol-gel material cures in approximately 5 to 10 minutes at room temperature. Sol-gels are discussed in Madou, 2002, Fundamentals of Microfabrication, The Science of Miniaturization, Second Edition, CRC Press, New York, pp. 156-157, which is hereby incorporated by reference herein in its entirety.

In some embodiments, the sealant 614 and/or sealant 616 is a ceramic cement material. Such materials are readily available from suppliers such as Aremco (Valley Cottage, N.Y.) and Sauereisen (Pittsburgh, Pa.). Such materials are relatively inexpensive and provide strong bonds to glass or metal. By their nature, however, these cements form porous ceramics which do not provide a hermetic waterproof seal. However, such materials can be waterproofed. A suspension of solder glass particles which are smaller than the pore size of the ceramic can be made in a volatile liquid. This liquid can then be allowed to wick into the pores of the ceramic by capillary action. Subsequent heating causes the solder glass to melt, thus wetting the ceramic material, and thereby sealing the ceramic and forming a hermetic seal. Aremco sells a product for this application (AremcoSeal 617). AremcoSeal 617 glass, however, has the drawback that it must be treated at high temperature. Thus, in preferred embodiments, a low melting point solder glass suspended in a binder such as provided by DieMat (DM2700P sealing glass paste) is used instead. Both the porous ceramics and the sol-gel can be waterproofed using these techniques.

In one embodiment in accordance with FIGS. 17A and 17B, DM2700P (DieMat, Byfield, Mass.) is coated onto the outer circumference of the transparent nonplanar casing 310 to form the sealant 616 and the paste is allowed to dry. Then, the sealant cap 612, made of stainless steel, is heated on a hotplate to about 420° C. Next, the coated end of the solar cell is manually inserted into the hot cap, while still on the hotplate. The sealing glass paste is allowed to melt and wet the surface of the sealant cap 612. The solar cell is removed from the hotplate and allowed to cool.

In another embodiment in accordance with FIGS. 17A and 17B, DM2700P coating is applied to the inner circumference of the sealant cap 612 in order to form the sealant 614. The paste is allowed to dry. Next, the stainless steel cap is heated on a hotplate to about 420° C. until the sealing glass melts. One end of the solar cell is manually inserted into the stainless steel cap while the cap is still on the hotplate. The sealing glass paste melts and wets the outer surface of surface of the transparent nonplanar casing 310. The assembly is then removed from the hotplate and allowed to cool.

Referring to FIG. 17C, the sealant 618 and/or 620 is used to seal the sealant cap 612 to the photovoltaic module 402. The sealant 618 and/or 620 is made of any of the compositions that can be used to make the sealant 614 and/or 616 described above. Referring to FIG. 17E, the sealant 622 and/or 624 is used to seal the sealant cap 612 to the photovoltaic module 402. The sealant 622 and/or 624 is made of any of the compositions that can be used to make the sealant 614 and/or 616 described above. Referring to FIG. 17G, the sealant 626 and/or 630 together with the sealant 628 and/or sealant 632 is used to seal the sealant cap 612 to the photovoltaic module 402. The sealant 626 and/or 628 and/or 630 and/or 632 is made of any of the compositions that can be used to make the sealant 614 and/or 616 described above.

Multifacial Embodiments. In other embodiments (not shown), the photovoltaic module 402 is bifacial, having two flat photovoltaic cells conjoined in opposite directions, such that light entering from either the top or the bottom would be received and converted to electric energy.

Further, the photovoltaic module 402 and the transparent casing 310 may have the same or substantially the same geometric shape as each other. Alternatively, the solar cell and the transparent casing 310 may have differing geometries (e.g., a bifacial solar cell can be disposed within a tubular or cylindrical casing). Accordingly, the photovoltaic module 402 and the casing 310 can thus have any suitable cross-sectional shapes, such as square, rectangular, elliptical, polygonal, or have a varying cross-sectional shape, and any desired overall shape and configuration.

In various embodiments, the photovoltaic module 402 can have a multi-facial, or omnifacial configuration, or otherwise be designed to capture light from directions both facing and not facing the initial light source. An example omnifacial topology of a photovoltaic module 402 is a cylindrical embodiment illustrated in FIG. 3A, where the surface of the cell has one continuous surface. In a multifacial configuration, the shape of the cross section of the photovoltaic module 402 can be described by any combination of straight lines and curved features. In some cases, the omnifacial and multifacial configurations are operable to receive light from differing orientations, including anti-parallel directions.

### 5.1.1 Solar Cell Unit Assemblies

FIG. 4A illustrates a cross-sectional view of the arrangement of three photovoltaic modules 402 arranged in a coplanar fashion in order to form an assembly 400. FIG. 4B provides a cross-sectional view with respect to line 4B-4B of FIG. 4A with the exception that back-electrode 404 is shown as a solid core. In preferred embodiments, back-electrode 404 is not a solid core but rather a one or more layers disposed on a elongated substrate 403. Thus, in some embodiments in accordance with FIG. 4, rather than being a solid cylindrical substrate, back-electrode 404 is a thin layer of electrically conducting material circumferentially disposed on elongated substrate 403 as depicted in FIG. 3B and FIG. 4A but not FIGS. 4B through 4D.

As can be seen with FIGS. 4A and 4B, each photovoltaic module 402 has a length that is great compared to the diameter d of its cross-section. An advantage of the architecture shown in FIG. 4A is that there is no front side contact that shades photovoltaic modules 402. Such a front side contact is found in known devices (e.g., elements 10 of FIG. 2B). Another advantage of the architecture shown in FIG. 4A is that photovoltaic modules 402 are electrically connected in series rather than in parallel. In such a series configuration, the voltage of each photovoltaic module 402 is summed. This serves to increase the voltage across the system, thereby keeping the current down, relative to comparable parallel architectures, and minimizes resistive losses. A serial electrical arrangement is maintained by arranging all or a portion of the photovoltaic modules 402 as illustrated in FIGS. 4A and 4B. Another advantage of the architecture shown in FIG. 4A is that the resistance loss across the system is low. This is because each electrode component of the circuit is made of highly conductive material. For example, as noted above, back-electrode 404 of each photovoltaic modules 402 is made of a conductive material such as metal. In the alternative, where the back-electrode 404 is not a solid, but rather is a layer deposited on a elongated substrate 403, the back-electrode layer 404 is highly conductive. The advantageous low resistance nature of the architecture illustrated in FIG. 4A is also facilitated by the highly conductive properties of the optional counter-electrode strips 420. However, in some embodiments, counter-electrode strips 420 are not used. Rather, monolithic integration architectures, such as those described in U.S. Pat. No. 7,235,736 entitled “Monolithic integration of cylindrical solar cells, which is hereby incorporated by reference herein in its entirety for such purpose, are used.

In some embodiments, for example, the counter-electrode strips 420 are composed of a conductive epoxy (e.g., silver epoxy) or conductive ink and the like. For example, in some embodiments, the counter-electrode strips 420 are formed by depositing a thin metallic layer on a suitable substrate and then patterning the layer into a series of parallel strips. Each counter-electrode strip 420 is affixed to a photovoltaic module 402 with a conductive epoxy along the length of a photovoltaic module 402, as shown in FIG. 4D. In some embodiments, the counter-electrode strips 420 are formed directly on the photovoltaic modules 402. In other embodiments, the counter-electrode strips 420 are formed on the outer transparent conductive layer 412, as illustrated in FIG. 3B. In some embodiments, connections between counter-electrode strip 420 to the electrodes 433 are established in series as depicted in FIG. 4B.

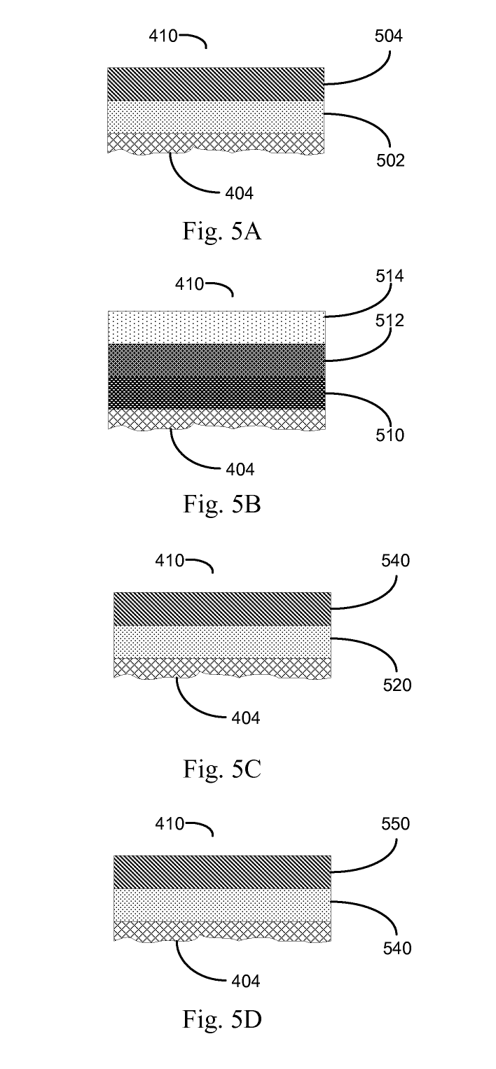

Still another advantage of the architecture illustrated in FIG. 4A is that the path length through the absorber layer (e.g., layer 502, 510, 520, or 540 of FIG. 5) of semiconductor junction 410 is, on average, longer than the path length through of the same type of absorber layer having the same width but in a planar configuration. Thus, the elongated architecture illustrated in FIG. 4A allows for the design of thinner absorption layers relative to analogous planar solar cell counterparts. In the elongated architecture, the thinner absorption layer absorbs the light because of the increased path length through the layer. Because the absorption layer is thinner relative to comparable planar solar cells, there is less resistance and, hence, an overall increase in efficiency in the cell relative to analogous planar solar cells. Additional advantages of having a thinner absorption layer that still absorbs sufficient amounts of light is that such absorption layers require less material and are thus cheaper. Furthermore, thinner absorption layers are faster to make, thereby further lowering production costs.

Another advantage of photovoltaic modules 402 illustrated in FIG. 4A is that they have a relatively small surface area, relative to comparable planar solar cells, and they possess radial symmetry, in the embodiment illustrated. Embodiments not illustrated do not necessarily have radial symmetry. Each of these properties allow for the controlled deposition of doped semiconductor layers necessary to form the semiconductor junction 410. The smaller surface area, relative to conventional flat panel solar cells, means that it is easier to present a uniform vapor across the surface during deposition of the layers that form the semiconductor junction 410. The radial symmetry can be exploited during the manufacture of the cells in order to ensure uniform composition (e.g., uniform material composition, uniform dopant concentration, etc.) and/or uniform thickness of individual layers of the semiconductor junction 410. For example, the back-electrode 404 upon which layers are deposited to make the solar cells 12 of the photovoltaic modules 412 can be rotated along its longitudinal axis during such deposition in order to ensure uniform material composition and/or uniform thickness in embodiments where the solar cells posses radial symmetry. As discussed above, not all embodiments of the present application possess radial symmetry.

The cross-sectional shape of each of the photovoltaic modules 402 is generally circular in FIG. 4B. In other embodiments, photovoltaic module 402 bodies with a quadrilateral cross-section or an elliptical shaped cross-section and the like are used. In fact, there is no limit on the cross-sectional shape of the photovoltaic modules 402 and solar cells 12 contained therein in the present application. In some embodiments the photovoltaic modules 402 maintain a general overall rod-like shape in which their length is much larger than their diameter and they possess some form of cross-sectional radial symmetry or approximate cross-sectional radial symmetry. In some embodiments, the photovoltaic modules 402 are characterized by any of the cross-sectional areas discussed above in conjunction with the description of the elongated substrate 403.

In some embodiments, as illustrated in FIG. 4A, a first and second photovoltaic module 402 are electrically connected in series by an electrical contact 433 that connects the back-electrode 404 (first electrode) of a solar cell 14 of a first photovoltaic module 402 to the corresponding counter-electrode strip 420 or TCO 412 of a solar cell 12 of a second photovoltaic module 402. In some embodiments, photovoltaic modules 402 are multiply arranged in a row parallel or nearly parallel with respect to each other and rest upon independent leads (counter-electrodes) 420 that are electrically isolated from each other. Advantageously, in the configuration illustrated in FIG. 4A, the photovoltaic modules 402 can receive direct light through the transparent casing 310.

In some embodiments, not all the photovoltaic modules 402 in assembly 400 are electrically arranged in series. For example, in some embodiments, there are pairs of photovoltaic modules 402 that are electrically arranged in parallel. A first and second photovoltaic module can be electrically connected in parallel, and are thereby paired, by using a first electrical contact (e.g., an electrically conducting wire, etc., not shown) that joins the back-electrode 404 of a solar cell 12 of a first photovoltaic module 402 to a solar cell 12 of a second photovoltaic module. To complete the parallel circuit, the transparent conductive layer 412 of the first solar cell 12 is electrically connected to the transparent conductive layer 412 of the solar cell of the second photovoltaic module 402 either by contacting the transparent conductive layers of the two solar cells either directly or through a second electrical contact (not shown). The pairs of photovoltaic modules are then electrically arranged in series. In some embodiments, three, four, five, six, seven, eight, nine, ten, eleven or more photovoltaic modules 402 are electrically arranged in parallel. These parallel groups of photovoltaic modules 402 are then electrically arranged in series.

FIG. 4C is an enlargement of region 4C of FIG. 4B in which a portion of the back-electrode 404 and the transparent conductive layer 412 have been cut away to illustrate the positional relationship between the counter-electrode strip 420, the electrode 433, the back-electrode 404, the semiconductor layer 410, and the transparent conductive layer 412. Furthermore, FIG. 4C illustrates how the electrical contact 433 joins the back-electrode 404 of one photovoltaic module 402 to the counter-electrode 420 of another photovoltaic modules 402.

One advantage of the configuration illustrated in FIG. 4 is that the electrical contacts 433 that serially connect the photovoltaic modules 402 together only need to be placed on one end of assembly 400, as illustrated in FIG. 4B. However, encapsulation shields each photovoltaic module 402 from unwanted electrical contacts from the adjacent photovoltaic modules 402, making encapsulation relatively simple. Thus, referring to FIG. 4D, which is a cross-sectional view of a photovoltaic module 402 cell taken about line 4D-4D of FIG. 4B, it is possible to completely seal far-end 455 of photovoltaic module 402 with the transparent casing 310 in the manner illustrated. In some embodiments, the layers in this seal are identical to the layers circumferentially disposed lengthwise on the back-electrode 404, namely, in order of deposition on the back-electrode 404 and/or elongated substrate 403, the semiconductor junction 410, the optional thin intrinsic layer (i-layer) 415, and the transparent conductive layer 412. In such embodiments, the end 455 can receive sunlight and therefore contribute to the electrical generating properties of the photovoltaic module 402. In some embodiments, the transparent casing 310 opens at both ends of the photovoltaic modules 402 such that electrical contacts can be extended from either end of the photovoltaic modules.

FIG. 4D also illustrates how, in some embodiments, the various layers deposited on the back-electrode 404 are tapered at end 466 where the electrical contacts 433 are found. For instance, a terminal portion of the back-electrode 404 is exposed, as illustrated in FIG. 4D. In other words, the semiconductor junction 410, the optional i-layer 415, and the transparent conductive layer 412 are stripped away from a terminal portion of the back-electrode 404. Furthermore, a terminal portion of the semiconductor junction 410 is exposed as illustrated in FIG. 4D. That is, the optional i-layer 415 and the transparent conductive layer 412 are stripped away from a terminal portion of semiconductor junction 410. The remaining portions of the back-electrode 404, the semiconductor junction 410, the optional i-layer 415, and the transparent conductive layer 412 are coated by the transparent casing 310. Such a configuration is advantageous because it prevents a short from developing between the transparent conductive layer 412 and the back-electrode 404. In FIG. 4D, the photovoltaic module 402 is positioned on the counter-electrode strip 420 which, in turn, is positioned against electrically resistant the transparent casing 310. However, there is no requirement that the counter-electrode strip 420 make contact with an electrically resistant transparent casing 310. In fact, in some embodiments, the photovoltaic modules 402 and their corresponding optional counter-electrode strips 420 are sealed within the transparent conductive layer 412 such that there is no unfavorable electrical contact. In such embodiments, the photovoltaic modules 402 and the optional corresponding electrode strips 420 are fixedly held in place by a sealant such as ethylene vinyl acetate or silicone. In some embodiments in accordance with the present application, the counter-electrode strips 420 are replaced with metal wires that are attached to the sides of the photovoltaic modules 402. In some embodiments in accordance with the present application, the photovoltaic modules 402 implement a segmented design to eliminate the requirement of additional wire- or strip-like counter-electrodes. Details on segmented solar cell design are found in copending U.S. Pat. No. 7,235,736, entitled “Monolithic Integration of Cylindrical Solar Cells,” filed Mar. 18, 2006, which is hereby incorporated by reference herein in its entirety.

FIG. 4D further provides a perspective view of electrical contacts 433 that serially connect the photovoltaic modules 402. For instance, a first electrical contact 433-1 electrically interfaces with the counter-electrode 420 whereas a second electrical contact 433-2 electrically interfaces with the back-electrode 404 (the first electrode of photovoltaic module 402). The first electrical contact 433-1 serially connects the counter-electrode of the photovoltaic modules 402 to the back-electrode 404 of another photovoltaic module. The second electrical contact 433-2 serially connects the back-electrode 404 of a solar cell 12 of a photovoltaic module 402 to the counter-electrode 420 of solar cell 12 of another photovoltaic module 402, as shown in FIG. 4B. Such an electrical configuration is possible regardless of whether the back-electrode 404 is itself a solid cylindrical substrate or is a layer of electrically conducting material on an elongated substrate 403 as depicted in FIG. 3B. Each photovoltaic module 402 is coated by a transparent casing 310.

In addition, FIG. 4D provides an encapsulated photovoltaic module 402 where the filler material 330 and a transparent casing 310 cover the photovoltaic module, leaving only one end 466 to establish electrical contracts. It is to be appreciated that, in some embodiments, the filler material 330 and the transparent casing 310 are configured such that both ends (e.g., 455 and 466 in FIG. 4D) of the photovoltaic module 402 are available to establish electrical contacts.

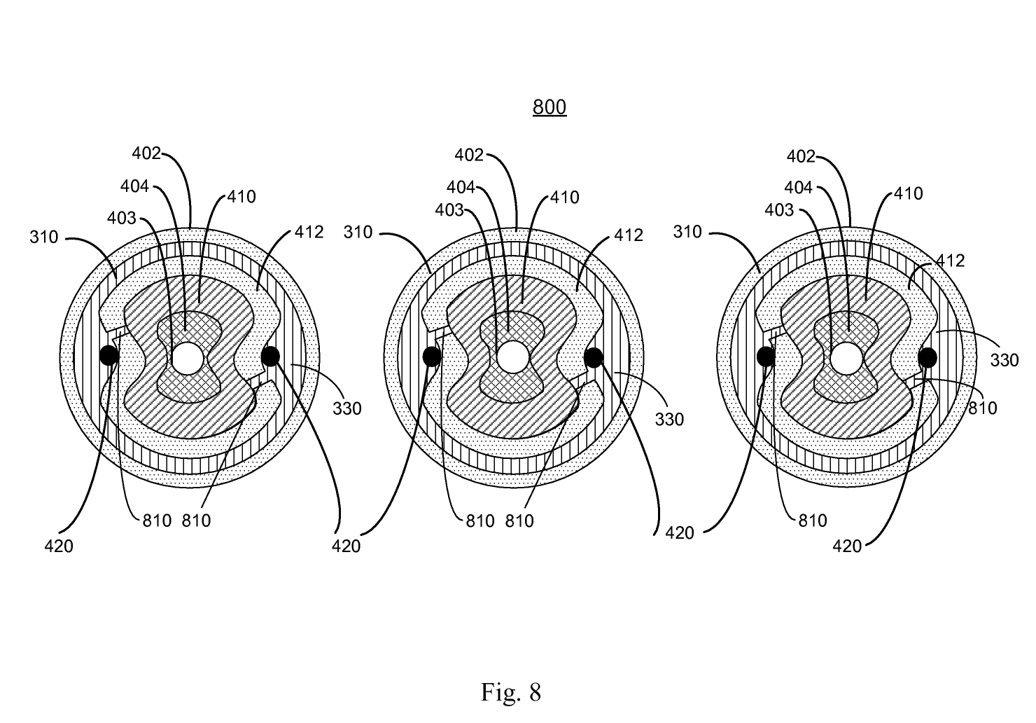

FIG. 8 illustrates an assembly 800 of the present application in which the transparent conductive layer 412 is interrupted by breaks 810 that run along the long axis of the photovoltaic module 402 and cut completely through transparent conductive layer 412. In the embodiment illustrated in FIG. 8, there are two breaks 810 that run the length of the photovoltaic module 402. The effect of such breaks 810 is that they electrically isolate the two counter-electrodes 420 associated with photovoltaic module 402 in the assembly 800. There are many ways in which the breaks 810 can be made. For example, a laser or an HCl etch can be used.

In some embodiments, not all the photovoltaic modules 402 in the assembly 800 are electrically arranged in series. For example, in some embodiments, there are pairs of photovoltaic modules 402 that are electrically arranged in parallel. A first and second photovoltaic module can be electrically connected in parallel, and are thereby paired, by using a first electrical contact (e.g., an electrically conducting wire, etc., not shown) that joins the back-electrode 404 of a first photovoltaic module to the second photovoltaic module. To complete the parallel circuit, a transparent conductive layer 412 of the first photovoltaic module 402 is electrically connected to a transparent conductive layer 412 of the second photovoltaic module 402 either by contacting the transparent conductive layers of the two photovoltaic modules either directly or through a second electrical contact (not shown). The pairs of photovoltaic modules are then electrically arranged in series. In some embodiments, three, four, five, six, seven, eight, nine, ten, eleven or more photovoltaic modules 402 are electrically arranged in parallel. These parallel groups of photovoltaic modules 402 are then electrically arranged in series.

In some embodiments, a transparent casing 310 is used to encase photovoltaic modules 402. Because it is important to exclude air from the photovoltaic module 402, a filler material 330 may be used to prevent oxidation of components of the photovoltaic module 402. As illustrated in FIG. 8, the filler material 330 (for example EVA) prevents seepage of oxygen and water into the photovoltaic module 402. In some embodiments, the individually encapsulated photovoltaic modules 402 are assembled into a planar array as depicted in FIG. 8.

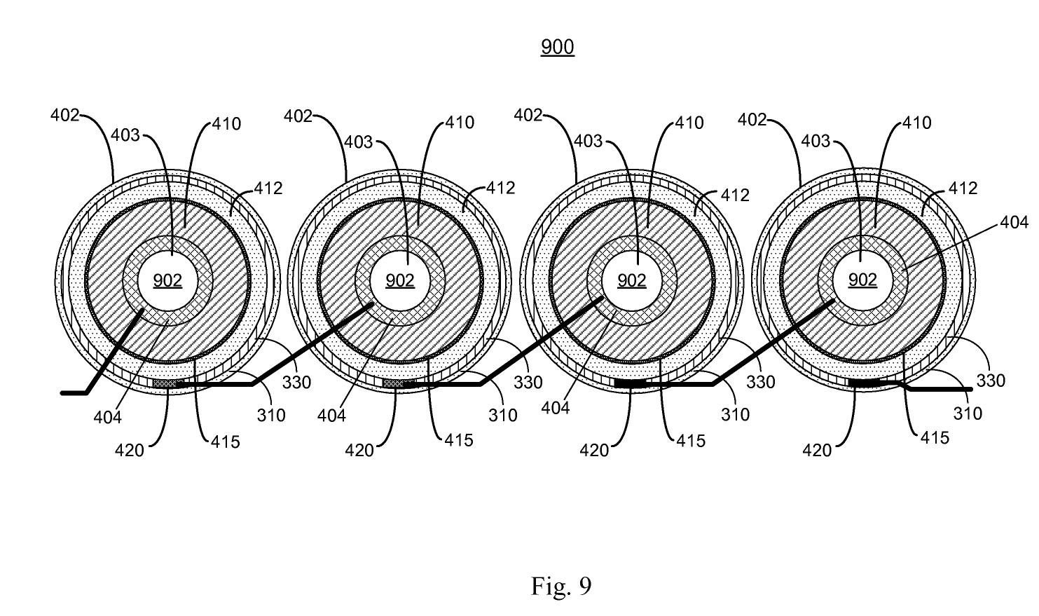

FIG. 9 illustrates an assembly 900 of the present application in which elongated substrates 403 are hollowed. In fact, elongated substrate 403 can be hollowed in any of the embodiments of the present application. One advantage a hollowed elongated substrate 403 design is that it reduces the overall weight of the assembly. The elongated substrate 403 is hollowed when there is a channel that extends lengthwise through all or a portion of the elongated substrate 403. In some embodiments, the elongated substrate 403 is metal tubing. In some embodiments, back-electrode 404 is a thin layer of electrically conducting material, e.g. molybdenum, that is deposited on the elongated substrate 403. In some embodiments, the elongated substrate 403 is made of glass or any of the materials described above in conjunction with the general description of elongated substrate 403.

In some embodiments, not all photovoltaic modules 402 in assembly 900 are electrically arranged in series. For example, in some embodiments, there are pairs of photovoltaic modules 402 that are electrically arranged in parallel. The pairs of photovoltaic modules are then electrically arranged in series. In some embodiments, three, four, five, six, seven, eight, nine, ten, eleven or more photovoltaic modules 402 are electrically arranged in parallel. These parallel groups of photovoltaic modules 402 are then electrically arranged in series.

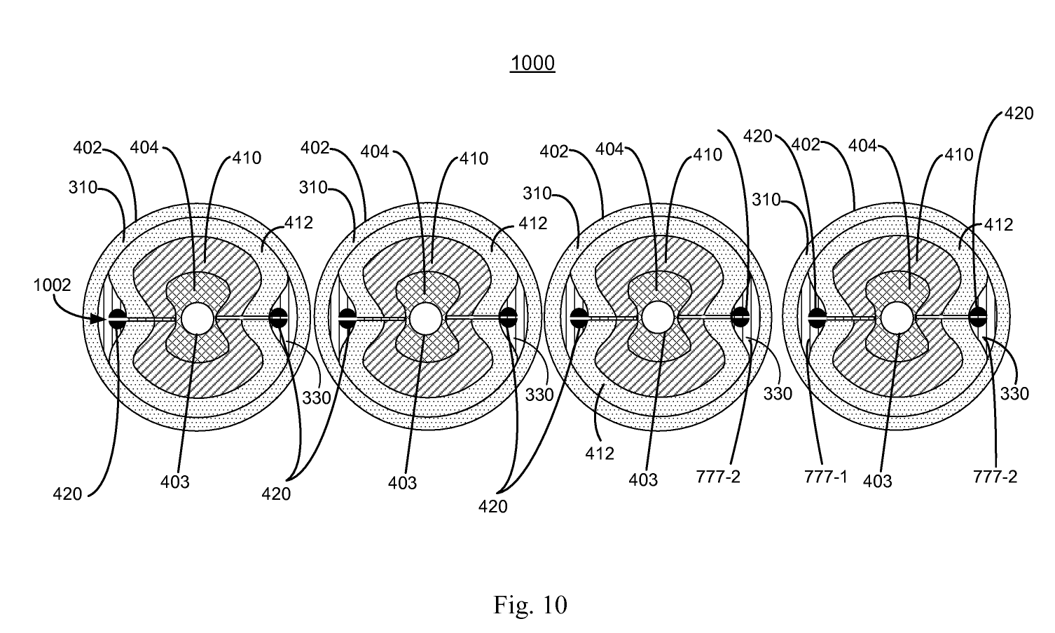

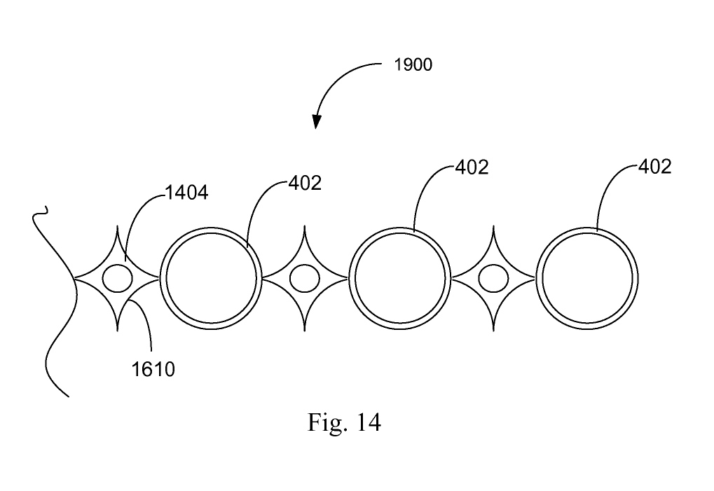

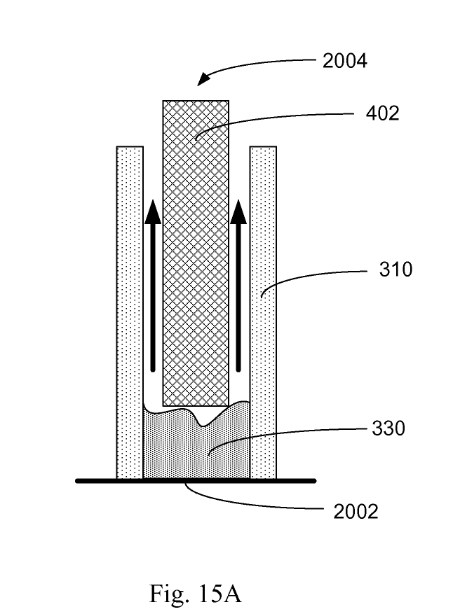

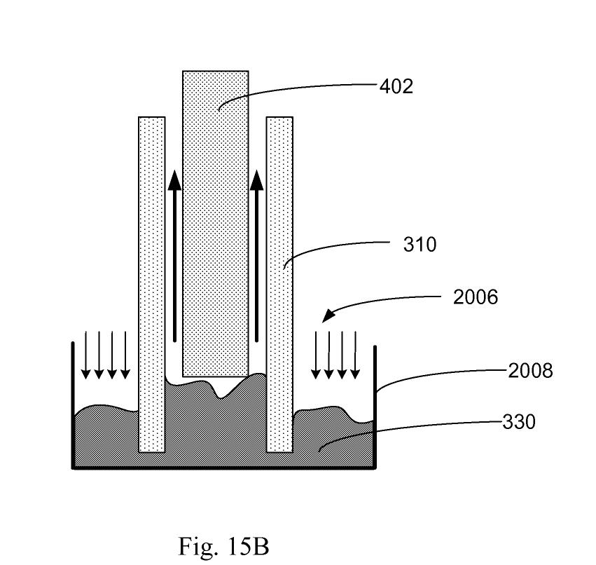

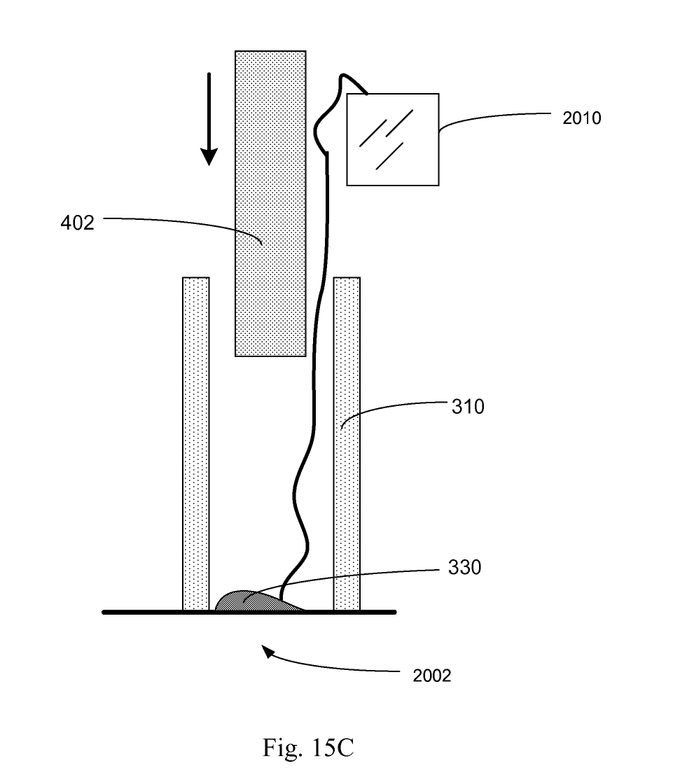

In some embodiments, a transparent casing 310 can be used to cover photovoltaic modules 402. Because it is important to exclude air from the photovoltaic module 402, additional sealant may be used to prevent oxidation of the photovoltaic module 402. Alternatively, as illustrated in FIG. 9, a filler material 330 (for example, EVA or silicone, etc.) may be used to prevent seepage of oxygen and water into photovoltaic modules 402. In some embodiments, the individually encased photovoltaic modules 402 are assembled into a planar array as depicted in FIG. 9. FIG. 10 illustrates an assembly 1000 of the present application in which counter-electrodes 420, transparent conductive layers 412, and junctions 410 are pierced, in the manner illustrated, in order to form two discrete junctions in parallel. In some embodiments, the transparent casing 310, for example as depicted in FIG. 14, may be used to encase photovoltaic module 402 with or without the filler material 330.

### 5.1.2 Transparent Casing

A transparent casing 310, as depicted in FIGS. 3A through 3C, seals a photovoltaic module 402 to provide support and protection to the photovoltaic module. The size and dimensions of the transparent casing 310 are determined by the size and dimension of the photovoltaic modules 402. The transparent casing 310 may be made of glass, plastic or any other suitable material. Examples of materials that can be used to make the transparent casing 310 include, but are not limited to, glass (e.g., soda lime glass), acrylics such as polymethylmethacrylate, polycarbonate, fluoropolymer (e.g., TEFZEL or TEFLON), polyethylene terephthalate (PET), TEDLAR, or some other suitable transparent material. Below are described exemplary methods used to make the transparent casing 310 in some embodiments. In some embodiments, the transparent casing 310 is a glass tubular rod into which a solar cell is fitted. The photovoltaic module is then sealed with a filler material 330 that is poured into the casing 310 in liquid or semi-liquid form, thereby sealing the device.

### 5.1.2.1 Transparent Casing Construction

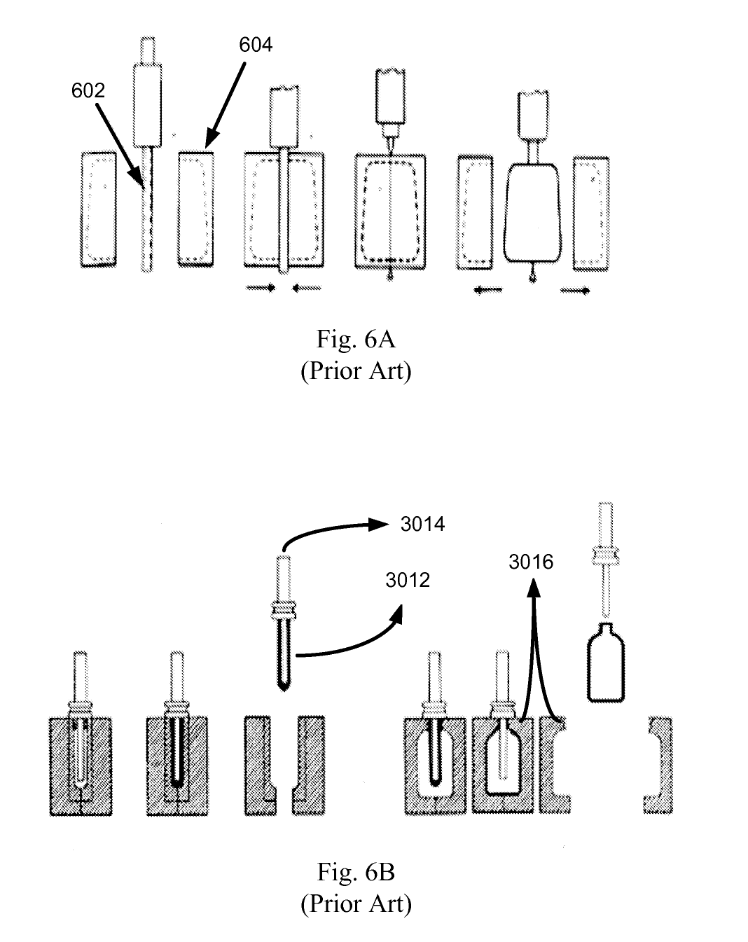

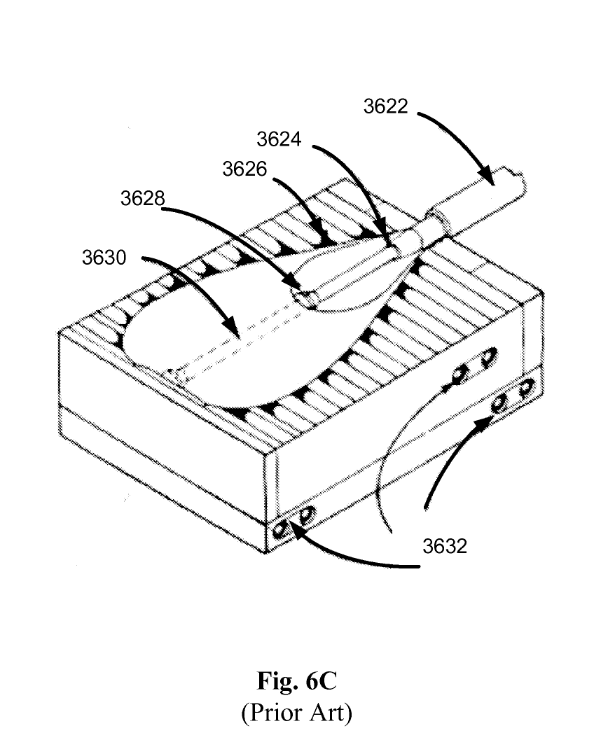

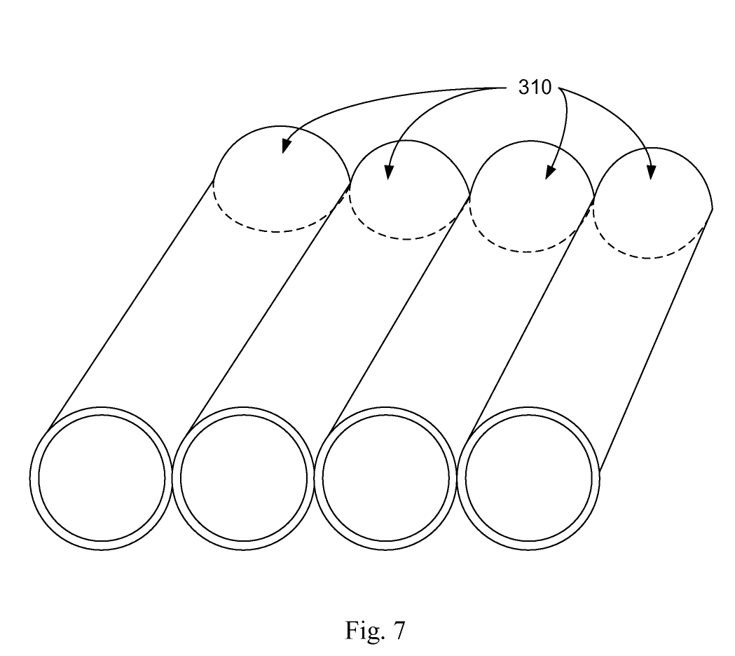

In some embodiments, the transparent casing 310 is constructed using blow molding. Blow molding involves clamping the ends of a softened tube of polymers, which can be either extruded or reheated, inflating the polymer against the mold walls with a blow pin, and cooling the product by conduction or evaporation of volatile fluids in the container. Three general types of blow molding are extrusion blow molding, injection blow molding, and stretch blow molding. U.S. Pat. No. 237,168 describes a process for blow molding (e.g., 602 in FIG. 6A). Other forms of blow molding that can be used to make the transparent casing 310 include low density polyethylene (LDPE) blow molding, high density polyethylene (HDPE) blow molding and polypropylene (PP) blow molding

Extrusion blow molding. As depicted in FIG. 6A, the extrusion blow molding method comprises a Parison (e.g., 602 in FIG. 6A) and mold halves that close onto the Parison (e.g., 604 in FIG. 6A). In extrusion blow molding (EBM), material is melted and extruded into a hollow tube (e.g., a Parison as depicted in FIG. 6A). The Parison is then captured by closing it into a cooled metal mold. Air is then blown into the Parison, inflating it into the shape of the hollow bottle, container or part. After the material has cooled sufficiently, the mold is opened and the part is ejected.

EBM processes consist of either continuous or intermittent extrusion of the Parison 602. The types of EBM equipment may be categorized accordingly. Typical continuous extrusion equipments usually comprise rotary wheel blow molding systems and a shuttle machinery that transports the finished products from the Parison. Exemplary intermittent extrusion machinery comprises a reciprocating screw machinery and an accumulator head machinery. Basic polymers, such as PP, HDPE, PVC and PET are increasingly being coextruded with high barrier resins, such as EVOH or Nylon, to provide permeation resistance to water, oxygen, CO₂ or other substances.

Compared to injection molding, blow molding is a low pressure process, with typical blow air pressures of 25 to 150 psi. This low pressure process allows the production of economical low-force clamping stations, while parts can still be produced with surface finishes ranging from high gloss to textured. The resulting low stresses in the molded parts also help make the containers resistant to strain and environmental stress cracking.

Injection blow molding. In injection blow molding (IBM), as depicted in FIG. 6B, material is injection molded onto a core pin (e.g., 3012 in FIG. 6B); then the core pin is rotated to a blow molding station (e.g., 3014 in FIG. 6B) to be inflated and cooled. The process is divided in to three steps: injection, blowing and ejection. A typical IBM machine is based on an extruder barrel and screw assembly which melts the polymer. The molten polymer is fed into a manifold where it is injected through nozzles into a hollow, heated preform mold (e.g., 3016 in FIG. 6B). The preform mold forms the external shape and is clamped around a mandrel (the core rod, e.g., 3012 in FIG. 6B) which forms the internal shape of the preform. The preform consists of a fully formed bottle/jar neck with a thick tube of polymer attached, which will form the body.

The preform mold opens and the core rod is rotated and clamped into the hollow, chilled blow mold. The core rod 3012 opens and allows compressed air into the preform 614, which inflates it to the finished article shape. After a cooling period the blow mold opens and the core rod is rotated to the ejection position. The finished article is stripped off the core rod and leak-tested prior to packing. The preform and blow mold can have many cavities, typically three to sixteen depending on the article size and the required output. There are three sets of core rods, which allow concurrent preform injection, blow molding and ejection.

Stretch blow molding In the stretch blow molding (SBM) process, as depicted in FIG. 6C, the material is first molded into a “preform,” e.g., 3628 in FIG. 6C, using the injection molded process. A typical SBM system comprises a stretch blow pin (e.g., 3622 in FIG. 6C), an air entrance (e.g., 3624 in FIG. 6C), mold vents (e.g., 3626 in FIG. 6C), a preform (e.g., 3628 in FIG. 6C), and cooling channels (e.g., 3632 in FIG. 6C). These preforms are produced with the necks of the bottles, including threads (the “finish”) on one end. These preforms are packaged, and fed later, after cooling, into an EBM blow molding machine. In the SBM process, the preforms are heated, typically using infrared heaters, above their glass transition temperature, then blown using high pressure air into bottles using metal blow molds. Usually the preform is stretched with a core rod as part of the process (e.g., as in position 3630 in FIG. 6C). The stretching of some polymers, such as PET (polyethylene terepthalate), results in strain hardening of the resin and thus allows the bottles to resist deforming under the pressures formed by carbonated beverages, which typically approach 60 psi.

FIG. 6C shows what happens inside the blow mold. The preform is first stretched mechanically with a stretch rod. As the rod travels down low-pressure air of 5 to 25 bar (70 to 350 psi) is introduced blowing a ‘bubble.’ Once the stretch rod is fully extended, high-pressure air of up to 40 bar (580 psi) blows the expanded bubble into the shape of the blow mold.

Plastic tube manufacturing. In some embodiments, the transparent casing 310 is made of plastic rather than glass. Production of the transparent casing 310 in such embodiments differs from glass transparent casing production even though the basic molding mechanisms remain the same. A typical plastic transparent casing manufacturing process comprises the following steps: extrusion, heading, decorating, and capping, with the latter two steps being optional.

In some embodiments, the transparent casing 310 is made using extrusion molding. A mixture of resin is placed into an extruder hopper. The extruder is temperature controlled as the resin is fed through to ensure proper melt of the resin. The material is extruded through a set of sizing dies that are encapsulated within a right angle cross section attached to the extruder. The forming die controls the shape of the transparent casing 310. The formed plastic sleeve cools under blown air or in a water bath and hardens on a moving belt. After cooling step, the formed plastic sleeve is ready for cutting to a given length by a rotating knife.

The forming die controls the shape of the transparent casing 310. In some embodiments in accordance with the present application the forming dies are custom-made such that the shape of transparent casing 310 complements the shape of the photovoltaic module 402. The forming die also controls the wall thickness of the transparent casing 310. In some embodiments in accordance with the present application, the transparent casing 310 has a wall thickness of 2 mm or thicker, 1 mm or thicker, 0.5 mm or thicker, 0.3 mm or thicker, or of any thickness between 0 and 0.3 mm.

During the production of one open-ended transparent casing, the balance of the manufacturing process can be accomplished in one of three ways. A common method is the “downs” process of compression, molding the head onto the tube. In this process, the sleeve is placed on a conveyor that takes it to the heading operation where the shoulder of the head is bound to the body of the tube while, at the same time, the thread is formed. The sleeve is then placed on a mandrel and transferred down to the slug pick-up station. The hot melt strip or slug is fused onto the end of the sleeve and then transferred onto the mold station. At this point, in one operation, the angle of the shoulder, the thread and the orifice are molded at the end of the sleeve. The head is then cooled, removed from the mold, and transferred into a pin conveyor. Two other heading methods are used in the United States and are found extensively worldwide: injection molding of the head to the sleeve, and an additional compression molding method whereby a molten donut of resin material is dropped into the mold station instead of the hot melt strip or slug.

The headed transparent casing is then conveyed to the accumulator. The accumulator is designed to balance the heading and decorating operation. From here, the transparent casing 310 may go to the decorating operation. Inks for the press are premixed and placed in the fountains. At this point, the ink is transferred onto a plate by a series of rollers. The plate then comes in contact with a rubber blanket, picking up the ink and transferring it onto the circumference of the transparent casing 310. The wet ink on the tube is cured by ultra-violet light or heat. In the embodiments in accordance with the present application, transparency is required in the tube products so the color process is unnecessary. However, a similar method may be used to apply a protective coating to the transparent casing 310.

After decorating, a conveyor transfers the tube to the capping station where the cap is applied and torqued to the customer's specifications. The capping step is unnecessary for the scope of this application.

Additional glass fabrication methods. Glass is a preferred material choice for the transparent casing 310 relative to plastics because glass provides better waterproofing and therefore provides protection and helps to maintain the performance and prolong the lifetime of the photovoltaic module 402. Similar to plastics, glass may be made into a transparent casing 310 using the standard blow molding technologies. In addition, techniques such as casting, extrusion, drawing, pressing, heat shrinking or other fabrication processes may also be applied to manufacture suitable glass transparent casings 310 to circumferentially cover and/or encapsulate photovoltaic modules 402. Molding technologies, in particular micromolding technologies for microfabrication, are discussed in greater detail in Madou, Fundamentals of Microfabrication, Chapter 6, pp. 325-379, second edition, CRC Press, New York, 2002; Polymer Engineering Principles: Properties, Processes, and Tests for Design, Hanser Publishers, New York, 1993; and Lee, Understanding Blow Molding, first edition., Hanser Gardner Publications, Munich, Cincinnati, 2000, each of which is hereby incorporated by reference herein in its entirety.

### 5.1.2.2 Exemplary Materials for Transparent Casing

Transparent casing made of glass. In some embodiments, the transparent casing 310 is made of glass. In its pure form, glass is a transparent, relatively strong, hard-wearing, essentially inert, and biologically inactive material that can be formed with very smooth and impervious surfaces. The present application contemplates a wide variety of glasses for use in making transparent casings 310, some of which are described in this section and others of which are know to those of skill in the relevant arts, and still others that are described in other portions of this application. Common glass contains about 70% amorphous silicon dioxide (SiO₂), which is the same chemical compound found in quartz, and its polycrystalline form, sand. Common glass is used in some embodiments of the present application to make a transparent casing 310. However, common glass is brittle and will break into sharp shards. Thus, in some embodiments, the properties of common glass are modified, or even changed entirely, with the addition of other compounds or heat treatment.

Pure silica (SiO₂) has a melting point of about 2000° C., and can be made into glass for special applications (for example, fused quartz). Two other substances can be added to common glass to simplify processing. One is soda (sodium carbonate Na₂CO₃), or potash, the equivalent potassium compound, which lowers the melting point to about 1000° C. However, the soda makes the glass water-soluble, which is undesirable, so lime (calcium oxide, CaO) is a third component that is added to restore insolubility. The resulting glass contains about 70% silica and is called a soda-lime glass. Soda-lime glass is used in some embodiments of the present application to make a transparent casing 310.

Besides soda-lime, most common glass has other ingredients added to change its properties. Lead glass, such as lead crystal or flint glass, is more ‘brilliant’ because the increased refractive index causes noticeably more “sparkles”, while boron may be added to change the thermal and electrical properties, as in Pyrex. Adding barium also increases the refractive index. Thorium oxide gives glass a high refractive index and low dispersion, and was formerly used in producing high-quality lenses, but due to its radioactivity has been replaced by lanthanum oxide in modern glasses. Large amounts of iron are used in glass that absorbs infrared energy, such as heat absorbing filters for movie projectors, while cerium (IV) oxide can be used for glass that absorbs UV wavelengths (biologically damaging ionizing radiation). Glass having one or more of these additives is used in some embodiments of the present application to make a transparent casing 310.

Common examples of glass material include, but is not limited to, aluminosilicate, borosilicate (e.g., PYREX®, DURAN®, SIMAX®), dichroic, germanium/semiconductor, glass ceramic, silicate/fused silica, soda lime, quartz, chalcogenide/sulphide, cereated glass, and fluoride glass and a transparent casing 310 can be made of any of these materials.

In some embodiments, a transparent casing 310 is made of glass material such as borosilicate glass. Trade names for borosilicate glass include, but are not limited, to PYREX® (Corning), DURAN® (Schott Glass), and SIMAX® (KAVALIER). Like most glasses, the dominant component of borosilicate glass is SiO₂ with boron and various other elements added. Borosilicate glass is easier to hot work than materials such as quartz, making fabrication less costly. Material cost for borosilicate glass is also considerably less than fused quartz. Compared to most glass, except fused quartz, borosilicate glass has low coefficient of expansion, three times less than soda lime glass. This makes borosilicate glass useful in thermal environments, without the risk of breakage due to thermal shock. Like soda lime glass, a float process can be used to make relatively low cost optical quality sheet borosilicate glass in a variety of thickness from less than 1 mm to over 30 mm thick. Relative to quartz, borosilicate glass is easily moldable. In addition, borosilicate glass has minimum devitrification when molding and flame working. This means high quality surfaces can be maintained when molding and slumping. Borosilicate glass is thermally stable up to 500° C. for continuous use. Borosilicate glass is also more resistant to non-fluorinated chemicals than household soda lime glass and mechanically stronger and harder than soda lime glass. Borosilicate is usually two to three times more expensive than soda lime glass.

Soda lime and borosilicate glass are only given as examples to illustrate the various aspects of consideration when using glass material to fabricate a transparent casing 310. The preceding discussion imposes no limitation to the scope of the application. Indeed, the transparent casing 310 can be made with glass such as, for example, aluminosilicate, borosilicate (e.g., PYRAX®, DURAN®, SIMAX®), dichroic, germanium/semiconductor, glass ceramic, silicate/fused silica, soda lime, quartz, chalcogenide/sulphide, cereated glass and/or fluoride glass.

Transparent casing made of plastic. In some embodiments, the transparent casing 310 is made of clear plastic. Plastics are a cheaper alternative to glass. However, plastic material is in general less stable under heat, has less favorable optical properties and does not prevent molecular water from penetrating the transparent casing 310. The last factor, if not rectified, damages photovoltaic modules 402 and severely reduces their lifetime. Accordingly, in some embodiments, the water resistant layer described in Section 5.1.1. is used to prevent water seepage into the photovoltaic modules 402 when the transparent casing 310 is made of plastic.

A wide variety of materials can be used to make a transparent casing 310, including, but not limited to, ethylene vinyl acetate (EVA), perfluoroalkoxy fluorocarbon (PFA), nylon/polyamide, cross-linked polyethylene (PEX), polyolefin, polypropylene (PP), polyethylene terephtalate glycol (PETG), polytetrafluoroethylene (PTFE), thermoplastic copolymer (for example, ETFE®, which is a derived from the polymerization of ethylene and tetrafluoroethylene: TEFLON® monomers), polyurethane/urethane, polyvinyl chloride (PVC), polyvinylidene fluoride (PVDF), TYGON®, Vinyl, and VITON®, acrylics, and polycarbonates.

### 5.1.2.3 Available Commercial Sources of Transparent Tubing Products

There are ample commercial sources for obtaining or custom manufacturing a transparent casing 310. Technologies for manufacturing plastic or glass tubing have been standardized and customized plastic or glass tubing are commercially available from numerous companies. A search on GlobalSpec database for “clear round plastic or glass tubing,” a web center of engineering resources (GlobalSpec Inc. Troy, N.Y.), results in over 950 catalog products. Over 180 companies make specialty pipe, tubing, hose and fittings. For example, Clippard Instrument Laboratory, Inc. (Cincinnati, Ohio) provides Nylon, Urethane or Plastic Polyurethane tubing that is as thin as 0.4 mm. Coast Wire & Plastic Tech., Inc. (Carson, Calif.) manufactures a comprehensive line of polyvinylidene fluoride clear round plastic tubing product under the trademark SUMIMARK™. Their product has a wall thickness as thin as 0.3 mm. Parker Hannifin/Fluid Connectors/Parflex Division (Ravenna, Ohio) provides vinyl, plastic polyurethane, polyether base, or polyurethane based clear plastic tubing of 0.8 mm or 1 mm thickness. Similar polyurethane products may also be found in Pneumadyne, Inc (Plymouth, Minn.). Saint-Gobain High-Performance Materials (U.S.A) further provides a line of 30 TYGON® tubing products of 0.8 mm in thickness. Vindum Engineering, Inc. (San Ramon, Calif.) also provides clear PFA Teflon tube of 0.8 mm in thickness. NewAge Industries, Inc. (Southampton, Pa.) provides 63 clear round plastic tubing products that have a wall thickness of 1 mm or thinner. In particular, VisiPak Extrusion (Arnold, Mo.), a division of Sinclair & Rush, Inc., provides clear round plastic tubing product as thin as 0.5 mm. Cleartec Packaging (St. Louis, Mo., a division of MOCAP, Inc.) manufactures clear round plastic tubing as thin as 0.3 mm.

In addition, numerous companies can manufacture clear round plastic or glass tubing with customized specification such as with even thinner walls. Some examples are Elasto Proxy Inc. (Boisbriand, Canada), Flex Enterprises, Inc. (Victor, N.Y.), Grob, Inc. (Grafton, Wis.), Mercer Gasket & Shim (Bellmawr, N.J.), New England Small Tube Corporation (Litchfield, N.H.), Precision Extrusion, Inc. (Glens Falls, N.Y.), and PSI Urethanes, Inc. (Austin, Tex.).

### 5.1.3 Integrating Photovoltaic Modules into Transparent Casings

In the present application, gaps or spaces between a transparent casing 310 and the underlying layers of the photovoltaic module 402 are eliminated in order to avoid adverse effects such as oxidation and water damage. Thus, in the present application, there is no void between the inside wall of a transparent casing 310 and the outer wall of the solar cells 12 of the photovoltaic module 402. In some embodiments (e.g., FIG. 3B), a filler material 330 is provided to seal a photovoltaic module 402 from adverse exposure to water or oxygen.

In some embodiments, a custom-designed transparent casing 310, made of either glass or plastics or other suitable transparent material, may be used to encase the corresponding embodiments of a photovoltaic module 402 to achieve tight fitting and better protection.

Rod or cylindrical shaped photovoltaic modules 402, individually encased by transparent a casing 310 can be assembled into solar cell assemblies of any shape and size. In some embodiments, the assembly can be monofacial, bifacial, multi-facial, or omnifacial arrays. There is no limit to the number of photovoltaic modules 402 in this plurality (e.g., 10 or more, 100 or more, 1000 or more, 10,000 or more, between 5,000 and one million photovoltaic modules 402, etc.).

Alternatively, instead of being encapsulated individually and then being assembled together for example into planar arrays, photovoltaic modules 402 may also be encapsulated as arrays. For example, as depicted in FIG. 7, multiple transparent casings may be manufactured as fused arrays. There is no limit to the number of transparent casings 310 in the assembly as depicted in FIG. 7 (e.g., 10 or more, 100 or more, 1000 or more, 10,000 or more, between 5,000 and one million transparent casings 310, etc.). In such embodiments, a assembly is further completed by loading the photovoltaic module 402 (for example 402 in FIG. 4A) into all or a portion of the transparent casing 310 in the array of casings.

### 5.1.3.1 Integrating Photovoltaic Modules Having a Filler Material into Transparent Casings

In some embodiments in accordance with the present application, a photovoltaic module 402 having a filler material coated thereon is assembled into a transparent casing 310. In some embodiments in accordance with the present application, the filler material 330 comprises one or more of the properties of: electrical insulation, oxidation eliminating effect, water proofing, and/or physical protection of transparent conductive layer 412 of a solar cell 12 of a photovoltaic module 402 during assembly.

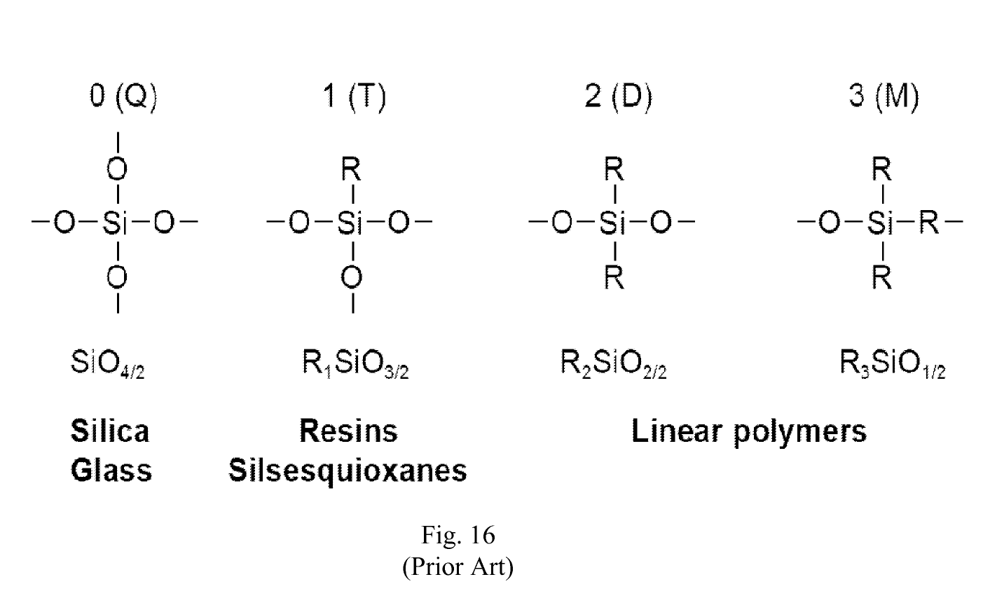

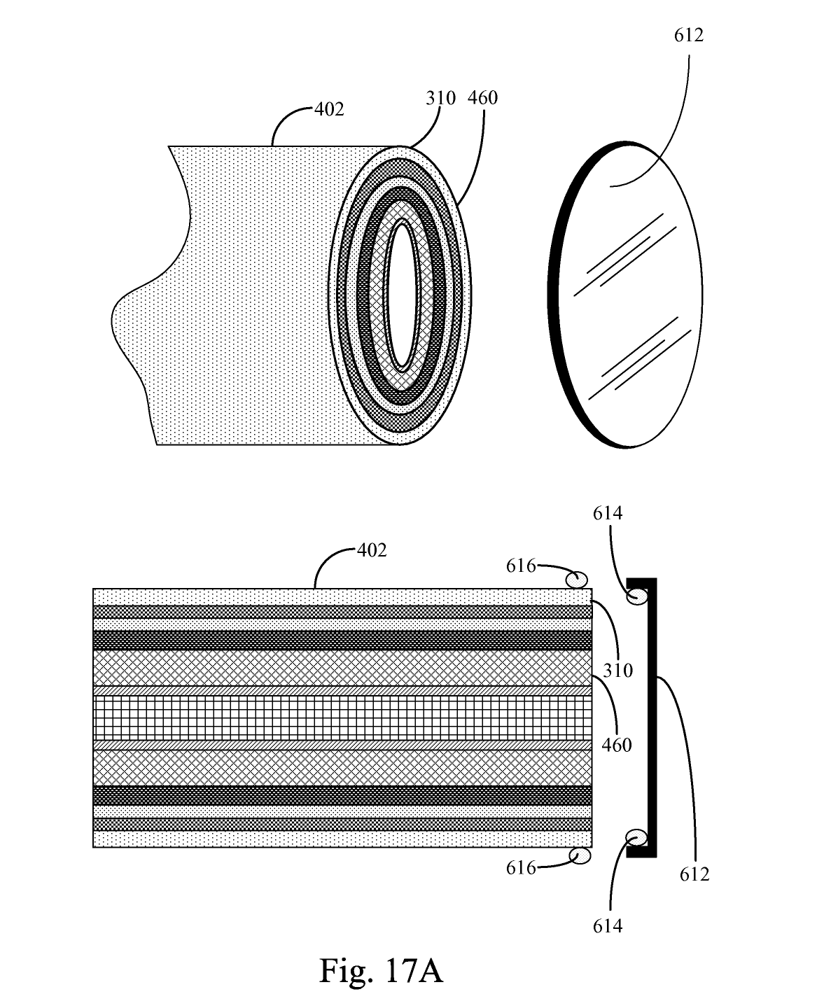

In some embodiments in accordance with the present application, the transparent casing 310 and filler material 330 assembled into the photovoltaic module 402 using a suction loading method. A transparent casing 310, made of transparent glass, plastics or other suitable material, is sealed at one end. Materials that are used to form the filler material 330, for example, silicone gel, are then poured into the sealed transparent casing 310. An example of a silicone gel is Wacker SILGEL® 612 (Wacker-Chemie GmbH, Munich, Germany). Wacker SILGEL® 612 is a pourable, addition-curing, RTV-2 silicone rubber that vulcanizes at room temperature to a soft silicone gel. Still another example of silicone gel is SYLGARD® silicone elastomer (Dow Corning). Another example of a silicone gel is Wacker ELASTOSIL® 601 (Wacker-Chemie GmbH, Munich, Germany). Wacker ELASTOSIL® 601 is a pourable, addition-curing, RTV-2 silicone rubber. Referring to FIG. 16, silicones can be considered a molecular hybrid between glass and organic linear polymers. As shown in FIG. 16, if there are no R groups, only oxygen, the structure is inorganic silica glass (called a Q-type Si). If one oxygen is substituted with an R group (e.g. methyl, ethyl, phenyl, etc.) a resin or silsequioxane (T-type Si) material is formed. These silsequioxanes are more flexible than the Q-type materials. Finally, if two oxygen atoms are replaced by organic groups a very flexible linear polymer (D-type Si) is obtained. The last structure shown (M-type Si) has three oxygen atoms replaced by R groups, resulting in an end cap structure. Because the backbone chain flexibility is increasing as R groups are added, the modulus of the materials and their coefficients of thermal expansion (CTE) also change. In some embodiments of the present application, the silicone used to form filler material is a Q-type silicone, a silsequioxane, a D-type silicone, or an M-type silicone. The elongated photovoltaic module 402 is then loaded into a transparent casing 310. Optional suction force may be applied at the open end of the transparent casing 310 to draw the filler material upwards to completely fill the space between the outer layers of the solar cells 12 and the transparent casing 310.

In some embodiments in accordance with the present application, a transparent casing 310 and filler material are assembled into a photovoltaic module using a pressure loading method. The transparent casing 310, made of transparent glass, plastics or other suitable material, is dipped in a container containing filler material (e.g., silicone gel) used to form the filler material 330. The photovoltaic module 402 is then loaded into the transparent casing 310. Pressure force is applied at the filler material surface to put the filler material upwards to completely fill the space between outer layers of the solar cells 12 and the transparent casing 310.

In yet other embodiments in accordance with the present application a transparent casing 310 and filler material 330 are assembled into the photovoltaic module 402 using a pour-and-slide loading method. A transparent casing 310, made of transparent glass, plastics or other suitable material, is sealed at one end. A container, containing filler material (e.g., silicone gel), is used to pour the filler material into the sealed transparent casing 310 while the photovoltaic module 402 is simultaneously slid into the transparent casing 310. The material that is being poured into the transparent casing 310 fills up the space between the photovoltaic module 402 and the transparent casing 310. Advantageously, the filler material that is being poured down the side of the transparent casing 310 provides lubrication to facilitate the slide-loading process.

### 5.1.3.2 Additional Methods for Forming Transparent Casing

In some embodiments, the transparent casing 310 is formed on the filler material 330) by spin coating, dip coating, plastic spraying, casting, Doctor's blade or tape casting, glow discharge polymerization, or UV curing. These techniques are discussed in greater detail in Madou, Fundamentals of Microfabrication, Chapter 3, pp. 159-161, second edition, CRC Press, New York, 2002, which is hereby incorporated by reference herein in its entirety. Casting is particularly suitable in instances where the transparent casing 310 is formed from acrylics or polycarbonates. UV curing is particularly suitable in instances where the transparent casing 310 is formed from an acrylic.

### 5.1.4 Optical, Chemical, and Dimensional Properties of the Materials Used for the Photovoltaic Module

In order to maximize input of solar radiation, any layer outside a photovoltaic module 402 (for example, the filler material 330 or the transparent casing 310) should not adversely affect the properties of incident radiation on the photovoltaic module. There are multiple factors to consider in optimizing the efficiency of the photovoltaic modules 402. A few significant factors will be discussed in detail in relation to solar cell production.

Transparency. In order to establish maximized input into semiconductor junction 410, absorption of the incident radiation by any layer outside a solar cell 12 should be avoided or minimized. This transparency requirement varies as a function of the absorption properties of the underlying semiconductor junction 410 of solar cells 12 of a photovoltaic module. In general, the transparent casing 310 and the filler material 330 should be as transparent as possible to the wavelengths absorbed by the semiconductor junction 410. For example, when the semiconductor junction 410 is based on CIGS, materials used to make transparent casing 310 and the filler material 330 should be transparent to light in the 500 nm to 1200 nm wavelength range.

Ultraviolet Stability. Any material used to construct a layer outside a solar cell 12 of the photovoltaic module 402 should be chemically stable and, in particular, stable upon exposure to UV radiation. More specifically, such material should not become less transparent upon UV exposure. Ordinary glass partially blocks UVA (wavelengths 400 and 300 nm) and it totally blocks UVC and UVB (wavelengths lower than 300 nm). The UV blocking effect of glass is usually due to additives, e.g. sodium carbonate, in glass. In some embodiments, additives in the transparent casings 310 made of glass can render the casing 310 entirely UV protective. In such embodiments, because the transparent casing 310 provides complete protection from UV wavelengths, the UV stability requirements of the underlying filler material 330 are reduced. For example, EVA, PVB, TPU (urethane), silicones, polycarbonates, and acrylics can be adapted to form a filler material 330 when the transparent casing 310 is made of UV protective glass. Alternatively, in some embodiments, where the transparent casing 310 is made of plastic material, UV stability requirement may be adopted.

Plastic materials that are sensitive to UV radiation are not used as the transparent casing 310 in some embodiments because yellowing of the material and/or filler material 330 blocks radiation input into the photovoltaic modules 402 and reduces their efficiency. In addition, cracking of the transparent casing 310 due to UV exposure permanently damages the photovoltaic modules 402. For example, fluoropolymers like ETFE, and THV (Dyneon) are UV stable and highly transparent, while PET is transparent, but not sufficiently UV stable. In some embodiments, the transparent casing 310 is made of fluoropolymer based on monomers of tetrafluoroethylene, hexafluoropropylene and vinylidene fluoride. In addition, polyvinyl chloride (“PVC” or “vinyl”), one of the most common synthetic materials, is also sensitive to UV exposure. Methods have been developed to render PVC UV-stabilized, but even UV stabilized PVC is typically not sufficiently durable (for example, yellowing and cracking of PVC product will occur over relative short term usage). Urethanes are better suited, but depend on the exact chemical nature of the polymer backbone. Urethane material is stable when the polymer backbone is formed by less reactive chemical groups (e.g., aliphatic or aromatic). On the other hand when the polymer backbone is formed by more reactive groups (e.g., double bonds), yellowing of the material occurs as a result of UV-catalyzed breakdown of the double bonds. Similarly, EVA will yellow and so will PVB upon continued exposure to UV light. Other options are polycarbonate (can be stabilized against UV for up to 10 years OD exposure) or acrylics (inherently UV stable).

Electrical Insulation. A characteristic of the transparent casing 310 and the filler material 330 in some embodiments is electrical insulation. In some embodiments, conductive material is used to form either the transparent casing 310 or the filler material 330.

Dimension requirement in some embodiments in which the photovoltaic module 402 has a cylindrical shape. The combined width of each of the layers outside the solar cells 12 of a photovoltaic module 402 (e.g., the combination of the transparent casing 310 and/or filler material 330) in some embodiments is:

$${r}_{i} \geq \frac{{r}_{o}}{{η}_{outer ring}}$$

where, referring to FIG. 3B,

rᵢ is the radius of the photovoltaic module 402, assuming that semiconductor junction 410 is a thin-film junction;

rₒ is the radius of the outermost layer of the transparent casing 310 and/or the filler material 330; and

η_{outer ring} is the refractive index of the outermost layer of the transparent casing 310 and/or the filler material 330.

As noted above, in some embodiments, the refractive index of many, but not all, of the materials used to make the transparent casing 310 and/or the filler material 330 is about 1.5. Thus, in some embodiments, values of rₒ are permissible that are less than 1.5*rᵢ. This constraint places a boundary on allowable thickness for the combination of the transparent casing 310 and/or the filler material 330. Alternatively, the radius of can be of fixed value, and thus η_{outer ring} is chosen to obey the inequality. For example, if rᵢ=7.5 mm and rₒ=11 mm, then η_{outer ring} must be greater or equal to 1.467. In some embodiments, the diameter of the outermost layer (e.g. the transparent casing 310) is between 20 and 24 mm, between 15 and 30 mm, over 20 mm, over 22 mm, or over 15 mm. In some embodiments, the diameter of the photovoltaic module 402 is between 13 and 17 mm, between 10 and 20 mm, below 22 cm, below 20 cm, or below 17 cm. In some embodiments the thickness of the transparent casing 310 and/or the filler material 330 is 1.5 mm, between 1.2 and 1.7 mm, or between 1 mm and 2 mm.

When light is refracted towards solar cells 12 of the photovoltaic module 402 while passing through layers 310 and 330, the photovoltaic module 402 are able to capture more light than if layers 310 and 330 were not present. This increases the effective optical area of the photovoltaic module 402 (specifically the effective optical area of transparent conductive layer 412). As the amount of refraction increases, so does the effective optical area of layer 412.

In some embodiments, η₃₃₀ is chosen so that the effective optical area of the surface of transparent conductive layer 412 is approximately equal to the area of the surface of transparent casing 310. This occurs when a light beam that hits the transparent casing 310 tangentially is refracted so that it is tangentially hits the surface of the transparent conductive layer 412. Using Snell's Law with η₁=ηₐᵢᵣ and θ₁=90 degrees (tangential incident ray), then:

1=η₂ sin(θ₂)

where η₂ is the effective refractive index of the transparent casing 310 and/or the filler material 330 (also known as η_{outer ring}). If rᵢ is much smaller than rₒ, then θ₂ is small and η₂ must be much larger than 1 for the photovoltaic module 402 to have an effective optical area approximately equal to the transparent casing 310. If rᵢ is only slightly smaller than rₒ, then θ₂ is larger and η₂ does not have to be much larger than 1 to achieve the same effect.

For purposes of this specification, a photovoltaic module 402 (also interchangeably referred to herein as an elongated photovoltaic module) is one that is characterized by having a longitudinal dimension and a width dimension. In some embodiments of a photovoltaic module 402, the longitudinal dimension exceeds the width dimension by at least a factor of 4, at least a factor of 5, or at least a factor of 6. In some embodiments, the longitudinal dimension of the photovoltaic module 402 is 10 centimeters (cm) or greater, 20 cm or greater, 100 cm or greater. In some embodiments, the width dimension of the photovoltaic module 402 is a diameter of 500 mm or more, 1 cm or more, 2 cm or more, 5 cm or more, or 10 cm or more. The elongated substrate of the module can be rigid in nature. The elongated substrate can be a solid substrate, or a hollow substrate. The elongated substrate can be closed at both ends, only at one end, or open at both ends.

### 5.2 Exemplary Semiconductor Junctions

Referring to FIG. 5A, in one embodiment, the semiconductor junction 410 is a heterojunction between an absorber layer 502, disposed on all or a portion of the back-electrode 404, and a junction partner layer 504, disposed on all or a portion of the absorber layer 502. In other embodiments, the junction partner layer 504 is disposed on all or a portion of back-electrode 404, and the absorber layer 502 is disposed on all or a portion of the junction partner layer 504. The absorber 502 and junction partner 504 layers are composed of different semiconductors with different band gaps and electron affinities such that the junction partner layer 504 has a larger band gap than the absorber layer 502.

For example, in some embodiments, the absorber layer 502 is p-doped and junction partner layer 504 (window layer) is n-doped. In such embodiments, the transparent conductive layer 412 is n⁺-doped. In alternative embodiments, the absorber layer 502 is n-doped and junction partner layer 504 is p-doped. In such embodiments, transparent conductive layer 412 is p⁺-doped. In some embodiments, the semiconductors listed in Pandey, Handbook of Semiconductor Electrodeposition, Marcel Dekker Inc., 1996, Appendix 5, which is hereby incorporated by reference herein in its entirety, are used to form the semiconductor junction 410.

Characteristics of solar cells based on p-n junctions. The principles of operation of solar cells based on p-n junctions (which is one form of semiconductor junction 410) are well understood. Briefly, a p-type semiconductor is placed in intimate contact with an n-type semiconductor. At equilibrium, electrons diffuse from the n-type side of the junction to the p-type side of the junction, where they recombine with holes, and holes diffuse from the p-type side of the junction to the n-type side of the junction, where they recombine with electrons. The resultant imbalance of charges creates a potential difference across the junction and forms a “space charge region” or “depletion layer,” which no longer contains mobile charge carriers, near the junction.

The p-type and n-type sides of the junction are connected to respective electrodes that are connected to an external load. In operation, one of the two junction layers behaves as an absorber, and the other junction layer is referred to as a “junction partner layer.” The absorber absorbs photons having energies above the band gap of the material of which it is made (more below), which generates electrons that drift under the influence of the potential generated by the junction. “Drift” is a charged particle's response to an applied electric field. The electrons drift to the electrode connected to the absorber, drift through the external load (thus generating electricity), and then into the junction partner layer. At the junction partner layer, the electrons recombine with holes in the junction partner layer. In some junctions 410 of the present application, a significant portion if not substantially all of the electricity generated by the junction (e.g., the electrons in the external load) derives from the absorption of photons by the absorber, e.g., greater than 30%, greater than 50%, greater than 60%, greater than 70%, greater than 80%, greater than 90%, greater than 95%, greater than 98%, greater than 99%, or substantially all of the electricity generated by the junction 410 derives from the absorption of photons in the visible spectrum by the absorber. In some embodiments, a significant portion if not substantially all of the electricity generated by photovoltaic modules 402 (e.g., the electrons in the external load) derives from the absorption of photons by the absorber, e.g., greater than 30%, greater than 50%, greater than 60%, greater than 70%, greater than 80%, greater than 90%, greater than 95%, greater than 98%, greater than 99%, or substantially all of the electricity generated by the junction 410 derives from the absorption of photons by the absorber. For further details, see Chapter 3 of Handbook of Photovoltaic Science and Engineering, 2003, Luque and Hegedus (eds.), Wiley & Sons, West Sussex, England, the entire contents of which are hereby incorporated by reference herein.

Note that dye and polymer-based thin-film solar cells are generally not p-n-junction solar cells, and the dominant mode of electron-hole separation is via charge carrier diffusion, not drift in response to an applied electric field. For further details on dye- and polymer-based thin film solar cells, see Chapter 15 of Handbook of Photovoltaic Science and Engineering, 2003, Luque and Hegedus (eds.), Wiley & Sons, West Sussex, England, the entire contents of which are hereby incorporated by reference herein.

Material Characteristics. In some embodiments, materials for use in the semiconductor junctions 410 are inorganic meaning that they substantially do not contain reduced carbon, noting that negligible amounts of reduced carbon may naturally exist as impurities in such materials. As used herein, the term “inorganic compound” refers to all compounds, except hydrocarbons and derivatives of hydrocarbons as set forth by Moeller, 1982, Inorganic Chemistry, A modern Introduction, Wiley, New York, p. 2, which is hereby incorporated by reference herein.

In some embodiments, materials for use in semiconductor junctions are solids, that is, the atoms making up the material have fixed positions in space relative to each other, with the exception that the atoms may vibrate about those positions due to the thermal energy in the material. A solid object is in the state of matter characterized by resistance to deformation and changes of volume. At the microscopic scale, a solid has the following properties. First, the atoms or molecules that make up a solid are packed closely together. Second, the constituent elements of a solid have fixed positions in space relative to each other. This accounts for the solid's rigidity. A crystal structure, which is one non-limiting form of a solid, is a unique arrangement of atoms in a crystal. A crystal structure is composed of a unit cell, a set of atoms arranged in a particular way; which is periodically repeated in three dimensions on a lattice. The spacing between unit cells in various directions is called its lattice parameters. The symmetry properties of the crystal are embodied in its space group. A crystal's structure and symmetry play a role in determining many of its properties, such as cleavage, electronic band structure, and optical properties. Third, if sufficient force is applied, either of the first and second properties identified above can be disrupted, causing permanent deformation.

In some embodiments, the semiconductor junction is in a solid state. In some embodiments, all of the layers in the solar cell are in a solid state. In some embodiments, any combination of the substrate 403, the back-electrode 404, the semiconductor junction 410, the optional intrinsic layer 415, the transparent conductive layer 412, the optional filler material 330, the transparent casing 310, the water resistant layer, and the antireflective coating is in the solid state.

Many, but not all, of the described semiconductor materials are crystalline or polycrystalline. By “crystalline” it is meant that the atoms or molecules making up the material are arranged in an ordered, repeating pattern that extends in all three spatial dimensions. By “polycrystalline” it is meant that the material includes crystalline regions, but that the arrangement of atoms or molecules within each particular crystalline region is not necessarily related to the arrangement of atoms or molecules within other crystalline regions. In polycrystalline materials, grain boundaries typically separate one crystalline region from another. In some embodiments, more than 10%, more than 20%, more than 30%, more than 40%, more than 50%, more than 60%, more than 70%, more than 80%, more than 90%, more than 99% or more of the material making up the absorber and/or the junction partner layer is in a crystalline state. In other words, in some embodiments more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are independently arranged into one or more crystals, where such crystals are in the triclinic, monoclinic, orthorhombic, tetragonal, trigonal (rhombohedral lattice), trigonal (hexagonal lattice), hexagonal, or cubic crystal system defined by Table 3.1 of Stout and Jensen, 1989, X-ray Structure Determination, A Practical Guide, John Wiley & Sons, p. 42, which is hereby incorporated by reference herein. In some embodiments, more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are independently arranged into one or more crystals that each conform to the symmetry of the triclinic crystal system, that each conform to the symmetry of the monoclinic crystal system, that each conform to the symmetry of the orthorhombic crystal system, that each conform to the symmetry of the tetragonal crystal system, that each conform to the symmetry of the trigonal (rhombohedral lattice) crystal system, that each conform to the symmetry of the trigonal (hexagonal lattice) crystal system, that that each conform to the symmetry of the hexagonal crystal system, or that each conform to the symmetry of the cubic crystal system. In some embodiments, more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are independently arranged into one or more crystals, where each of the one or more crystals is independently in any one of the 230 possible space groups. For a list of the 230 possible space groups, see Table 3.4 of Stout and Jensen, 1989, X-ray Structure Determination, A Practical Guide, John Wiley & Sons, p. 68-69, which is hereby incorporated by reference herein. In some embodiments, more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are arranged in a cubic space group. For a list of each of the cubic space groups, see Table 3.4 of Stout and Jensen, 1989, X-ray Structure Determination, A Practical Guide, John Wiley & Sons, p. 68-69, which is hereby incorporated by reference herein. In some embodiments, more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are arranged in a tetragonal space group. For a list of each of the tetragonal space groups, see Table 3.4 of Stout and Jensen, 1989, X-ray Structure Determination, A Practical Guide, John Wiley & Sons, p. 68-69, which is hereby incorporated by reference herein. In some embodiments, more than 10%, more than 20%, more than 30%, more than 40%, more than 50%, more than 60%, more than 70%, more than 80%, more than 90%, more than 99% or more of the molecules of the material making up the absorber and/or the junction partner layer of a semiconductor junction 410 are arranged in the Fm3m space group. The absorber and/or the junction partner layer of a semiconductor junction may include one or more grain boundaries.

In typical embodiments, the materials used in semiconductor junctions 410 are solid inorganic semiconductors. That is, such materials are inorganic, they are in a solid state, and they are semiconductors. A direct consequence of such materials being in such a state is that the electronic band structure of such materials has a unique band structure in which there is an almost fully occupied valence band and an almost fully unoccupied conduction band, with a forbidden gap between the valence band and the conduction band that is referred to herein as the band gap. In some embodiments, at least 80%, or at least 90%, or substantially of the molecules in the absorber layer are inorganic semiconductor molecules, and at least 80%, or at least 90%, or substantially all of the molecules in the junction partner layer are inorganic semiconductor molecules.

Others of the described semiconductor materials, such as Si in some embodiments, are amorphous. By “amorphous” it is meant a material in which there is no long-range order of the positions of the atoms or molecules making up the material. For example, on length scales greater than 10 nm, or greater than 50 nm, there is typically no recognizable order in an amorphous material. However, on small length scales (e.g., less than 5 nm, or less than 2 nm) even amorphous materials may have some short-range order among the atomic positions such that, on small length scales, such materials obey the requirements of one of the 230 possible space groups in standard orientation.

In some embodiments, semiconducting materials suitable for use in various embodiments of solar cells, such as those described herein, are non-polymeric (e.g., not based on organic polymers). In general, although a polymer may have a repeating chemical structure based on the monomeric units of which it is made, those of skill in the art recognize that polymers are typically found in the amorphous state because there is typically no long-range order to the spatial positions of portions of the polymer relative to other portions and because the spatial positions of such polymers do not obey the symmetry requirements of any of the 230 possible space groups or any of the symmetry requirements of any of the seven crystal systems. However, it is recognized that polymer materials may have short-range crystalline regions.

Band gaps. In some embodiments of the present application, at least forty percent, at least fifty percent, at least sixty percent, at least seventy percent, at least eighty percent, at least ninety percent, at least ninety-five percent, at least 99 percent or substantially all of the energy generated in the solar cell is generated by the absorber layer (e.g. any layer that is deemed to be an absorber layer in a semiconductor junction 410 disclosed herein) absorbing photons with energies at or above the band gap of the absorber layer. For example, at least about 30%, at least about 40%, at least about 50%, at least about 60%, at least about 70%, at least about 80%, at least about 85%, at least about 90%, at least about 95%, at least about 98%, at least about 99%, or even more of the energy generated in the solar cell is generated by the absorber layer (e.g., any layer that is deemed to be an absorber layer in a semiconductor junction 410 disclosed herein) absorbing photons with energies at or above the band gap of the absorber layer.

Usefully, in many embodiments, the semiconductor junction, e.g., absorber layer 502 and junction partner layer 504, each have a band gap between, e.g., about 0.6 eV (about 2066 nm) and about 2.4 eV (about 516 nm). In some embodiments, a semiconductor junction 410 has a band gap between, e.g., about 0.7 eV (about 1771 nm) and about 2.2 eV (about 563 nm). In some embodiments, the absorber layer or the junction partner layer in a semiconductor junction 410 band gap has a band gap between, e.g., about 0.8 eV (about 1550 nm) and about 2.0 eV (about 620 nm). In some embodiments, an absorber layer or a junction partner layer in a semiconductor junction 410 has a band gap between, e.g., about 0.9 eV (about 1378 nm) and about 1.8 eV (about 689 nm). In some embodiments, an absorber layer or a junction partner layer in a semiconductor junction 410 has a band gap between, e.g., about 1 eV (about 1240 nm) and about 1.6 eV (about 775 nm). In some embodiments, an absorber layer or a junction partner layer in a semiconductor junction 410 has a band gap between, e.g., about 1.1 eV (about 1127 nm) and about 1.4 eV (about 886 nm). In some embodiments, an absorber layer or a junction partner layer in a semiconductor junction 410 has a band gap between, e.g., about 1.1 eV (about 1127 nm) and about 1.2 eV (about 1033 nm). In some embodiments, an absorber layer or a junction partner layer in a semiconductor junction 41 410 has a band gap between, e.g., about 1.2 eV (about 1033 nm) and about 1.3 eV (about 954 nm).

In some embodiments, the absorber layer and/or the junction partner layer in a semiconductor junction 410 has a band gap between, e.g., 0.6 eV (2066 nm) and 2.4 eV (516 nm), 0.7 eV (1771 nm) and 2.2 eV (563 nm), 0.8 eV (1550 nm) and 2.0 eV (620 nm), 0.9 eV (1378 nm) and 1.8 eV (689 nm), 1 eV (1240 nm) and 1.6 eV (775 nm), 1.1 eV (1127 nm) and 1.4 eV (886 nm), or 1.2 eV (1033 nm) and 1.3 eV (954 nm). In some embodiments, an absorber layer in a semiconductor junction 410 has a band gap between, e.g., 0.6 eV (2066 nm) and 2.4 eV (516 nm), 0.7 eV (1771 nm) and 2.2 eV (563 nm), e.g., 0.8 eV (1550 nm) and 2.0 eV (620 nm), 0.9 eV (1378 nm) and 1.8 eV (689 nm), 1 eV (1240 nm) and 1.6 eV (775 nm), 1.1 eV (1127 nm) and 1.4 eV (886 nm), or 1.2 eV (1033 nm) and 1.3 eV (954 nm). In some embodiments, a junction partner layer in a semiconductor junction 410 has a band gap between, e.g., 0.6 eV (2066 nm) and 2.4 eV (516 nm), e.g., 0.7 eV (1771 nm) and 2.2 eV (563 nm), 0.8 eV (1550 nm) and 2.0 eV (620 nm), e.g., 0.9 eV (1378 nm) and 1.8 eV (689 nm), e.g., 1 eV (1240 nm) and 1.6 eV (775 nm), 1.1 eV (1127 nm) and 1.4 eV (886 nm) or between, e.g., 1.2 eV (1033 nm) and 1.3 eV (954 nm).

As noted above, the absorber layer 502 and the junction partner layer 504 include different semiconductors with different band gaps and electron affinities such that junction partner layer 504 has a larger band gap than absorber layer 502. For example, the absorber may have a band gap between about 0.9 eV and about 1.8 eV. In some embodiments, the absorber layer in a semiconductor junction 410 includes copper-indium-gallium-diselenide (CIGS) and the band gap of the absorber layer is in the range of 1.04 eV to 1.67 eV. In some embodiments, the absorber layer in a semiconductor junction 410 includes copper-indium-gallium-diselenide (CIGS) and the minimum band gap of the absorber layer is between 1.1 eV and 1.2 eV.

In some embodiments the absorber layer in a semiconductor junction 410 is graded such that the band gap of the absorber layer varies as a function of absorber layer depth. As is known in the art, for the purposes of modeling, such a graded absorber layer can be modeled as stacked layers, each with a different composition and corresponding band gap. For instance, in some embodiments, the absorber layer in a semiconductor junction 410 includes copper-indium-gallium-diselenide having the stiochiometry CuIn₁₋ₓGaₓSe₂ with non-uniform Ga/In composition versus absorber layer depth. Such non-uniform Ga/In composition can be achieved, for example, by varying elemental fluxes of Ga and In during deposition of the absorber layer onto a nonplanar back-electrode. In some embodiments, the absorber layer in a semiconductor junction 410 includes copper-indium-gallium-diselenide with the stiochiometry CuIn₁₋ₓGaₓSe₂ in which the band gap ranges of the absorber varies between a first value in the range 1.04 eV to 1.67 eV and a second value in the range of 1.04 eV to 1.67 eV as a function of absorber depth, where the first value is greater than the second value. In some embodiments, the absorber layer in a semiconductor junction 410 includes copper-indium-gallium-diselenide having the stiochiometry CuIn₁₋ₓGaₓSe₂ in which the band gap of the absorber layer ranges between a first value in the range of 1.04 eV to 1.67 eV to a second value in the range of 1.04 eV to 1.67 eV as a function of absorber layer depth, where the first value is less than the second value. Typically, in such embodiments, the band gap ranges between the first value and the second value in a continuous linear gradient as a function of absorber layer depth. However, in some embodiments, the band gap ranges between the first value and the second value in a nonlinear gradient or even a discontinuous fashion as a function of absorber layer depth.

In some embodiments, the absorber layer or the junction partner layer in a semiconductor junction 410 is characterized by a band gap that ranges between a first value in the range 1.04 eV to 1.67 eV to a second value in the range of 1.04 eV to 1.67 eV as a function of absorber layer depth, where the first value is greater than the second value. In some embodiments, the absorber layer in a semiconductor junction 410 includes copper-indium-gallium-diselenide having the stiochiometry CuIn₁₋ₓGaₓSe₂ in which the band gap ranges between a first value in the range of 1.04 eV to 1.67 eV to a second value in the range of 1.04 eV to 1.67 eV as a function of absorber depth, where the first value is less than the second value. In some embodiments, the band gap ranges between the first value and the second value in a continuous linear gradient as a function of absorber depth. However, in some embodiments, the band gap ranges between the first value and the second value in a nonlinear gradient or even a discontinuous fashion as a function of absorber depth. Moreover, in some embodiments, the band gap ranges between the first value and the second value in such a manner that the band gap increases and decreases a plurality of times as a function of absorber layer depth.

In some embodiments, the absorber layer or the junction partner layer in a semiconductor junction 410 of the present application is characterized by a band gap that ranges between a first value in the range of 0.6 eV (2066 nm) to 2.4 eV (516 nm) and a second value in the range of 0.6 eV (2066 nm) to 2.4 eV (516 nm), where the first value is less than the second value. In some embodiments, the absorber layer or the junction partner layer in a semiconductor junction 410 of the present application is characterized by a band gap that ranges between a first value in the range of 0.7 eV (1771 nm) to 2.2 eV (563 nm) and a second value in the range of 0.7 eV (1771 nm) to 2.2 eV (563 nm), where the first value is less than the second value. In some embodiments, the absorber layer or the junction partner layer in a semiconductor junction 410 of the present application is characterized by a band gap that ranges between a first value in the range of 0.8 eV (1550 nm) to 2.0 eV (620 nm) and a second value in the range of 0.8 eV (1550 nm) to 2.0 eV (620 nm), where the first value is less than the second value. In some embodiments, the absorber layer or the junction partner layer in a semiconductor junction 410 of the present application is characterized by a band gap that ranges between a first value in the range of 0.9 eV (1378 nm) to 1.8 eV (689 nm) and a second value in the range of 0.9 eV (1378 nm) to 1.8 eV (689 nm), where the first value is less than the second value. In some embodiments, the absorber layer or the junction partner layer in a semiconductor junction 410 of the present application is characterized by a band gap that ranges between a first value in the range of 1 eV (1240 nm) to 1.6 eV (775 nm) and a second value in the range of 1 eV (1240 nm) to 1.6 eV (775 nm), where the first value is less than the second value. In some embodiments, the absorber layer or the junction partner layer in a semiconductor junction 410 of the present application is characterized by a band gap that ranges between a first value in the range of 1.1 eV (1127 nm) to 1.4 eV (886 nm) and a second value in the range of 1.1 eV (1127 nm) to 1.4 eV (886 nm), where the first value is less than the second value. In some embodiments, the absorber layer or the junction partner layer in a semiconductor junction 410 of the present application is characterized by a band gap that ranges between a first value in the range of 1.2 eV (1033 nm) to 1.3 eV (954 nm) and a second value in the range of 1.2 eV (1033 nm) to 1.3 eV (954 nm), where the first value is less than the second value. In some embodiments, the band gap ranges between the first value and the second value in a continuous linear gradient as a function of absorber layer or junction partner layer depth. However, in some embodiments, the band gap ranges between the first value and the second value in a nonlinear gradient or even a discontinuous fashion as a function of absorber layer depth or junction partner layer depth. Moreover, in some embodiments, the band gap ranges between the first value and the second value in such a manner that the band gap increases and decreases a plurality of times as a function of absorber layer or junction partner layer depth.

In some embodiments, the absorber layer or the junction partner layer in a semiconductor junction 410 of the present application is characterized by a band gap that ranges between a first value in the range of 0.6 eV (2066 nm) to 2.4 eV (516 nm) and a second value in the range of 0.6 eV (2066 nm) to 2.4 eV (516 nm), where the first value is greater than the second value. In some embodiments, the absorber layer or the junction partner layer in a semiconductor junction 410 of the present application is characterized by a band gap that ranges between a first value in the range of 0.7 eV (1771 nm) to 2.2 eV (563 nm) and a second value in the range of 0.7 eV (1771 nm) to 2.2 eV (563 nm), where the first value is greater than the second value. In some embodiments, the absorber layer or the junction partner layer in a semiconductor junction 410 of the present application is characterized by a band gap that ranges between a first value in the range of 0.8 eV (1550 nm) to 2.0 eV (620 nm) and a second value in the range of 0.8 eV (1550 nm) to 2.0 eV (620 nm), where the first value is greater than the second value. In some embodiments, the absorber layer or the junction partner layer in a semiconductor junction 410 of the present application is characterized by a band gap that ranges between a first value in the range of 0.9 eV (1378 nm) to 1.8 eV (689 nm) and a second value in the range of 0.9 eV (1378 nm) to 1.8 eV (689 nm), where the first value is greater than the second value. In some embodiments, the absorber layer or the junction partner layer in a semiconductor junction 410 of the present application is characterized by a band gap that ranges between a first value in the range of 1 eV (1240 nm) to 1.6 eV (775 nm) and a second value in the range of 1 eV (1240 nm) to 1.6 eV (775 nm), where the first value is greater than the second value. In some embodiments, the absorber layer or the junction partner layer in a semiconductor junction 410 of the present application is characterized by a band gap that ranges between a first value in the range of 1.1 eV (1127 nm) to 1.4 eV (886 nm) and a second value in the range of 1.1 eV (1127 nm) to 1.4 eV (886 nm), where the first value is greater than the second value. In some embodiments, the absorber layer or the junction partner layer in a semiconductor junction 410 of the present application is characterized by a band gap that ranges between a first value in the range of 1.2 eV (1033 nm) to 1.3 eV (954 nm) and a second value in the range of 1.2 eV (1033 nm) to 1.3 eV (954 nm), where the first value is greater than the second value. In some embodiments, the band gap ranges between the first value and the second value in a continuous linear gradient as a function of absorber layer or junction partner layer depth. However, in some embodiments, the band gap ranges between the first value and the second value in a nonlinear gradient or even a discontinuous fashion as a function of absorber layer or junction partner layer depth. Moreover, in some embodiments, the band gap ranges between the first value and the second value in such a manner that the band gap increases and decreases a plurality of times as a function of absorber layer or junction partner layer depth.

Table 1 lists exemplary band gaps of several semiconductors suitable for use in semiconductor junctions such as those described herein, as well as some other physical properties of the semiconductors. “D” indicates a direct band gap, and “I” indicates an indirect band gap.

TABLE 1
Properties of various semiconductors (adapted from Pandey, Handbook of Semiconductor
Electrodeposition, Marcel Dekker Inc., 1996, Appendix 5) that may be used
in semiconductor junctions 410 of the present application

| | | Band | | Electron | Hole | |
|---|---|---|---|---|---|---|
| Material | Density | gap | Gap | Mobility | Mobility | Dielectric |
| (type) | (g/cm³) | (eV) | transition | (cm²V¹s¹) | (cm²V¹s¹) | Constant |
| B | — | 1.53 | I | 6,000 | 4000 | — |
| Si (n, p) | 2.33 | 1.11 | I | 1,350 | 480 | 12 |
| Ge (n, p) | 5.33 | 0.66 | I | 3,600 | 1800 | 16 |
| SiC (n, p) | 3.22 | 2.75-3.1 | I | 60-120 | 10.2 | 4.84 |
| CdS (n, p) | 4.83 | 2.42 | D | 340 | — | 9-10.3 |
| CdSe (n) | 5.74 | 1.7 | D | 600 | — | 9.3-10 |
| CdTe (n, p) | 5.86 | 1.44 | D | 700 | 65 | 9.6 |
| ZnS (n) | 4.09 | 3.58 | D | 120 | — | 8.3 |
| ZnSe (n) | 5.26 | 2.67 | D | 530 | — | 9.1 |
| ZnTe (p) | 5.70 | 2.26 | D | 530 | 130 | 10.1 |
| HgSe | 7.1-8.9 | 0.6 | — | 18,500 | — | 5.8 |
| HgTe | | 0.025 | — | 22,000 | 160 | — |
| PbS | 7.5 | 0.37 | I | 600 | 200 | — |
| PbSe | 8.10 | 0.26 | I | 1,400 | 1400 | — |
| PbTe (n, p) | 8.16 | 0.29 | I | 6,000 | 4000 | — |
| Bi₂S₃ (n) | | 1.3 | I | 200 | — | — |
| Sb₂Se₃ | | 1.2 | — | 15 | 45 | — |
| Sb₂S₃ | | 1.7 | — | — | — | — |
| As₂Se₃ | | 1.6 | — | 15 | 45 | — |
| In₂S₃ | | 2.28 | — | — | — | — |
| In₂Se₃ | | 1.25 | — | 30 | — | — |
| Mg₂Si | | 0.77 | — | 370 | 65 | — |
| ZnAs₂ | | 0.9 | — | — | 50 | — |
| CdAs₂ | | 1.0 | — | — | 100 | — |
| AlAs (n, p) | 3.79 | 2.15 | I | — | 280 | 10.1 |
| AlSb (n, p) | 4.26 | 1.6 | I | 900 | 400 | 10.3 |
| GaAs (n, p) | 5.32 | 1.43 | D | 58,000 | 300 | 11.5 |
| GaSb (n, p) | 5.60 | 0.68 | D | 5,000 | 1000 | 14.8 |
| GaP (n, p) | 4.13 | 2.3 | D | 110 | 75 | 8.5 |
| InP (n, p) | 4.78 | 1.27 | D | 4,500 | 100 | 12.1 |
| InSb (n, p) | 5.77 | 0.17 | D | 80,000 | 450 | 15.07 |
| InAs (n, p) | 5.60 | 0.36 | D | 33,000 | 450 | 11.7 |
| MoS₂ (n, p) | 4.8 | 1.75 | I, D | — | 200 | — |
| MoSe₂ (n, p) | | 1.4 | I, D | 10-50 | — | — |
| MoTe₂ (n, p) | | 1.0 | I | — | — | — |
| WSe₂ (n, p) | | 1.57 | I | 100-150 | — | — |
| ZrSe₂ (p) | | 1.05-1.22 | I | — | — | — |
| CuInS₂ (n, p) | 4.75 | 1.3-1.5 | — | — | — | — |
| CuInSe₂ (n, p) | 5.77 | 0.9-1.11 | — | — | — | — |
| CuGaS₂ (p) | 4.35 | 2.1 | — | — | — | — |
| CuGaSe₂ (p) | 5.56 | 1.5 | — | — | — | — |
| CuInS_{0.5}Se_{1.5} (p) | | 1.5 | — | — | — | — |
| CuInSSe (p) | | 1.2 | — | — | — | — |
| CuInS_{1.5}S_{o.5} (n, p) | | 1.3 | — | — | — | — |
| CuGa_{0.5}In_{0.5}S₂ (p) | | 1.4 | — | — | — | — |
| CuGA_{0.5}In_{0.5}Se₂ (p) | | 1.1 | — | — | — | — |
| CuGa_{0.75}In_{0.25}Se₂ (p) | | 1.35 | — | — | — | — |
| CuGa_{0.25}In_{0.75}Se₂ | | 1.0 | — | — | — | — |
| CuGa_{0.5}In_{0.5}SSe (p) | | 1.2 | — | — | — | — |
| CuGa_{0.25}In_{0.75}S_{0.5}Se_{1..5} | | 1.0 | — | — | — | — |
| (p) | | | | | | |
| CuGa_{0.75}In_{0.25}SSe_{1.5} | | 1.1 | — | — | — | — |
| (p) | | | | | | |
| Cu₂CdSnSe₄ (p) | | 1.5 | — | — | — | — |
| CuInSnS₄ (p) | | 1.1 | — | — | — | — |
| CuInSnSe₄ (p) | | 0.9 | — | — | — | — |
| CuIn₅Se₈ (p) | | 1.3 | — | — | — | — |
| CuGa₃S₅ (p) | | 1.8 | — | — | — | — |
| CuGa₅Se₈ (p) | | 2.0 | — | — | — | — |
| CuGa₅Se₈ | | 1.2 | — | — | — | — |
| CuGa_{2.5}In_{2.5}S₄Se₈ | | 1.4 | — | — | — | — |

In some embodiments, the density of the semiconductor materials in the absorber layer and/or the junction partner of a semiconductor junction 410 ranges between about 2.33 g/cm³ and 8.9 g/cm³. In some embodiments, the absorber layer has a density of between about 5 g/cm³ and 6 g/cm³. In some embodiments the absorber layer includes CIGS. The density of CIGS changes with its composition because the unit crystal cell changes from cubic to tetragonal. The chemical formula for CIGS is: Cu(In₁₋ₓGaₓ)Se₂. At gallium mole fractions below 0.5, the CIGS takes on a tetragonal chalcopyrite structure. At mole fractions above 0.5, the cell structure is cubic zinc-blende. In some embodiments, the absorber layer of a semiconductor junction 410 includes CIGS in which the mole fraction (x) is between 0.2 and 0.6, a density of between 5 g/cm³ and 6 g/cm³ and a band gap between about 1.2 eV and 1.4 eV. In an embodiment, the absorber layer of a semiconductor junction 410 includes CIGS in which the mole fraction (x) is between 0.2 and 0.6, the density of the CIGS is between 5 g/cm³ and 6 g/cm³ and the band gap of the CIGS is between about 1.2 eV and 1.4 eV. In an embodiment, the absorber layer of a semiconductor junction 410 includes CIGS in which the mole fraction (x) is 0.4, the density of the CIGS is about 5.43 g/cm³, and the band gap of the CIGS is about 1.2 eV.

Current Densities. The combination of materials used in the semiconductor junction, e.g., absorber layer and junction partner layer, are selected to generate a sufficient current density (also commonly called the “short circuit current density,” or J_{sc}) upon irradiation with photons with energies at or above the band gap of the absorber layer, to efficiently produce electricity. In order to enhance J_{sc}, it is desirable to (1) absorb as much of the incident light as possible, e.g., to have a small band gap with high absorption over a wide energy range, and (2) to have material properties such that the photoexcited electrons and holes are able to be collected by the internal electric field generated by the junction and pass into an external circuit before they recombine, e.g., a material with a high minority carrier lifetime and mobility. At the same time, the band gap of the junction partner layer is usefully large relative to that of the absorber layer so that the bulk of the photon absorption occurs in the absorber layer. For example, in some embodiments, the compounds in the semiconductor junction 410 (e.g., the absorber layer and/or the junction partner layer) are selected such that the solar cell generates a current density J_{sc} of at least 10 mA/cm², at least 15 mA/cm², at least 20 mA/cm², at least 25 mA/cm², at least 30 mA/cm², at least 35 mA/cm², or at least 39 mA/cm² upon irradiation with an air mass (AM) 1.5 global spectrum, an AM1.5 direct terrestrial spectra, an AM0 reference spectra as defined in Section 16.2.1 of Handbook of Photovoltaic Science and Engineering, 2003, Luque and Hegedus (eds.), Wiley & Sons, West Sussex, England (2003), which is hereby incorporated by reference herein. The air-mass value 0 equates to insolation at sea level with the Sun at its zenith, as shown, AM 1.0 represents sunlight with the Sun at zenith above the Earth's atmosphere and absorbing oxygen and nitrogen gases, AM 1.5 is the same, but with the Sun at an oblique angle of 48.2°, which simulates a longer optical path through the Earth's atmosphere, and AM 2.0 extends that oblique angle to 60.1°. See Jeong, 2007, Laser Focus World 43, 71-74, which is hereby incorporated by reference herein.

In some embodiments, the solar cells of the present invention exhibit a J_{sc}, when measured under standard conditions (25° C., AM 1.5 G 100 mW/cm²), that is between 22 mA/cm² and 35 mA/cm². In some embodiments, the solar cells of the present invention exhibit a J_{sc}, when measured under AM 1.5 G, that is between 22 mA/cm² and 35 mA/cm² at any temperature between 0° C. and 70° C. In some embodiments, the solar cells exhibit a J_{sc}, when measured under AM 1.5 G conditions, that is between 22 mA/cm² and 35 mA/cm² at any temperature between 10° C. and 60° C. For computing current density, illumination intensities are calibrated, for example, by the standard amorphous Si solar cell in the manner used to report values in Nishitani et al., 1998, Solar Energy Materials and Solar Cells 50, p. 63-70 and the references cited therein, which is hereby incorporated by reference in its entirety.

In some embodiments, the materials of the absorber layer and/or the junction partner layer of the semiconductor junction 410 have electron mobilities between, e.g., 10 cm²V¹s¹ and 80,000 10 cm²V¹s¹.

In some embodiments, substantially all, or some of the photovoltaic current generated by the solar cells is from absorption of light by a semiconductor in the semiconductor junction 410. In some embodiments, the semiconductor junction is in a crystalline or polycrystalline state. In some embodiments, at least fifty percent, or at least sixty percent, or at least seventy percent, or at least eighty percent, or at least ninety percent, or at least ninety-five percent of the photovoltaic current generated by the solar cell is from absorption of light by a semiconductor in the semiconductor junction.

Open circuit voltage. In some embodiments, the solar cells of the present invention exhibit an open circuit voltage V_{oc} (V), when measured under standard conditions (25° C., AM 1.5 G 100 mW/cm²), that is between 0.4V and 0.8V. In some embodiments, the solar cells of the present invention exhibit a V_{oc}, when measured under AM 1.5 G, that is between 0.4V and 0.8V at any temperature between 0° C. and 70° C. In some embodiments, the solar cells of the present invention exhibit a V_{oc}, when measured under AM 1.5 G conditions, that is between 0.4V and 0.8V at any temperature between 10° C. and 60° C. For computing open circuit voltage, illumination intensities are calibrated, for example, by the standard amorphous Si solar cell in the manner used to report values in Nishitani et al., 1998, Solar Energy Materials and Solar Cells 50, p. 63-70 and the references cited therein, which is hereby incorporated by reference in its entirety.

### 5.2.1 Thin-Film Semiconductor Junctions Based on Copper Indium Diselenide and Other Type I-III-VI Materials

Continuing to refer to FIG. 5A, in some embodiments, the absorber layer 502 is a group I-III-VI₂ compound such as copper indium di-selenide (CuInSe₂; also known as CIS). In some embodiments, the absorber layer 502 is a group I-III-VI₂ ternary compound selected from the group consisting of CdGeAs₂, ZnSnAs₂, CuInTe₂, AgInTe₂, CuInSe₂, CuGaTe₂, ZnGeAs₂, CdSnP₂, AgInSe₂, AgGaTe₂, CuInS₂, CdSiAs₂, ZnSnP₂, CdGeP₂, ZnSnAs₂, CuGaSe₂, AgGaSe₂, AgInS₂, ZnGeP₂, ZnSiAs₂, ZnSiP₂, CdSiP₂, or CuGaS₂ of either the p-type or the n-type when such compound is known to exist.

In some embodiments, the junction partner layer 504 is CdS, ZnS, ZnSe, or CdZnS. In one embodiment, the absorber layer 502 is p-type CIS and the junction partner layer 504 is n⁻type CdS, ZnS, ZnSe, or CdZnS. Such semiconductor junctions 410 are described in Chapter 6 of Bube, Photovoltaic Materials, 1998, Imperial College Press, London, which is hereby incorporated by reference herein in its entirety.

In some embodiments, the absorber layer 502 is copper-indium-gallium-diselenide (CIGS). Such a layer is also known as Cu(InGa)Se₂. In some embodiments, the absorber layer 502 is copper-indium-gallium-diselenide (CIGS) and the junction partner layer 504 is CdS, ZnS, ZnSe, or CdZnS. In some embodiments, the absorber layer 502 is p-type CIGS and the junction partner layer 504 is n-type CdS, ZnS, ZnSe, or CdZnS. Such semiconductor junctions 410 are described in Chapter 13 of Handbook of Photovoltaic Science and Engineering, 2003, Luque and Hegedus (eds.), Wiley & Sons, West Sussex, England, Chapter 12, which is hereby incorporated by reference herein in its entirety. In some embodiments, CIGS is deposited using techniques disclosed in Beck and Britt, Final Technical Report, January 2006, NREL/SR-520-39119; and Delahoy and Chen, August 2005, “Advanced CIGS Photovoltaic Technology,” subcontract report; Kapur et al., January 2005 subcontract report, NREL/SR-520-37284, “Lab to Large Scale Transition for Non-Vacuum Thin Film CIGS Solar Cells”; Simpson et al., October 2005 subcontract report, “Trajectory-Oriented and Fault-Tolerant-Based Intelligent Process Control for Flexible CIGS PV Module Manufacturing,” NREL/SR-520-38681; and Ramanathan et al., 31^{st} IEEE Photovoltaics Specialists Conference and Exhibition, Lake Buena Vista, Fla., Jan. 3-7, 2005, each of which is hereby incorporated by reference herein in its entirety.

In some embodiments the CIGS the absorber layer 502 is grown on a molybdenum the back-electrode 404 by evaporation from elemental sources in accordance with a three stage process described in Ramanthan et al., 2003, “Properties of 19.2% Efficiency ZnO/CdS/CuInGaSe₂ Thin-film Solar Cells,” Progress in Photovoltaics: Research and Applications 11, 225, which is hereby incorporated by reference herein in its entirety. In some embodiments the layer 504 is a ZnS(O,OH) buffer layer as described, for example, in Ramanathan et al., Conference Paper, “CIGS Thin-Film Solar Research at NREL: FY04 Results and Accomplishments,” NREL/CP-520-37020, January 2005, which is hereby incorporated by reference herein in its entirety.

In some embodiments, the layer 502 is between 0.5 μm and 2.0 μm thick. In some embodiments, the composition ratio of Cu/(In+Ga) in layer 502 is between 0.7 and 0.95. In some embodiments, the composition ratio of Ga/(In+Ga) in the layer 502 is between 0.2 and 0.4. In some embodiments the CIGS absorber has a <110> crystallographic orientation. In some embodiments the CIGS absorber has a <112> crystallographic orientation. In some embodiments the CIGS absorber is randomly oriented.

### 5.2.2 Semiconductor Junctions Based on Amorphous Silicon or Polycrystalline Silicon

In some embodiments, referring to FIG. 5B, the semiconductor junction 410 comprises amorphous silicon. In some embodiments this is an n/n type heterojunction. For example, in some embodiments, layer 514 comprises SnO₂(Sb), layer 512 comprises undoped amorphous silicon, and layer 510 comprises n+ doped amorphous silicon.

In some embodiments, the semiconductor junction 410 is a p-i-n type junction. For example, in some embodiments, layer 514 is p⁺ doped amorphous silicon, layer 512 is undoped amorphous silicon, and layer 510 is n⁺ amorphous silicon. Such semiconductor junctions 410 are described in Chapter 3 of Bube, Photovoltaic Materials, 1998, Imperial College Press, London, which is hereby incorporated by reference herein in its entirety.

In some embodiments of the present application, the semiconductor junction 410 is based upon thin-film polycrystalline. Referring to FIG. 5B, in one example in accordance with such embodiments, layer 510 is a p-doped polycrystalline silicon, layer 512 is depleted polycrystalline silicon and layer 514 is n-doped polycrystalline silicon. Such semiconductor junctions are described in Green, Silicon Solar Cells: Advanced Principles & Practice, Centre for Photovoltaic Devices and Systems, University of New South Wales, Sydney, 1995; and Bube, Photovoltaic Materials, 1998, Imperial College Press, London, pp. 57-66, which is hereby incorporated by reference herein in its entirety.

In some embodiments of the present application, the semiconductor junctions 410 based upon p-type microcrystalline Si:H and microcrystalline Si:C:H in an amorphous Si:H solar cell are used. Such semiconductor junctions are described in Bube, Photovoltaic Materials, 1998, Imperial College Press, London, pp. 66-67, and the references cited therein, which is hereby incorporated by reference herein in its entirety.

In some embodiments, of the present application, the semiconductor junction 410 is a tandem junction. Tandem junctions are described in, for example, Kim et al., 1989, “Lightweight (AlGaAs)GaAs/CuInSe2 tandem junction solar cells for space applications,” Aerospace and Electronic Systems Magazine, IEEE Volume 4, Issue 11, November 1989 Page(s):23-32; Deng, 2005, “Optimization of a-SiGe based triple, tandem and single-junction solar cells Photovoltaic Specialists Conference, 2005 Conference Record of the Thirty-first IEEE 3-7 Jan. 2005 Page(s): 1365-1370; Arya et al., 2000, Amorphous silicon based tandem junction thin-film technology: a manufacturing perspective,” Photovoltaic Specialists Conference, 2000. Conference Record of the Twenty-Eighth IEEE 15-22 Sep. 2000 Page(s):1433-1436; Hart, 1988, “High altitude current-voltage measurement of GaAs/Ge solar cells,” Photovoltaic Specialists Conference, 1988, Conference Record of the Twentieth IEEE 26-30 Sep. 1988 Page(s):764-765 vol. 1; Kim, 1988, “High efficiency GaAs/CuInSe2 tandem junction solar cells,” Photovoltaic Specialists Conference, 1988, Conference Record of the Twentieth IEEE 26-30 Sep. 1988 Page(s):457-461 vol. 1; Mitchell, 1988, “Single and tandem junction CuInSe2 cell and module technology,” Photovoltaic Specialists Conference, 1988, Conference Record of the Twentieth IEEE 26-30 Sep. 1988 Page(s):1384-1389 vol. 2; and Kim, 1989, “High specific power (AlGaAs)GaAs/CuInSe2 tandem junction solar cells for space applications,” Energy Conversion Engineering Conference, 1989, IECEC-89, Proceedings of the 24^{th} Intersociety 6-11 Aug. 1989 Page(s):779-784 vol. 2, each of which is hereby incorporated by reference herein in its entirety.

### 5.2.3 Semiconductor Junctions Based on Gallium Arsenide and Other Type III-V Materials

In some embodiments, the semiconductor junctions 410 are based upon gallium arsenide (GaAs) or other III-V materials such as InP, AlSb, and CdTe. GaAs is a direct-band gap material having a band gap of 1.43 eV and can absorb 97% of AM1 radiation in a thickness of about two microns. Suitable type III-V junctions that can serve as semiconductor junctions 410 of the present application are described in Chapter 4 of Bube, Photovoltaic Materials, 1998, Imperial College Press, London, which is hereby incorporated by reference in its entirety.

Furthermore, in some embodiments the semiconductor junction 410 is a hybrid multijunction solar cell such as a GaAs/Si mechanically stacked multijunction as described by Gee and Virshup, 1988, 20^{th} IEEE Photovoltaic Specialist Conference, IEEE Publishing, New York, p. 754, which is hereby incorporated by reference herein in its entirety, a GaAs/CuInSe₂ MSMJ four-terminal device, consisting of a GaAs thin film top cell and a ZnCdS/CuInSe₂ thin bottom cell described by Stanbery et al., 19^{th} IEEE Photovoltaic Specialist Conference, IEEE Publishing, New York, p. 280, and Kim et al., 20^{th} IEEE Photovoltaic Specialist Conference, IEEE Publishing, New York, p. 1487, each of which is hereby incorporated by reference herein in its entirety. Other hybrid multijunction solar cells are described in Bube, Photovoltaic Materials, 1998, Imperial College Press, London, pp. 131-132, which is hereby incorporated by reference herein in its entirety.

### 5.2.4 Semiconductor Junctions Based on Cadmium Telluride and Other Type II-VI Materials

In some embodiments, the semiconductor junctions 410 are based upon II-VI compounds that can be prepared in either the n-type or the p-type form. Accordingly, in some embodiments, referring to FIG. 5C, the semiconductor junction 410 is a p-n heterojunction in which the layers 520 and 540 are any combination set forth in the following table or alloys thereof.

| Layer 520 | Layer 540 |
|---|---|
| n-CdSe | p-CdTe |
| n-ZnCdS | p-CdTe |
| n-ZnSSe | p-CdTe |
| p-ZnTe | n-CdSe |
| n-CdS | p-CdTe |
| n-CdS | p-ZnTe |
| p-ZnTe | n-CdTe |
| n-ZnSe | p-CdTe |
| n-ZnSe | p-ZnTe |
| n-ZnS | p-CdTe |
| n-ZnS | p-ZnTe |

Methods for manufacturing the semiconductor junctions 410 that are based upon II-VI compounds are described in Chapter 4 of Bube, Photovoltaic Materials, 1998, Imperial College Press, London, which is hereby incorporated by reference in its entirety.

### 5.2.5 Semiconductor Junctions Based on Crystalline Silicon

While semiconductor junctions 410 that are made from thin film semiconductor films are preferred, the application is not so limited. In some embodiments the semiconductor junctions 410 are based upon crystalline silicon. For example, referring to FIG. 5D, in some embodiments, the semiconductor junction 410 comprises a layer of p-type crystalline silicon 540 and a layer of n-type crystalline silicon 550. Methods for manufacturing crystalline silicon semiconductor junctions 410 are described in Chapter 2 of Bube, Photovoltaic Materials, 1998, Imperial College Press, London, which is hereby incorporated by reference herein in its entirety.

### 5.3 Albedo Embodiments

In some embodiments of the present application, assemblies 402 (e.g., 800 of FIG. 8, 900 of FIG. 9, 1000 of FIG. 10 etc.) are arranged in a reflective environment in which surfaces around the photovoltaic modules 402 of the assemblies have some amount of albedo. Albedo is a measure of reflectivity of a surface or body. It is the ratio of electromagnetic radiation (EM radiation) reflected to the amount incident upon it. This fraction is usually expressed as a percentage from 0% to 100%. In some embodiments, surfaces in the vicinity of the assemblies of the present application are prepared so that they have a high albedo by painting such surfaces a reflective white color. In some embodiments, other materials that have a high albedo can be used. For example, the albedo of some materials around such photovoltaic modules approach or exceed ninety percent. See, for example, Boer, 1977, Solar Energy 19, 525, which is hereby incorporated by reference herein in its entirety. However, surfaces having any amount of albedo (e.g., five percent or more, ten percent or more, twenty percent or more) are within the scope of the present application. In one embodiment, the photovoltaic modules of the present application are arranged in rows above a gravel surface, where the gravel has been painted white in order to improve the reflective properties of the gravel. In general, any Lambertian or diffuse reflector surface can be used to provide a high albedo surface.

### 5.4 Exemplary Substrates

In some embodiments, the elongated substrate 403 is made of a material such as polybenzamidazole (e.g., CELAZOLE®, available from Boedeker Plastics, Inc., Shiner, Tex.). In some embodiments, the inner core is made of polyimide (e.g., DUPONT™ VESPEL®, or DUPONT™ KAPTON®, Wilmington, Del.). In some embodiments, the inner core is made of polytetrafluoroethylene (PTFE) or polyetheretherketone (PEEK), each of which is available from Boedeker Plastics, Inc. In some embodiments, the elongated substrate 403 is made of polyamide-imide (e.g., TORLON® PAI, Solvay Advanced Polymers, Alpharetta, Ga.).

In some embodiments, the elongated substrate 403 is made of a glass-based phenolic. Phenolic laminates are made by applying heat and pressure to layers of paper, canvas, linen or glass cloth impregnated with synthetic thermosetting resins. When heat and pressure are applied to the layers, a chemical reaction (polymerization) transforms the separate layers into a single laminated material with a “set” shape that cannot be softened again. Therefore, these materials are called “thermosets.” A variety of resin types and cloth materials can be used to manufacture thermoset laminates with a range of mechanical, thermal, and electrical properties. In some embodiments, the elongated substrate 403 is a phenoloic laminate having a NEMA grade of G-3, G-5, G-7, G-9, G-10 or G-11. Exemplary phenolic laminates are available from Boedeker Plastics, Inc.

In some embodiments, the elongated substrate 403 is made of polystyrene. Examples of polystyrene include general purpose polystyrene and high impact polystyrene as detailed in Marks' Standard Handbook for Mechanical Engineers, ninth edition, 1987, McGraw-Hill, Inc., p. 6-174, which is hereby incorporated by reference herein in its entirety. In still other embodiments, the elongated substrate 403 is made of cross-linked polystyrene. One example of cross-linked polystyrene is REXOLITE® (C-Lec Plastics, Inc). REXOLITE is a thermoset, in particular a rigid and translucent plastic produced by cross linking polystyrene with divinylbenzene.

In still other embodiments, the elongated substrate 403 is made of polycarbonate. Such polycarbonates can have varying amounts of glass fibers (e.g., 10%, 20%, 30%, or 40%) in order to adjust tensile strength, stiffness, compressive strength, as well as the thermal expansion coefficient of the material. Exemplary polycarbonates are ZELUX® M and ZELUX® W, which are available from Boedeker Plastics, Inc.

In some embodiments, the elongated substrate 403 is made of polyethylene. In some embodiments, the elongated substrate 403 is made of low density polyethylene (LDPE), high density polyethylene (HDPE), or ultra high molecular weight polyethylene (UHMW PE). Chemical properties of HDPE are described in Marks' Standard Handbook for Mechanical Engineers, ninth edition, 1987, McGraw-Hill, Inc., p. 6-173, which is hereby incorporated by reference herein in its entirety. In some embodiments, the elongated substrate 403 is made of acrylonitrile-butadiene-styrene, polytetrfluoro-ethylene (TEFLON), polymethacrylate (lucite or plexiglass), nylon 6,6, cellulose acetate butyrate, cellulose acetate, rigid vinyl, plasticized vinyl, or polypropylene. Chemical properties of these materials are described in Marks' Standard Handbook for Mechanical Engineers, ninth edition, 1987, McGraw-Hill, Inc., pp. 6-172 through 6-175, which is hereby incorporated by reference herein in its entirety.

Additional exemplary materials that can be used to form the elongated substrate 403 are found in Modern Plastics Encyclopedia, McGraw-Hill; Reinhold Plastics Applications Series, Reinhold Roff, Fibres, Plastics and Rubbers, Butterworth; Lee and Neville, Epoxy Resins, McGraw-Hill; Bilmetyer, Textbook of Polymer Science, Interscience; Schmidt and Marlies, Principles of high polymer theory and practice, McGraw-Hill; Beadle (ed.), Plastics, Morgan-Grampiand, Ltd., 2 vols. 1970; Tobolsky and Mark (eds.), Polymer Science and Materials, Wiley, 1971; Glanville, The Plastics's Engineer's Data Book, Industrial Press, 1971; Mohr (editor and senior author), Oleesky, Shook, and Meyers, SPI Handbook of Technology and Engineering of Reinforced Plastics Composites, Van Nostrand Reinhold, 1973, each of which is hereby incorporated by reference herein in its entirety.

In general, back-electrode 404 is made out of any material that can support the photovoltaic current generated by a solar cell 12 of the photovoltaic module 402 with negligible resistive losses. In some embodiments, the back-electrode 404 is made of any conductive metal, such as aluminum, molybdenum, steel, nickel, silver, gold, or an alloy thereof. In some embodiments, the back-electrode 404 is made out of a metal-, graphite-, carbon black-, or superconductive carbon black-filled oxide, epoxy, glass, or plastic. In some embodiments, the back-electrode 404 is made of a conductive plastic. In some embodiments, this conductive plastic is inherently conductive without any requirement for a filler. In some embodiments, the elongated substrate 403 is made out of a conductive material and the back-electrode 404 is made out of molybdenum. In some embodiments, the elongated substrate 403 is made out of a nonconductive material, such as a glass rod, and the back-electrode 404 is made out of molybdenum.

### 5.5 Exemplary Dimensions

The present application encompasses assemblies of photovoltaic modules 402 having any dimensions that fall within a broad range of dimensions. For example, referring to FIG. 4B, the present application encompasses assemblies having a length l between 1 cm and 50,000 cm and a width w between 1 cm and 50,000 cm. In some embodiments, the assemblies have a length l between 10 cm and 1,000 cm and a width w between 10 cm and 1,000 cm. In some embodiments, the assemblies have a length l between 40 cm and 500 cm and a width w between 40 cm and 500 cm.

As illustrated in FIGS. 3A and 3B, a photovoltaic module 402 has a length l that is great compared to a width of its cross-section. In some embodiments, a photovoltaic module 402 has a length l between 10 mm and 100,000 mm and a width w between 3 mm and 10,000 mm. In some embodiments, a photovoltaic module 402 has a length l between 10 mm and 5,000 mm and a width w between 10 mm and 1,000 mm. In some embodiments, a photovoltaic module 402 has a length l between 40 mm and 15000 mm and a width w between 10 mm and 50 mm.

In some embodiments, a photovoltaic module 402 may be elongated as illustrated in FIG. 3A. As illustrated in FIGS. 3A and 3B, a photovoltaic module 402 is one that is characterized by having a longitudinal dimension l and a width dimension w. In some embodiments of a photovoltaic module 402, the longitudinal dimension l exceeds the width dimension w by at least a factor of 4, at least a factor of 5, or at least a factor of 6. In some embodiments, the longitudinal dimension l of the photovoltaic module 402 is 10 centimeters or greater, 20 centimeters or greater, or 100 centimeters or greater. In some embodiments, the width w (e.g., diameter in instances where the photovoltaic module 402 is cylindrical) of the photovoltaic module 402 is 5 millimeters or more, 10 millimeters or more, 50 millimeters or more, 100 millimeters or more, 500 millimeters or more, 1000 millimeters or more, or 2000 millimeters or more.

### 5.6 Additional Embodiments

Using FIG. 3B for reference to element numbers, in some embodiments, copper-indium-gallium-diselenide (Cu(InGa)Se₂), referred to herein as CIGS, is used to make the absorber layer of junction 410. In such embodiments, the back-electrode 404 is made of molybdenum. In some embodiments, the elongated substrate 403 is polyimide and the back-electrode 404 is a thin film of molybdenum sputtered onto the polyimide elongated substrate 403 prior to CIGS deposition. On top of the molybdenum, the CIGS film, which absorbs the light, is evaporated. Cadmium sulfide (CdS) is then deposited on the CIGS in order to complete semiconductor junction 410. Optionally, a thin intrinsic layer (i-layer) 415 is then deposited on the semiconductor junction 410. The i-layer 415 can be formed using a material including but not limited to, zinc oxide, metal oxide or any transparent material that is highly insulating. Next, the transparent conductive layer 412 is disposed on either the i-layer (when present) or the semiconductor junction 410 (when the i-layer is not present). The transparent conductive layer 412 can be made of a material such as aluminum doped zinc oxide (ZnO:Al), gallium doped zinc oxide, boron dope zinc oxide, indium-zinc oxide, or indium-tin oxide.

ITN Energy Systems, Inc., Global Solar Energy, Inc., and the Institute of Energy Conversion (IEC), have collaboratively developed technology for manufacturing CIGS photovoltaics on polyimide substrates using a roll-to-roll co-evaporation process for deposition of the CIGS layer. In this process, a roll of molybdenum-coated polyimide film, referred to as the web, is unrolled and moved continuously into and through one or more deposition zones. In the deposition zones, the web is heated to temperatures of up to ˜450° C. and copper, indium, and gallium are evaporated onto it in the presence of selenium vapor. After passing out of the deposition zone(s), the web cools and is wound onto a take-up spool. See, for example, 2003, Jensen et al., “Back Contact Cracking During Fabrication of CIGS Solar Cells on Polyimide Substrates,” NCPV and Solar Program Review Meeting 2003, NREL/CD-520-33586, pages 877-881, which is hereby incorporated by reference herein in its entirety. Likewise, Birkmire et al., 2005, Progress in Photovoltaics: Research and Applications 13, 141-148, hereby incorporated by reference herein, disclose a polyimide/Mo web structure, specifically, PI/Mo/Cu(InGa)Se₂/CdS/ZnO/ITO/Ni-Al. Deposition of similar structures on stainless foil has also been explored. See, for example, Simpson et al., 2004, “Manufacturing Process Advancements for Flexible CIGS PV on Stainless Foil,” DOE Solar Energy Technologies Program Review Meeting, PV Manufacturing Research and Development, P032, which is hereby incorporated by reference herein in its entirety.

In some embodiments of the present application, an absorber material is deposited onto a polyimide/molybdenum web, such as those developed by Global Solar Energy (Tucson, Ariz.), or a metal foil (e.g., the foil disclosed in Simpson et al.). In some embodiments, the absorber material is any of the absorbers disclosed herein. In a particular embodiment, the absorber is Cu(InGa)Se₂. In some embodiments, the elongated substrate 403 is made of a nonconductive material such as undoped plastic. In some embodiments, the elongated substrate 403 is made of a conductive material such as a conductive metal, a metal-filled epoxy, glass, or resin, or a conductive plastic (e.g., a plastic containing a conducting filler). Next, the semiconductor junction 410 is completed by depositing a window layer onto the absorber layer. In the case where the absorber layer is Cu(InGa)Se₂, CdS can be used. Finally, the optional i-layer 415 and the transparent conductive layer 412 are added to complete the solar cell. Next, the foil is wrapped around and/or glued to an elongated substrate 403. The advantage of such a fabrication method is that material that cannot withstand the deposition temperature of the absorber layer, window layer, i-layer or transparent conductive layer 412 can be used as an elongated substrate 403 for the photovoltaic module 402. This manufacturing process can be used to manufacture any of the photovoltaic modules 402 disclosed in the present application. The elongated substrate 403 is any conductive or nonconductive material disclosed herein whereas the back-electrode 404 is the web or foil onto which the absorber layer, window layer, and transparent conductive layer were deposited prior to rolling the foil onto the inner core. In some embodiments, the web or foil is glued onto the elongated substrate 403 using appropriate glue.

An aspect of the present application provides a method of manufacturing a photovoltaic module 402 comprising depositing an absorber layer on a first face of a metallic web or a conducting foil. Next, a window layer is deposited onto the absorber layer. Next, a transparent conductive layer is deposited onto the window layer. The metallic web or conducting foil is then rolled around an elongated substrate 403, thereby forming a photovoltaic module 402. In some embodiments, the absorber layer is copper-indium-gallium-diselenide (Cu(InGa)Se₂) and the window layer is cadmium sulfide. In some embodiments, the metallic web is a polyimide/molybdenum web. In some embodiments, the conducting foil is steel foil or aluminum foil. In some embodiments, the elongated core is made of a conductive metal, a metal-filled epoxy, a metal-filled glass, a metal-filled resin, or a conductive plastic.

In some embodiments, a transparent conducting oxide conductive film is deposited on a tubular shaped or rigid solid rod shaped elongated substrate 403 rather than wrapping a metal web or foil around the elongated substrate 403. In such embodiments, the tubular shaped or rigid solid rod shaped elongated substrate 403 can be, for example, a plastic rod, a glass rod, a glass tube, or a plastic tube. Such embodiments require some form of conductor in electrical communication with the interior face or back contact of the semiconductor junction. In some embodiments, divots in the tubular shaped or rigid solid rod shaped elongated substrate 403 are filled with a conductive metal in order to provide such a back-electrode 404. The conductor can be inserted in the divots prior to depositing the transparent conductive layer or conductive back contact film onto the tubular shaped or rigid solid rod shaped elongated core. In some embodiments such a conductor is formed from a metal source that optionally runs lengthwise along the side of the photovoltaic module 402. This metal can be deposited by evaporation, sputtering, screen printing, inkjet printing, metal pressing, conductive ink or glue used to attach a metal wire, or other means of metal deposition.

More specific embodiments will now be disclosed. In some embodiments, the elongated substrate 403 is a glass tubing having a divot that runs lengthwise on the outer surface of the glass tubing, and the manufacturing method comprises depositing a conductor in the divot prior to the rolling step. In some embodiments, the glass tubing has a second divot that runs lengthwise on the surface of the glass tubing. In such embodiments, the first divot and the second divot are on approximate or exact opposite circumferential sides of the glass tubing. In such embodiments, accordingly, the method further comprises depositing a conductor in the second divot prior to the rolling or, in embodiments in which rolling is not used, prior to the deposition of an inner transparent conductive layer or conductive film, junction, and outer transparent conductive layer onto the elongated core.

In some embodiments, the elongated substrate 403 is a glass rod having a first divot that runs lengthwise on the surface of the glass rod and the method comprises depositing a conductor in the first divot prior to the rolling. In some embodiments, the glass rod has a second divot that runs lengthwise on the surface of the glass rod and the first divot and the second divot are on approximate or exact opposite circumferential sides of the glass rod. In such embodiments, accordingly, the method further comprises depositing a conductor in the second divot prior to the rolling or, in embodiments in which rolling is not used, prior to the deposition of an inner transparent conductive layer or conductive film, junction, and outer transparent conductive layer onto the elongated core. Suitable materials for the conductor are any of the materials described as a conductor herein including, but not limited to, aluminum, molybdenum, titanium, steel, nickel, silver, gold, or an alloy thereof.

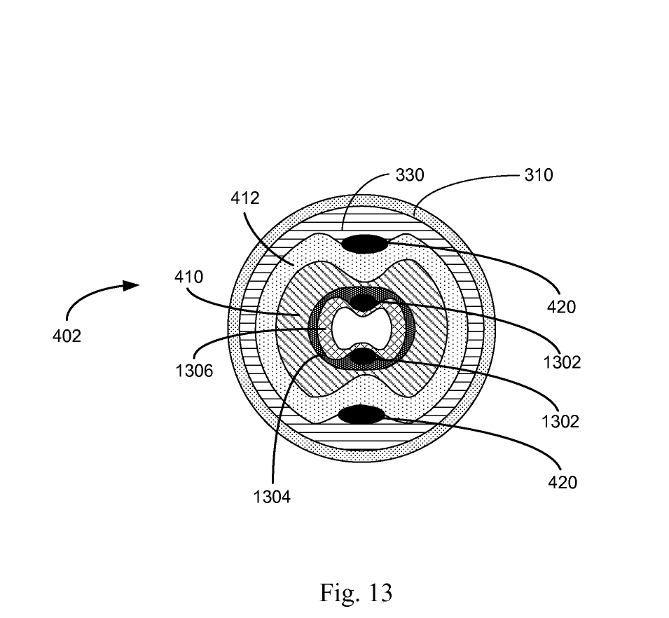

FIG. 13 details a cross-section of a photovoltaic module 402 in accordance with an embodiment of the present application. The photovoltaic module 402 can be manufactured using either the rolling method or deposition techniques. Components that have reference numerals corresponding to other embodiments of the present application (e.g., 410, 412, and 420) are made of the same materials disclosed in such embodiments. In FIG. 13, there is an elongated tubing 1306 having a first and second divot running lengthwise along the tubing (perpendicular to the plane of the page) that are on circumferentially opposing sides of tubing 1306 as illustrated. In typical embodiments, the tubing 1306 is not conductive. For example, the tubing 1306 is made of plastic or glass in some embodiments. The conductive wiring 1302 is placed in the first and second divot as illustrated in FIG. 13. In some embodiments, the conductive wiring is made of any of the conductive materials of the present application. In some embodiments, the conductive wiring 1302 is made out of aluminum, molybdenum, steel, nickel, titanium, silver, gold, or an alloy thereof. In embodiments where element 1304 is a conducting foil or metallic web, the conductive wiring 1302 is inserted into the divots prior to wrapping the metallic web or conducting foil 1304 around the elongated core 1306. In embodiments where element 1304 is a transparent conductive oxide or conductive film, the conductive wiring 1302 is inserted into the divots prior to depositing the transparent conductive oxide or conductive film 1304 onto the elongated core 1306. As noted, in some embodiments the metallic web or conducting foil 1304 is wrapped around the tubing 1306. In some embodiments, metallic web or the conducting foil 1304 is glued to the tubing 1306. In some embodiments, the layer 1304 is not a metallic web or conducting foil. For instance, in some embodiments, the layer 1304 is a transparent conductive layer. Such a layer is advantageous because it allows for thinner absorption layers in the semiconductor junction. In embodiments where the layer 1304 is a transparent conductive layer, the transparent conductive layer, the semiconductor junction 410 and the outer transparent conductive layer 412 are deposited using deposition techniques.

One aspect of the application provides an assembly comprising a plurality of photovoltaic modules 402 each having the structure disclosed in FIG. 13. That is, each photovoltaic module 402 in the plurality of photovoltaic modules comprises an elongated tubing 1306, a metallic web or a conducting foil (or, alternatively, a layer of TCO) 1304 circumferentially disposed on the elongated tubing 1306, a semiconductor junction 410 circumferentially disposed on the metallic web or the conducting foil (or, alternatively, a layer of TCO) 1304 and a transparent conductive layer 412 disposed on the semiconductor junction 410. The photovoltaic modules 402 in the plurality of photovoltaic modules are geometrically arranged in a parallel or a near parallel manner thereby forming a planar array having a first face and a second face. The plurality of photovoltaic modules are arranged such that one or more photovoltaic modules in the plurality of photovoltaic modules are not in electrically conductive contact with adjacent photovoltaic modules. In some embodiments, the photovoltaic modules can be in physical contact with each other if there is an insulative layer between adjacent photovoltaic modules. The assembly further comprises a plurality of metal counter-electrodes. Each respective photovoltaic module 402 in the plurality of photovoltaic modules is bound to a first corresponding metal counter-electrode 420 in the plurality of metal counter-electrodes such that the first metal counter-electrode lies in a first groove that runs lengthwise on the respective photovoltaic module 402. The apparatus further comprises a transparent electrically insulating substrate that covers all or a portion of the face of the planar array. A first and second photovoltaic module in the plurality of photovoltaic modules are electrically connected in series by an electrical contact that connects the first electrode of the first photovoltaic module to the first corresponding counter-electrode of the second photovoltaic module. In some embodiments, the elongated tubing 1306 is glass tubing or plastic tubing having a one or more grooves filled with a conductor 1302. In some embodiments, each respective photovoltaic module 402 in the plurality of photovoltaic modules is bound to a second corresponding metal counter-electrode 420 in the plurality of metal counter-electrodes such that the second metal counter-electrode lies in a second groove that runs lengthwise on the respective photovoltaic module 402 and such that the first groove and the second groove are on opposite or substantially opposite circumferential sides of the respective photovoltaic module 402. In some embodiments, the plurality of photovoltaic modules 402 is configured to receive direct light from the first face and the second face of the planar array.

### 5.7 Static Concentrators

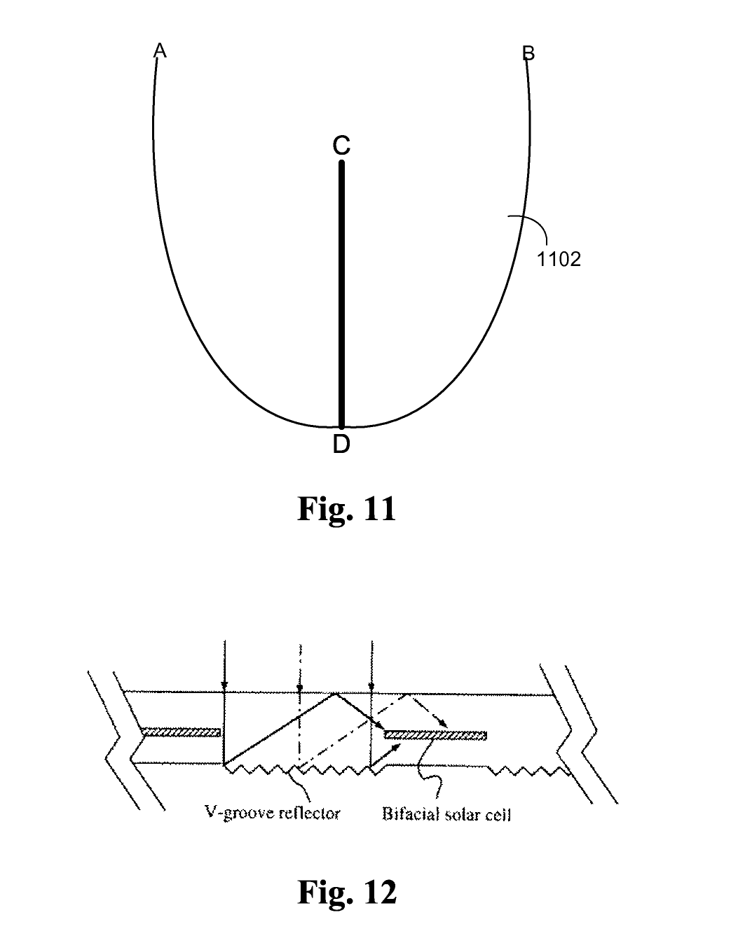

In some embodiments photovoltaic modules 402 may be assembled into bifacial, multi-facial, or omnifacial arrays as, for example, any of assemblies 400 (FIG. 4), 800 (FIG. 8), 900 (FIG. 9), or 1000 (FIG. 10). In some embodiments, static concentrators are used to improve the performance of the assemblies of the present application. The use of a static concentrator in one exemplary embodiment is illustrated in FIG. 11, where the static concentrator 1102, with aperture AB, is used to increase the efficiency of bifacial solar cell assembly CD, where solar cell assembly CD is, for example, any of assemblies 400 (FIG. 4), 800 (FIG. 8), 900 (FIG. 9), or 1000 (FIG. 10) or other assemblies of photovoltaic modules 402 of the present application. The static concentrator 1102 can be formed from any static concentrator materials known in the art such as, for example, a simple, properly bent or molded aluminum sheet, or reflector film on polyurethane. The concentrator 1102 depicted in FIG. 11 is an example of a low concentration ratio, nonimaging, compound parabolic concentrator (CPC)-type collector. Any (CPC)-type collector can be used with the solar cell assemblies of the present application. For more information on (CPC)-type collectors, see Pereira and Gordon, 1989, Journal of Solar Energy Engineering, 111, pp. 111-116, which is hereby incorporated by reference herein in its entirety.

Additional static concentrators that can be used with the present application are disclosed in Uematsu et al., 1999, Proceedings of the 11^{th} International Photovoltaic Science and Engineering Conference, Sapporo, Japan, pp. 957-958; Uematsu et al., 1998, Proceedings of the Second World Conference on Photovoltaic Solar Energy Conversion, Vienna, Austria, pp. 1570-1573; Warabisako et al., 1998, Proceedings of the Second World Conference on Photovoltaic Solar Energy Conversion, Vienna, Austria, pp. 1226-1231; Eames et al., 1998, Proceedings of the Second World Conference on Photovoltaic Solar Energy Conversion, Vienna Austria, pp. 2206-2209; Bowden et al., 1993, Proceedings of the 23^{rd} IEEE Photovoltaic Specialists Conference, pp. 1068-1072; and Parada et al., 1991, Proceedings of the 10^{th} EC Photovoltaic Solar Energy Conference, pp. 975-978, each of which is hereby incorporated by reference herein in its entirety.

In some embodiments, a static concentrator as illustrated in FIG. 12 is used. The bifacial solar cells illustrated in FIG. 12 can be any bifacial solar cell assembly of the present application including, but not limited to, assembly 400 (FIG. 4), 800 (FIG. 8), 900 (FIG. 9), or 1000 (FIG. 10). The static concentrator illustrated in FIG. 12 uses two sheets of cover glass on the front and rear of the module with submillimeter V-grooves that are designed to capture and reflect incident light as illustrated in the figure. More details of such concentrators are found in Uematsu et al., 2001, Solar Energy Materials & Solar Cell 67, 425-434 and Uematsu et al., 2001, Solar Energy Materials & Solar Cell 67, 441-448, each of which is hereby incorporated by reference herein in its entirety. Additional static concentrators that can be used with the present application are discussed in Handbook of Photovoltaic Science and Engineering, 2003, Luque and Hegedus (eds.), Wiley & Sons, West Sussex, England, Chapter 12, which is hereby incorporated by reference herein in its entirety.

### 5.8 Internal Reflector Embodiments

After photovoltaic modules 402 are encapsulated they may be arranged to form assemblies. Referring to FIG. 14, an internal reflector 1404 may be used to enhance solar input into the solar cell system in such assemblies. elongated substrate 403

In general, internal reflectors 1404 of the present application are designed to optimize reflection of light into adjacent photovoltaic modules 402. In some embodiments, an internal reflector 1404 may have a symmetrical four-sided cross-sectional shape. In other embodiments, the cross-sectional shape of the internal reflectors 1404 of the present application is not limited to such a configuration. In some embodiments, a cross-sectional shape of an internal reflector 1404 is astroid. In some embodiments, a cross-sectional shape of an internal reflector 1404 is four-sided and at least one side of the four-sided cross-sectional shape is linear. In some embodiments, a cross-sectional shape of an internal reflector 1404 is four-sided and at least one side of the four-sided cross-sectional shape is parabolic. In some embodiments, a cross-sectional shape of an internal reflector 1404 is four-sided and at least one side of the four-sided cross-sectional shape is concave. In some embodiments, a cross-sectional shape of an internal reflector 1404 is four-sided; and at least one side of the four-sided cross-sectional shape is circular or elliptical. In some embodiments, a cross-sectional shape of an internal reflector in the plurality of internal reflectors is four-sided and at least one side of the four-sided cross-sectional shape defines a diffuse surface on the internal reflector. In some embodiments, a cross-sectional shape of an internal reflector 1404 is four-sided and at least one side of the four-sided cross-sectional shape is the involute of a cross-sectional shape of photovoltaic module 402. In some embodiments, a cross-sectional shape of an internal reflector 1404 is two-sided, three-sided, four-sided, five-sided, or six-sided. In some embodiments, a cross-sectional shape of an internal reflector in the plurality of internal reflectors 1404 is four-sided and at least one side of the four-sided cross-sectional shape is faceted.

Additional features are added to the reflectors 1404 to enhance the reflection onto adjacent photovoltaic modules 402 in some embodiments. Modified reflectors 1404 are equipped with a strong reflective property such that incident light is effectively reflected off the side surfaces 1610 of the reflectors 1404. In some embodiments, the reflected light off surfaces 1610 does not have directional preference. In other embodiments, the reflector surfaces 1610 are designed such that the reflected light is directed towards the photovoltaic module 402 for optimal absorbance.

In some embodiments, the connection between an internal reflector 1404 and an adjacent photovoltaic module is provided by an additional adaptor piece. Such an adapter piece has surface features that are complementary to both the shapes of internal reflectors 1404 as well as photovoltaic modules 402 in order to provide a tight fit between such components. In some embodiments, such adaptor pieces are fixed on the internal reflectors 1404. In other embodiments, the adaptor pieces are fixed on the photovoltaic modules 402. In additional embodiments, the connection between photovoltaic modules 402 and internal reflectors 1404 may be strengthened by electrically conducting glue or tapes.

Diffuse Reflection. In some embodiments in accordance with the present application, a side surface 1610 of the reflector 1404 is a diffuse reflecting surface (e.g., 1610 in FIG. 14). The concept of diffuse reflection can be better appreciated with a first understanding of specular reflection. Specular reflection is defined as the reflection off smooth surfaces such as mirrors or a calm body of water. On a specular surface, light is reflected mainly in the direction of the reflected ray and is attenuated by an amount dependent upon the physical properties of the surface. Since the light reflected from the surface is mainly in the direction of the reflected ray, the position of the observer (e.g., the position of the photovoltaic modules 402) determines the perceived illumination of the surface. Specular reflection models the light reflecting properties of shiny or mirror-like surfaces. In contrast to specular reflection, reflection off rough surfaces such as clothing, paper, and the asphalt roadway leads to a different type of reflection known as diffuse reflection. Light incident on a diffuse reflection surface is reflected equally in all directions and is attenuated by an amount dependent upon the physical properties of the surface. Since light is reflected equally in all directions the perceived illumination of the surface is not dependent on the position of the observer or receiver of the reflected light (e.g. the position of the photovoltaic module 402). Diffuse reflection models the light reflecting properties of matte surfaces.

Diffuse reflection surfaces reflect off light with no directional dependence for the viewer. Whether the surface is microscopically rough or smooth has a tremendous impact upon the subsequent reflection of a beam of light. Input light from a single directional source is reflected off in all directions on a diffuse reflecting surface. Diffuse reflection originates from a combination of internal scattering of light, e.g., the light is absorbed and then re-emitted, and external scattering from the rough surface of the object.

Lambertian reflection. In some embodiments in accordance with the present application, a surface 1610 of a reflector 1404 is a Lambertian reflecting surface (e.g., 1610 in FIG. 14). A Lambertian source is defined as an optical source that obeys Lambert's cosine law, i.e., that has an intensity directly proportional to the cosine of the angle from which it is viewed. Accordingly, a Lambertian surface is defined as a surface that provides uniform diffusion of incident radiation such that its radiance (or luminance) is the same in all directions from which it can be measured (e.g., radiance is independent of viewing angle) with the caveat that the total area of the radiating surface is larger than the area being measured.

On a perfectly diffusing surface, the intensity of the light emanating in a given direction from any small surface component is proportional to the cosine of the angle of the normal to the surface. The brightness (luminance, radiance) of a Lambertian surface is constant regardless of the angle from which it is viewed.

The incident light \vec{l} strikes a Lambertian surface and reflects in different directions. When the intensity of \vec{l} is defined as Iᵢₙ, the intensity (e.g., Iₒᵤₜ) of a reflected light \vec{ν} can be defined as following in accordance to Lambert's cosine law:

$${I}_{out} ( {v}^{->} ) = {I}_{i n} ( {l}^{->} ) ϕ ( {v}^{->} , {l}^{->} ) \frac{cos {θ}_{in}}{cos {θ}_{out}}$$

where φ(\vec{ν},\vec{l})=k_{d} cos θₒᵤₜ and k_{d} is related to the surface property. The incident angle is defined as θᵢₙ, and the reflected angle is defined as θₒᵤₜ. Using the vector dot product formula, the intensity of the reflected light can also be written as:

Iₒᵤₜ(\vec{ν})=k_{d}Iᵢₙ(\vec{l})\vec{l}·\vec{n},

where \vec{n} denotes a vector that is normal to the Lambertian surface.

Such a Lambertian surface does not lose any incident light radiation, but re-emits it in all the available solid angles with 2π radians, on the illuminated side of the surface. Moreover, a Lambertian surface emits light so that the surface appears equally bright from any direction. That is, equal projected areas radiate equal amounts of luminous flux. Though this is an ideal, many real surfaces approach it. For example, a Lambertian surface can be created with a layer of diffuse white paint. The reflectance of such a typical Lambertian surface may be 93%. In some embodiments, the reflectance of a Lambertian surface may be higher than 93%. In some embodiments, the reflectance of a Lambertian surface may be lower than 93%. Lambertian surfaces have been widely used in LED design to provide optimized illumination, for example, in U.S. Pat. No. 6,257,737 to Marshall, et al.; U.S. Pat. No. 6,661,521 to Stem; and U.S. Pat. No. 6,603,243 to Parkyn, et al., which are each hereby incorporated by reference herein in their entirety.

Advantageously, Lambertian surfaces on an internal reflector 1404 effectively reflect light in all directions. The reflected light is then directed towards the photovoltaic module 402 to enhance solar cell performance.

Reflection on involute surfaces. In some embodiments in accordance with the present application, a surface 1610 of the internal reflector 1404 is an involute surface of the photovoltaic module 402. In some embodiments, the photovoltaic module 402 is circular or near circular. In some embodiments, the reflector surface 1610 is preferably the involute of a circle. The involute of a circle is defined as the path traced out by a point on a straight line that rolls around a circle. For example, the involute of a circle can be drawn in the following steps. First, attach a string to a point on a curve. Second, extend the string so that it is tangent to the curve at the point of attachment. Third, wind the string up, keeping it always taut. The locus of points traced out by the end of the string is called the involute of the original circle. The original circle is called the evolute of its involute curve.

Although in general a curve has a unique evolute, it has infinitely many involutes corresponding to different choices of initial point. An involute can also be thought of as any curve orthogonal to all the tangents to a given curve. For a circle of radius r, at any time t, its equation can be written as:

x=r cos t

y=r sin t

Correspondingly, the parametric equation of the involute of the circle is:

xᵢ=r(cos t+t sin t)

yᵢ=r(sin t−t cos t)

Evolute and involute are reciprocal functions. The evolute of an involute of a circle is a circle.

Involute surfaces have been implemented in numerous patent designs to optimize light reflections. For example, a flash lamp reflector (U.S. Pat. No. 4,641,315 to Draggoo, hereby incorporated by reference herein in its entirety) and concave light reflector devices (U.S. Pat. No. 4,641,315 to Rose, hereby incorporated by reference herein in its entirety) both utilize involute surfaces to enhance light reflection efficiency.

Assemblies. In some embodiments, a plurality of photovoltaic modules 402 are geometrically arranged in a parallel or near parallel manner. In some embodiments, the terminal ends of photovoltaic modules 402 can be stripped down to the back-electrode 404. For example, consider the case in which the photovoltaic module 402 is constructed out of a s a cylindrical elongated substrate 403 and a back-electrode 404 made of molybdenum. In such a case, the end of the photovoltaic module 402 can be stripped down to the molybdenum back-electrode 404 and an external electrode can be electrically connected with the back-electrode 404.

In some embodiments, each internal reflector 1404 connects to two photovoltaic modules as depicted in FIG. 14402. Because of this, photovoltaic modules 402 are effectively joined into a single composite device. In some embodiments, external electrodes extend the connection from back-electrode 404. In some embodiments, internal reflectors 1404 are connected to photovoltaic modules 402 via indentations on the transparent casing 310. In some embodiments, the indentations on the transparent casing 310 are created to complement the shape of the internal reflector 1404. Indentations on two transparent casings 310 are used to lock in one internal reflector 1404 that is positioned between the two photovoltaic modules. In some embodiments, adhesive materials, e.g., epoxy glue, are used to fortify the connections between the internal reflector 1404 and the adjacent encapsulated photovoltaic modules such that solar radiation is properly reflected towards the photovoltaic modules 402 for absorption.

In some embodiments in accordance with the present application, the internal reflector 1404 and the transparent casing 310 of a photovoltaic module 402 can be created in the same molding process. For example, an array of alternating the transparent casing 310 and astroid reflectors 1404 can be made as a single composite entity. Additional modifications may be done to enhance the albedo effect from the internal reflector 1404. There is no limit to the number of internal reflectors 1404 in an assembly (e.g., 10 or more, 100 or more, 1000 or more, 10,000 or more, between 5,000 and one million internal reflectors 1404).

### 5.9 Additional Substrate Embodiments

In some embodiments, all or a portion of the elongated substrate 403 is a nonplanar closed form shape. For instance, in some embodiments, all or a portion of the elongated substrate 403 is a rigid tube or a rigid solid rod. In some embodiments, all or a portion of the elongated substrate 403 is any solid cylindrical shape or hollowed cylindrical shape. In some embodiments, the elongated substrate 403 is a rigid tube made out plastic metal or glass. In some embodiments, the overall outer shape of the photovoltaic module 402 is the same shape as the elongated substrate 403. In some embodiments, the overall outer shape of the photovoltaic module 402 is different than the shape of the elongated substrate 403. In some embodiments, the elongated substrate 403 is nonfibrous

In some embodiments, the elongated substrate 403 is rigid. Rigidity of a material can be measured using several different metrics including, but not limited to, Young's modulus. In solid mechanics, Young's Modulus (E) (also known as the Young Modulus, modulus of elasticity, elastic modulus or tensile modulus) is a measure of the stiffness of a given material. It is defined as the ratio, for small strains, of the rate of change of stress with strain. This can be experimentally determined from the slope of a stress-strain curve created during tensile tests conducted on a sample of the material. Young's modulus for various materials is given in the following table.

| | Young's modulus | Young's modulus (E) in |
|---|---|---|
| Material | (E) in GPa | lbf/in² (psi) |
| Rubber (small strain) | 0.01-0.1 | 1,500-15,000 |
| Low density polyethylene | 0.2 | 30,000 |
| Polypropylene | 1.5-2 | 217,000-290,000 |
| Polyethylene terephthalate | 2-2.5 | 290,000-360,000 |
| Polystyrene | 3-3.5 | 435,000-505,000 |
| Nylon | 3-7 | 290,000-580,000 |
| Aluminum alloy | 69 | 10,000,000 |
| Glass (all types) | 72 | 10,400,000 |
| Brass and bronze | 103-124 | 17,000,000 |
| Titanium (Ti) | 105-120 | 15,000,000-17,500,000 |
| Carbon fiber reinforced plastic | 150 | 21,800,000 |
| (unidirectional, along grain) | | |
| Wrought iron and steel | 190-210 | 30,000,000 |
| Tungsten (W) | 400-410 | 58,000,000-59,500,000 |
| Silicon carbide (SiC) | 450 | 65,000,000 |
| Tungsten carbide (WC) | 450-650 | 65,000,000-94,000,000 |
| Single Carbon nanotube | 1,000+ | 145,000,000 |
| Diamond (C) | 1,050-1,200 | 150,000,000-175,000,000 |

In some embodiments, a material (e.g., an elongated substrate 403) is deemed to be rigid when it is made of a material that has a Young's modulus of 20 GPa or greater, 30 GPa or greater, 40 GPa or greater, 50 GPa or greater, 60 GPa or greater, or 70 GPa or greater. In some embodiments of the present application a material (e.g., the elongated substrate 403) is deemed to be rigid when the Young's modulus for the material is a constant over a range of strains. Such materials are called linear, and are said to obey Hooke's law. Thus, in some embodiments, the elongated substrate 403 is made out of a linear material that obeys Hooke's law. Examples of linear materials include, but are not limited to, steel, carbon fiber, and glass. Rubber and soil (except at very low strains) are non-linear materials. In some embodiments, a material is considered rigid when it adheres to the small deformation theory of elasticity, when subjected to any amount of force in a large range of forces (e.g., between 1 dyne and 10⁵ dynes, between 1000 dynes and 10⁶ dynes, between 10,000 dynes and 10⁷ dynes), such that the material only undergoes small elongations or shortenings or other deformations when subject to such force. The requirement that the deformations (or gradients of deformations) of such exemplary materials are small means, mathematically, that the square of either of these quantities is negligibly small when compared to the first power of the quantities when exposed to such a force. Another way of characterizing a material as rigid is to say that such a material does not visibly deform over a large range of forces (e.g., between 1 dyne and 10⁵ dynes, between 1000 dynes and 10⁶ dynes, between 10,000 and 10⁷ dynes). Still another way of stating the requirement for a rigid material is that such a material, over a large range of forces (e.g., between 1 dyne and 10⁵ dynes, between 1000 dynes and 10⁶ dynes, between 10,000 and 10⁷ dynes), is characterized by a strain tensor that only has linear terms. The strain tensor for materials is described in Borg, 1962, Fundamentals of Engineering Elasticity, Princeton, N.J., pp. 36-41, which is hereby incorporated by reference herein in its entirety. In some embodiments, a material is considered rigid when a sample of the material of sufficient size and dimensions does not bend under the force of gravity.

In general, the extent to which a body (e.g., the elongated substrate 403, etc.) deflects under a force, e.g., the stiffness of the body, is related to the Young's Modulus of the material from which it is made, the body's length and cross-sectional dimensions, and the force applied to the body, as is known to those of ordinary skill in the art. In some embodiments, the Young's Modulus of the body material, and the body's length and cross-sectional area, are selected such that the body (e.g., the elongated substrate 403, etc.) substantially does not visibly deflect (bend) when a first end of the body is subjected to a force of, e.g., between 1 dyne and 10⁵ dynes, between 100 dynes and 10⁶ dynes, or between 10,000 dynes and 10⁷ dynes, while a second end of the body is held fixed. In some embodiments, the Young's Modulus of the body material, and the body's length and cross-sectional area, are selected such that the body (e.g., the elongated substrate 403, etc.) substantially does not visibly deflect when a first end of the body is subjected to the force of gravity, while a second end of the body is held fixed.

The present application is not limited to substrates that have rigid cylindrical shapes or are solid rods. All or a portion of the elongated substrate 403 can be characterized by a cross-section bounded by any one of a number of shapes other than the circular shaped depicted in FIG. 3B. The bounding shape can be any one of circular, ovoid, or any shape characterized by one or more smooth curved surfaces, or any splice of smooth curved surfaces. The bounding shape can also be linear in nature, including triangular, rectangular, pentangular, hexagonal, or having any number of linear segmented surfaces. The bounding shape can be an n-gon, where n is 3, 5, or greater than 5. Or, the cross-section can be bounded by any combination of linear surfaces, arcuate surfaces, or curved surfaces. The bounding shape can be any shape that includes at least one arcuate edge. As described herein, for ease of discussion only, an omnifacial circular cross-section is illustrated to represent nonplanar embodiments of the photovoltaic module 402. However, it should be noted that any cross-sectional geometry may be used in a photovoltaic module 402 that is nonplanar in practice.

In some embodiments, a first portion of the elongated substrate 403 is characterized by a first cross-sectional shape and a second portion of the elongated substrate 403 is characterized by a second cross-sectional shape, where the first and second cross-sectional shapes are the same or different. In some embodiments, at least ten percent, at least twenty percent, at least thirty percent, at least forty percent, at least fifty percent, at least sixty percent, at least seventy percent, at least eighty percent, at least ninety percent or all of the length of the elongated substrate 403 is characterized by the first cross-sectional shape. In some embodiments, the first cross-sectional shape is planar (e.g., has no arcuate side) and the second cross-sectional shape has at least one arcuate side.

In some embodiments, the elongated substrate 403 is made of a urethane polymer, an acrylic polymer, a fluoropolymer, polybenzamidazole, polyimide, polytetrafluoroethylene, polyetheretherketone, polyamide-imide, glass-based phenolic, polystyrene, cross-linked polystyrene, polyester, polycarbonate, polyethylene, polyethylene, acrylonitrile-butadiene-styrene, polytetrafluoro-ethylene, polymethacrylate, nylon 6,6, cellulose acetate butyrate, cellulose acetate, rigid vinyl, plasticized vinyl, or polypropylene. In some embodiments, the elongated substrate 403 is made of aluminosilicate glass, borosilicate glass (e.g., Pyrex, Duran, Simax, etc.), dichroic glass, germanium/semiconductor glass, glass ceramic, silicate/fused silica glass, soda lime glass, quartz glass, chalcogenide/sulphide glass, fluoride glass, pyrex glass, a glass-based phenolic, cereated glass, or flint glass. In some embodiments, the elongated substrate 403 is a solid cylindrical shape. Such solid cylindrical substrates 403 can be made out of a plastic, glass, metal, or metal alloy.

In some embodiments, a cross-section of the elongated substrate 403 is circumferential and has an outer diameter of between 3 mm and 100 mm, between 4 mm and 75 mm, between 5 mm and 50 mm, between 10 mm and 40 mm, or between 14 mm and 17 mm. In some embodiments, a cross-section of the elongated substrate 403 is circumferential and has an outer diameter of between 1 mm and 1000 mm.

In some embodiments, the elongated substrate 403 is a tube with a hollowed inner portion. In such embodiments, a cross-section of the elongated substrate 403 is characterized by an inner radius defining the hollowed interior and an outer radius. The difference between the inner radius and the outer radius is the thickness of the elongated substrate 403. In some embodiments, the thickness of the elongated substrate 403 is between 0.1 mm and 20 mm, between 0.3 mm and 10 mm, between 0.5 mm and 5 mm, or between 1 mm and 2 mm. In some embodiments, the inner radius is between 1 mm and 100 mm, between 3 mm and 50 mm, or between 5 mm and 10 mm.

In some embodiments, the elongated substrate 403 has a length (perpendicular to the plane defined by FIG. 3B) that is between 5 mm and 10,000 mm, between 50 mm and 5,000 mm, between 100 mm and 3000 mm, or between 500 mm and 1500 mm. In one embodiment, the elongated substrate 403 is a hollowed tube having an outer diameter of 15 mm and a thickness of 1.2 mm, and a length of 1040 mm.

In some embodiments, the elongated substrate 403 has a width dimension and a longitudinal dimension. In some embodiments, the longitudinal dimension of the elongated substrate 403 is at least four times greater than the width dimension. In other embodiments, the longitudinal dimension of the elongated substrate 403 is at least five times greater than the width dimension. In yet other embodiments, the longitudinal dimension of the elongated substrate 403 is at least six times greater than the width dimension. In some embodiments, the longitudinal dimension of the elongated substrate 403 is 10 cm or greater. In other embodiments, the longitudinal dimension of the elongated substrate 403 is 50 cm or greater. In some embodiments, the width dimension of the elongated substrate 403 is 1 cm or greater. In other embodiments, the width dimension of the elongated substrate 403 is 5 cm or greater. In yet other embodiments, the width dimension of the elongated substrate 403 is 10 cm or greater.

### 5.10 Optional Electrode Strips

In some embodiments, the electrode strips 420 are thin strips of electrically conducting material that run lengthwise along the long axis (cylindrical axis) of the photovoltaic module 402, as depicted in FIG. 4A. In some embodiments, the optional electrode strips are positioned at spaced intervals on the surface of the transparent conductive layer 412. For instance, in FIG. 3B, the electrode strips 420 run parallel to each other and are spaced out at ninety degree intervals along the cylindrical axis of the photovoltaic module 402. In some embodiments, the electrode strips 420 are spaced out at five degree, ten degree, fifteen degree, twenty degree, thirty degree, forty degree, fifty degree, sixty degree, ninety degree or 180 degree intervals on the surface of the transparent conductive layer 412. In some embodiments, there is a single electrode strip 420 on the surface of the transparent conductive layer 412. In some embodiments, there is no electrode strip 420 on the surface of the transparent conductive layer 412. In some embodiments, there are zero, one, two, three, four, five, six, seven, eight, nine, ten, eleven, twelve, fifteen or more, or thirty or more electrode strips on the transparent conductive layer 412, all running parallel, or near parallel, to each down the long (cylindrical) axis of the photovoltaic module. In some embodiments the electrode strips 420 are evenly spaced about the circumference of the transparent conductive layer 412, for example, as depicted in FIG. 3B. In alternative embodiments, the electrode strips 420 are not evenly spaced about the circumference of the transparent conductive layer 412. In some embodiments, the electrode strips 420 are only on one face of the photovoltaic module. In some embodiments, the electrode strips 420 are made of conductive epoxy, conductive ink, copper or an alloy thereof, aluminum or an alloy thereof, nickel or an alloy thereof, silver or an alloy thereof, gold or an alloy thereof, a conductive glue, or a conductive plastic.

In some embodiments, there are electrode strips that run along the long (cylindrical) axis of the photovoltaic module and these electrode strips are interconnected to each other by grid lines. These grid lines can be thicker than, thinner than, or the same width as the electrode strips. These grid lines can be made of the same or different electrically material as the electrode strips.

In some embodiments, the electrode strips 420 are deposited on the transparent conductive layer 412 using ink jet printing. Examples of conductive ink that can be used for such strips include, but are not limited to silver loaded or nickel loaded conductive ink. In some embodiments epoxies as well as anisotropic conductive adhesives can be used to construct the electrode strips 420. In typical embodiments, such inks or epoxies are thermally cured in order to form the electrode strips 420.

### 5.11 Back-Electrode 404

In some embodiments, the back-electrode 404 is composed of any conductive material, such as aluminum, molybdenum, tungsten, vanadium, rhodium, niobium, chromium, tantalum, titanium, steel, nickel, platinum, silver, gold, an alloy thereof, or any combination thereof. In some embodiments, the back-electrode 404 is composed of any conductive material, such as indium tin oxide, titanium nitride, tin oxide, fluorine doped tin oxide, doped zinc oxide, aluminum doped zinc oxide, gallium doped zinc oxide, boron doped zinc oxide indium-zinc oxide, a metal-carbon black-filled oxide, a graphite-carbon black-filled oxide, a carbon black-filled oxide, a superconductive carbon black-filled oxide, an epoxy, a conductive glass, or a conductive plastic. As defined herein, a conductive plastic is one that, through compounding techniques, contains conductive fillers which, in turn, impart their conductive properties to the plastic. In some embodiments, the conductive plastics used in the present application to form the back-electrode 404 contain fillers that form sufficient conductive current-carrying paths through the plastic matrix to support the photovoltaic current generated by the photovoltaic module with negligible resistive losses. The plastic matrix of the conductive plastic is typically insulating, but the composite produced exhibits the conductive properties of the filler.

### 5.12 Transparent Conductive Layer 412

In some embodiments, the transparent conductive layer 412 is made of tin oxide SnOₓ (with or without fluorine doping), indium-tin oxide (ITO), doped zinc oxide (e.g., aluminum doped zinc oxide, gallium doped zinc oxide, boron doped zinc oxide), indium-zinc oxide or any combination thereof. In some embodiments, the transparent conductive layer 412 is either p-doped or n-doped. In some embodiments, the transparent conductive layer is made of carbon nanotubes. Carbon nanotubes are commercially available, for example from Eikos (Franklin, Mass.) and are described in U.S. Pat. No. 6,988,925, which is hereby incorporated by reference herein in its entirety. For example, in embodiments where the outer semiconductor layer of the junction 410 is p-doped, the transparent conductive layer 412 can be p-doped. Likewise, in embodiments where the outer semiconductor layer of the junction 410 is n-doped, the transparent conductive layer 412 can be n-doped. In general, the transparent conductive layer 412 is preferably made of a material that has very low resistance, suitable optical transmission properties (e.g., greater than 90%), and a deposition temperature that will not damage underlying layers of the semiconductor junction 410 and/or the optional i-layer 415. In some embodiments, the transparent conductive layer 412 is an electrically conductive polymer material such as a conductive polythiophene, a conductive polyaniline, a conductive polypyrrole, a PSS-doped PEDOT (e.g., Bayrton), or a derivative of any of the foregoing. In some embodiments, the transparent conductive layer 412 comprises more than one layer, including a first layer comprising tin oxide SnOₓ (with or without fluorine doping), indium-tin oxide (ITO), indium-zinc oxide, doped zinc oxide (e.g., aluminum doped zinc oxide, gallium doped zinc oxide, boron dope zinc oxide) or a combination thereof and a second layer comprising a conductive polythiophene, a conductive polyaniline, a conductive polypyrrole, a PSS-doped PEDOT (e.g., Bayrton), or a derivative of any of the foregoing. Additional suitable materials that can be used to form transparent conductive layer are disclosed in United States Patent publication 2004/0187917A1 to Pichler, which is hereby incorporated by reference herein in its entirety.

### 5.13 Transparent Casing 310

Potential transparent casing 310 geometries include, but are not limited to, cylindrical, various elongate structures where the radial dimension and/or cross-sectional area are far less than the length, having arcuate features, box-like, or any potential geometry compatible for use with photovoltaic cells. In some of the embodiments described herein, the transparent casing 310 is tubular, with a hollow core. However, it should be understood that other geometries and shapes can be used.

In some embodiments, the transparent casing 310 is made of a urethane polymer, an acrylic polymer, polymethylmethacrylate (PMMA), a fluoropolymer, silicone, poly-dimethyl siloxane (PDMS), silicone gel, epoxy, ethylene vinyl acetate (EVA), perfluoroalkoxy fluorocarbon (PFA), nylon/polyamide, cross-linked polyethylene (PEX), polyolefin, polypropylene (PP), polyethylene terephtalate glycol (PETG), polytetrafluoroethylene (PTFE), thermoplastic copolymer (for example, ETFE® which is a derived from the polymerization of ethylene and tetrafluoroethylene: TEFLON® monomers), polyurethane/urethane, polyvinyl chloride (PVC), polyvinylidene fluoride (PVDF), TYGON®, vinyl, VITON®, or any combination or variation thereof.

In some embodiments, the transparent casing 310 comprises a plurality of transparent casing layers. In some embodiments, each transparent casing is composed of a different material. For example, in some embodiments, the transparent casing 310 comprises a first transparent casing layer and a second transparent casing layer. Depending on the exact configuration of the solar cell, the first transparent casing layer is disposed on the transparent conductive layer 412, the filler material 330 or the water resistant layer. The second transparent casing layer is disposed on the first transparent casing layer.

In some embodiments, each transparent casing layer has different properties. In one example, the outer transparent casing layer has excellent UV shielding properties whereas the inner transparent casing layer has good water proofing characteristics. Moreover, the use of multiple transparent casing layers can be used to reduce costs and/or improve the overall properties of the transparent casing 310. For example, one transparent casing layer may be made of an expensive material that has a desired physical property. By using one or more additional transparent casing layers, the thickness of the expensive transparent casing layer may be reduced, thereby achieving a savings in material costs. In another example, one transparent casing layer may have excellent optical properties (e.g., index of refraction, etc.) but be very heavy. By using one or more additional transparent casing layers, the thickness of the heavy transparent casing layer may be reduced, thereby reducing the overall weight of the transparent casing 310.

### 6. REFERENCES CITED

All references cited herein are incorporated herein by reference in their entirety and for all purposes to the same extent as if each individual publication or patent or patent application was specifically and individually indicated to be incorporated by reference in its entirety for all purposes.

Many modifications and variations of this application can be made without departing from its spirit and scope, as will be apparent to those skilled in the art. The specific embodiments described herein are offered by way of example only, and the application is to be limited only by the terms of the appended claims, along with the full scope of equivalents to which such claims are entitled.

What is claimed:

1. A photovoltaic module comprising:
(A) an elongated substrate wherein at least a portion of the elongated substrate is rigid, the elongated substrate having a width dimension and a longitudinal dimension;
(B) one or more solar cells disposed on said elongated substrate, said one or more solar cells each comprising:
a back-electrode disposed on a surface of the elongated substrate;
a semiconductor junction layer disposed on all or a portion of a surface of said back-electrode; and
a transparent conductive layer disposed on all or a portion of a surface of the semiconductor junction, wherein said transparent conductive layer has a first refractive index;
(C) a filler material disposed on the transparent conductive layer of each of the one or more solar cells, wherein the filler material has a second refractive index that is smaller or equal in value to said first refractive index; and
(D) a transparent casing disposed on said filler material thereby sealing said photovoltaic module, wherein said transparent casing has a third refractive index.

2. The photovoltaic module of claim 1, wherein said second refractive index has a value approximately equal to said third refractive index plus X, where X is half the absolute difference between the values of said first refractive index and said third refractive index.

3. The solar cell unit of claim 1, wherein said second refractive index is approximately equal to said first refractive index.

4. The photovoltaic module of claim 1, wherein said second refractive index is approximately equal to said third refractive index.

5. The photovoltaic module of claim 1, wherein said first and second refractive indexes are chosen to minimize the reflection of light on a surface of said transparent conductive layer.

6. The photovoltaic module of claim 1, wherein said third refractive index is in the range of 1.2 to 1.9.

7. The photovoltaic module of claim 1, wherein said third refractive index is in the range of 1.1 to 2.

8. The photovoltaic module of claim 1, wherein said second refractive index is in the range of 1.2 to 1.9.

9. The photovoltaic module of claim 1, wherein said second refractive index is approximately equal to 1.6.

10. The photovoltaic module of claim 1, wherein said first refractive index is greater or equal to 1.5.

11. The photovoltaic module of claim 1, wherein said first refractive index is greater or equal to 1.6.

12. The photovoltaic module of claim 1, wherein said first, second, and third refractive indexes are chosen such that light incident on said transparent casing is refracted towards the center of said photovoltaic module.

13. The photovoltaic module of claim 1, wherein a first solar cell in said one or more solar cells has a first surface area and said transparent casing has a second surface area, and wherein said first, second, and third refractive indexes are chosen such that said first solar cell has an effective optical surface area approximately equal to the second surface area.

14. The photovoltaic module of claim 1, wherein said second and third refractive indexes are chosen to minimize the reflection of light on the surface of said filler material.

15. The photovoltaic module of claim 1, wherein said filler material comprises ethylene vinyl acetate (EVA), silicone, silicone gel, a silicone-based oil, epoxy, polydimethyl siloxane (PDMS), RTV silicone rubber, polyvinyl butyral (PVB), thermoplastic polyurethane (TPU), a polycarbonate, an acrylic, a fluoropolymer, or a urethane.

16. The photovoltaic module of claim 1, wherein said filler material is a polydimethylsiloxane polymer liquid.

17. The photovoltaic module of claim 16, wherein the polydimethylsiloxane polymer liquid has the chemical formula (CH₃)₃SiO[SiO(CH₃)₂]ₙSi(CH₃)₃, wherein n is a range of integers chosen such that the liquid has an average bulk viscosity that falls in the range between 40 centistokes and 60 centistokes.

18. The photovoltaic module of claim 1, wherein the filler material has a thermal coefficient of expansion of greater than 500×10⁻⁶/° C.

19. The photovoltaic module of claim 1, wherein the filler material is formed from a silicone oil mixed with a dielectric gel.

20. The photovoltaic module of claim 19, wherein the silicone oil is a polydimethylsiloxane polymer liquid and the dielectric gel is a mixture of a first silicone elastomer and a second silicone elastomer.

21. The photovoltaic module of claim 1, wherein the filler material is formed from X %, by weight, a polydimethylsiloxane polymer liquid, Y %, by weight, a first silicone elastomer, and Z %, by weight, a second silicone elastomer, where X, Y, and Z sum to 100.

22. The photovoltaic module of claim 21, wherein the polydimethylsiloxane polymer liquid has the chemical formula (CH₃)₃SiO[SiO(CH₃)₂]ₙSi(CH₃)₃, wherein n is a range of integers chosen such that the polymer liquid has an average bulk viscosity that falls in a range between 50 centistokes and 100,000 centistokes.

23. The photovoltaic module of claim 21, wherein the first silicone elastomer comprises at least sixty percent, by weight, dimethylvinyl-terminated dimethyl siloxane and between 3 and 7 percent by weight silicate.

24. The photovoltaic module of claim 21, wherein the second silicone elastomer comprises:
(i) at least sixty percent, by weight, dimethylvinyl-terminated dimethyl siloxane; (ii) between ten and thirty percent by weight hydrogen-terminated dimethyl siloxane; and
(iii) between 3 and 7 percent by weight trimethylated silica.

25. The photovoltaic module of claim 21, wherein
X is between 30 and 90;
Y is between 2 and 20; and
Z is between 2 and 20.

26. The photovoltaic module of claim 1, further comprising a water resistant layer disposed on all or a portion of said transparent casing.

27. The photovoltaic module of claim 1, further comprising an antireflective coating disposed on all or a portion of said transparent casing.

28. The photovoltaic module of claim 1, wherein all or a portion of the elongated substrate is a rigid tube or a rigid solid rod.

29. The photovoltaic module of claim 1, wherein a solar cell in the one or more solar cells is cylindrical shaped and wherein
$${r}_{i} \geq \frac{{r}_{o}}{{η}_{outer ring}}$$
wherein
rᵢ is a radius of the solar cell;
rₒ is the radius of the transparent casing; and
η_{outer ring} is said second refractive index, said third refractive index, or some combination of said second and third refractive indexes.

30. The photovoltaic module of claim 1, wherein the elongated substrate or the transparent casing is nonplanar.

31. The photovoltaic module of claim 1, wherein the elongated substrate or the transparent casing is characterized by a circular cross-section, an ovoid cross-section, a triangular cross-section, a pentangular cross-section, a hexagonal cross-section, a cross-section having at least one arcuate portion, or a cross-section having at least one curved portion.

32. The photovoltaic module of claim 1, wherein a first portion of the elongated substrate or the transparent casing is characterized by a first cross-sectional shape and a second portion of the elongated substrate or the transparent casing is characterized by a second cross-sectional shape.

33. The photovoltaic module of claim 32, wherein the first cross-sectional shape and the second cross-sectional shape are the same.

34. The photovoltaic module of claim 32, wherein the first cross-sectional shape and the second cross-sectional shape are different.

35. The photovoltaic module of claim 32, wherein at least ninety percent of a length of the elongated substrate is characterized by the first cross-sectional shape.

36. The photovoltaic module of claim 32, wherein the first cross-sectional shape is planar and the second cross-sectional shape has at least one arcuate side.

37. The photovoltaic module of claim 32, wherein a cross-section of the elongated substrate or the transparent casing forms an n-sided polygon, wherein n is an integer greater than or equal to 3.

38. The photovoltaic module of claim 1, wherein the portion of the elongated substrate that is rigid has a Young's modulus of 20 GPa or greater.

39. The photovoltaic module of claim 1, wherein the portion of the elongated substrate that is rigid has a Young's modulus of 40 GPa or greater.

40. The photovoltaic module of claim 1, wherein the portion of the elongated substrate that is rigid has a Young's modulus of 70 GPa or greater.

41. The photovoltaic module of claim 1, wherein the portion of the elongated substrate that is rigid is made of a linear material.

42. The photovoltaic module of claim 1, wherein a longitudinal dimension of the elongated substrate is at least four times greater than the width dimension of the elongated substrate.

43. The photovoltaic module of any one of claim 1, wherein a longitudinal dimension of the elongated substrate is at least five times greater than the width dimension of the elongated substrate.

44. The photovoltaic module of claim 1, wherein the filler material has a viscosity of less than 1×10⁶ cP.

45. The photovoltaic module of claim 1, wherein a longitudinal dimension of the elongated substrate is 50 cm or greater.

46. The photovoltaic module of claim 1, wherein the width dimension of the elongated substrate is 1 cm or greater.

47. The photovoltaic module of claim 1, wherein the width dimension of the elongated substrate is 5 cm or greater.

48. The photovoltaic module of claim 1, wherein the elongated substrate is either:
closed at a first end and a second end of the elongated substrate,
open at a first end and closed at a second end of the elongated substrate, or
open at a first end and a second end of the elongated substrate.

49. The photovoltaic module of claim 1, further comprising a first sealant cap that hermetically seals a first end of the transparent casing.

50. The photovoltaic module of claim 49, further comprising a second sealant cap that hermetically seals a second end of the transparent casing.

51. The photovoltaic module of claim 49, wherein the first sealant cap is made of metal, metal alloy, or glass.

52. The photovoltaic module of claim 49, wherein the first sealant cap is made of aluminosilicate glass, borosilicate glass, dichroic glass, germanium/semiconductor glass, glass ceramic, silicate/fused silica glass, soda lime glass, quartz glass, chalocogenide/sulphide glass, fluoride glass, PYREX glass, a glass-based phenolic, cereated glass, or flint glass.

53. The photovoltaic module of claim 49, wherein the first sealant cap is hermetically sealed to an inner surface or an outer surface of the transparent casing, and wherein the hermetic seal between the first sealant cap and the transparent casing is formed by a strip of sealant.

54. The photovoltaic module of claim 53, wherein the strip of sealant is on an inner edge of the first sealant cap, on an outer edge of the first sealant cap, on an outer edge of the transparent casing, or an inner edge of the transparent casing, and wherein the strip of sealant is formed from glass frit, sol-gel, or a ceramic cement.

55. The photovoltaic module of claim 50, wherein a water transmission rate of the photovoltaic module is 10⁻⁴ g/m²·day or less.

56. The photovoltaic module of claim 50, wherein a water transmission rate of the photovoltaic module is 10⁻⁶ g/m²·day or less.

57. The photovoltaic module of claim 50, wherein a water transmission rate of the photovoltaic module is 10⁻⁷ g/m²·day or less.

58. An assembly comprising a plurality of photovoltaic modules, each photovoltaic module in the plurality of photovoltaic modules having the structure of the photovoltaic module of claim 1, wherein photovoltaic modules in said plurality of solar photovoltaic modules are arranged in coplanar rows to form said assembly.

59. The assembly of claim 58, further comprising an albedo surface positioned to reflect sunlight into the plurality of photovoltaic modules.

60. The assembly of claim 59, wherein the albedo surface has an albedo that exceeds 80%.

61. The assembly of claim 59, wherein the albedo surface is Lambertian or diffuse.

62. The assembly of claim 59, wherein a first photovoltaic module and a second photovoltaic module in the plurality of photovoltaic modules are electrically coupled in series.

63. The assembly of claim 59, wherein a first photovoltaic module and a second photovoltaic module in the plurality of photovoltaic modules are electrically coupled in parallel.

64. The photovoltaic module of claim 1, wherein a back-electrode of a solar cell in the one or more solar cells is circumferentially disposed on the elongated substrate.

65. The photovoltaic module of claim 1, wherein a semiconductor junction of a first solar cell in the one or more solar cells is circumferentially disposed on the back-electrode of the first solar cell.

66. The photovoltaic module of claim 1, wherein a transparent conductive layer of a first solar cell in the one or more solar cells is circumferentially disposed on the semiconductor junction layer of the first solar cell.

67. The photovoltaic module of claim 1, wherein the one or more solar cells consists of three or more solar cells.

68. The photovoltaic module of claim 1, wherein the one or more solar cells consists of one hundred or more solar cells.

69. The photovoltaic module of claim 1, wherein one or more solar cells comprises a first solar cell and a second solar cell linearly arranged on said elongated substrate, and wherein the transparent conductive layer of the first solar cell is in serial electrical communication with the back-electrode of the second solar cell.

70. The photovoltaic module of claim 1, wherein the one or more solar cells consists of a plurality of solar cells and wherein:
a first terminal solar cell at a first end of said elongated substrate;
a second terminal solar cell at a second end of said elongated substrate; and
at least one intermediate photovoltaic cell between said first terminal solar cell and said second solar cell, wherein the transparent conductive layer of each intermediate solar cell in said at least one intermediate solar cell is in serial electrical communication with the back-electrode of an adjacent solar cell in said plurality of solar cells.

71. A photovoltaic module comprising
(A) a nonplanar elongated substrate having a first end and a second end; and
(B) a plurality of solar cells linearly arranged on said nonplanar elongated substrate, the plurality of solar cells comprising a first solar cell and a second solar cell, each solar cell in said plurality of solar cells comprising:
(i) a back-electrode disposed on a surface of said nonplanar elongated substrate;
(ii) a semiconductor junction layer disposed on a surface of said back-electrode; and
(iii) a transparent conductive layer disposed on a surface of said semiconductor junction, wherein said transparent conductive layer has a first refractive index,
wherein the transparent conductive layer of the first solar cell in said plurality of solar cells is in serial electrical communication with the back-electrode of the second solar cell in said plurality of solar cells;
(C) a filler material disposed on the transparent conductive layer of each solar cell in the plurality of solar cells, wherein said filler material has a second refractive index that is smaller or equal in value to said first refractive index; and
(D) a transparent casing disposed on said filler material thereby sealing said photovoltaic module, wherein said transparent casing has a third refractive index.

72. The photovoltaic module of claim 1, wherein said third refractive index is greater than the second refractive index.

73. The photovoltaic module of claim 1, wherein said third refractive index is smaller or equal in value to said second refractive index.

74. The photovoltaic module of claim 71, wherein said third refractive index is greater than the second refractive index.

75. The photovoltaic module of claim 71, wherein said third refractive index is smaller or equal in value to said second refractive index.

76. The photovoltaic module of claim 1, wherein a semiconductor junction of a first solar cell in the one or more solar cells comprises:
a first layer comprising a first inorganic semiconductor; and
a second layer comprising a second inorganic semiconductor.

77. The photovoltaic module of claim 76, wherein the first inorganic semiconductor and the second inorganic semiconductor are the same.

78. The photovoltaic module of claim 76, wherein the first inorganic semiconductor and the second inorganic semiconductor are the different.

79. The photovoltaic module of claim 76, wherein:
the first layer has a first conductivity type, and
the second layer has a second conductivity type that is different from the first conductivity type.

80. The photovoltaic module of claim 79, wherein a difference between the first conductivity type and the second conductivity type generates a potential difference across an interface between the first and second layers.

81. The photovoltaic module of claim 76, wherein the photovoltaic module is connected to an external load and wherein, responsive to light with photons having energies above a first band gap of the first layer, the first layer generates electrons that pass through the external load under an influence of the potential difference and then recombine with holes in the second layer.

82. The photovoltaic module of claim 81, wherein at least thirty percent of the electrons in the external load are derived from the first layer's response to irradiation with photons above the first band gap.

83. The photovoltaic module of claim 81, wherein at least seventy percent of the electrons in the external load are derived from the first layer's response to irradiation with photons above the first band gap.

84. The photovoltaic module of claim 79, wherein the first conductivity type is p and the second conductivity type is n.

85. The photovoltaic module of claim 79, wherein the first conductivity type is n and the second conductivity type is p.

86. The photovoltaic module of claim 76, further comprising a third layer disposed between the first and second layers, the third layer comprising an undoped insulator.

87. The photovoltaic module of claim 76, wherein:
the first inorganic semiconductor is an n type inorganic semiconductor; and
the second inorganic semiconductor is an n+ type inorganic semiconductor.

88. The photovoltaic module of claim 76, wherein
the first layer is an absorber layer; and
the second layer is a junction partner layer.

89. The photovoltaic module of claim 76, wherein
the first layer is a junction partner layer; and
the second layer is an absorption layer.

90. The photovoltaic module of claim 76, wherein:
the first layer is characterized by a first band gap;
the second layer is characterized by a second band gap; and
the second band gap is larger than the first band gap.

91. The photovoltaic module of claim 76, wherein:
the first layer is characterized by a first band gap;
the second layer is characterized by a second band gap; and
the second band gap is smaller than the first band gap.

92. The photovoltaic module of claim 76, wherein the first layer is characterized by a first band gap that is in the range of 0.7 eV to 2.2 eV.

93. The photovoltaic module of claim 76, wherein:
the first layer comprises copper-indium-gallium-diselenide (CIGS); and
the first layer is characterized by a first band gap that is in the range of 1.04 eV to 1.67 eV.

94. The photovoltaic module of claim 76, wherein:
the first layer comprises copper-indium-gallium-diselenide (CIGS); and
the first layer is characterized by a first band gap that is in the range of 1.1 eV to 1.2 eV.

95. The photovoltaic module of claim 76, wherein the first layer is an absorber layer that is graded such that a band gap of the first layer varies as a function of absorber layer depth.

96. The photovoltaic module of claim 76, wherein the first layer is an absorber layer comprising copper-indium-gallium-diselenide having the stoichiometry CuIn₁₋ₓGaₓSe₂ with non-uniform Ga/In composition versus absorber layer depth.

97. The photovoltaic module of claim 76, wherein the first layer is an absorber layer comprising copper-indium-gallium-diselenide with the stoichiometry CuIn₁₋ₓGaₓSe₂ and wherein a band gap of the absorber layer ranges between a first value in the range 1.04 eV to 1.67 eV and a second value in the range of 1.04 eV to 1.67 eV as a function of absorber layer depth, wherein the first value is greater than the second value.

98. The photovoltaic module of claim 76, wherein the first layer is an absorber layer comprising copper-indium-gallium-diselenide having the stoichiometry CuIn₁₋ₓGaₓSe₂ wherein a band gap of the absorber layer ranges between a first value in the range of 1.04 eV to 1.67 eV to a second value in the range of 1.04 eV to 1.67 eV as a function of absorber layer depth, wherein the first value is less than the second value.

99. The photovoltaic module of claim 97, wherein the band gap of the absorber layer ranges between the first value and the second value in a continuous linear gradient as a function of absorber layer depth.

100. The photovoltaic module of claim 98, wherein the band gap of the absorber layer ranges between the first value and the second value in a continuous linear gradient as a function of absorber layer depth.

101. The photovoltaic module unit of claim 76, wherein the first layer is characterized by a first band gap that is in the range of 0.9 eV and 1.8 eV.

102. The photovoltaic module of claim 76, wherein the first layer is characterized by a first band gap that is in the range of 1.1 eV and 1.4 eV.

103. The photovoltaic module of claim 1, wherein the filler material is a gel.

104. The photovoltaic module of claim 1, wherein the filler material is a liquid.

105. The photovoltaic module of claim 1, wherein the filler material is a solid.
